(19) United States
(12) Patent Application Publication
(10) Pub. No.: US 2026/0282391 A1
(43) Pub. Date: Sep. 17, 2026

(54) 3D SEMICONDUCTOR DEVICES AND STRUCTURES WITH VERTICAL CONNECTIVITY

(71) Applicant: Monolithic 3D Inc., Klamath Falls, OR (US)

(72) Inventors: Zvi Or-Bach, Haifa (IL); Jin-Woo Han, San Jose, CA (US); Brian Cronquist, Klamath Falls, OR (US)

(73) Assignee: Monolithic 3D Inc., Klamath Falls, OR (US)

(21) Appl. No.: 19/145,934

(22) PCT Filed: Aug. 1, 2021
(86) PCT No.: PCT/US2021/044110

§ 371 Date: Jul. 5, 2025

Related U.S. Application Data
(60) Provisional application No. 63/140,661, filed on Jan. 22, 2021.
(60) Provisional application No. 63/144,970, filed on Feb. 2, 2021.
(60) Provisional application No. 63/151,664, filed on Feb. 20, 2021.
(60) Provisional application No. 63/180,083, filed on Apr. 27, 2021.
(60) Provisional application No. 63/196,682, filed on Jun. 4, 2021.
(60) Provisional application No. 63/220,443, filed on Jul. 9, 2021.

(51) Int. Cl. H10B 80/00; H10W 80/00; H10W 90/00; H10W 90/26

(52) U.S. Cl. CPC H10B 80/00; H10W 80/312; H10W 90/26; H10W 90/792

(57) ABSTRACT

A 3D device, the device including: a first level including first transistors and a first interconnect; a second level including second transistors, the second level overlaying the first level; at least four functional units each including a first circuit and a second circuit; and a redundancy circuit, the first circuit including a portion of the first transistors, the second circuit including a portion of the second transistors, where each of the at least four functional units includes a vertical connectivity structure, the vertical connectivity structure including a plurality of pillars, where the plurality of pillars provides electrical control connection between the first circuit and the second circuit, where each of the at least four functional units includes at least one memory control circuit and at least one memory array, where the second level is bonded to the first level, where the bonded includes metal to metal bonding regions.

### BACKGROUND OF THE INVENTION

### 1. Field of the Invention

This application relates to the general field of Integrated Circuit (IC) devices and fabrication methods, and more particularly to multilayer or Three Dimensional Integrated Memory Circuit (3D-Memory) and Three Dimensional Integrated Logic Circuit (3D-Logic) devices and fabrication methods.

### 2. Discussion of Background Art

Over the past 40 years, there has been a dramatic increase in functionality and performance of Integrated Circuits (ICs). This has largely been due to the phenomenon of “scaling”; i.e., component sizes such as lateral and vertical dimensions within ICs have been reduced (“scaled”) with every successive generation of technology. There are two main classes of components in Complementary Metal Oxide Semiconductor (CMOS) ICs, namely transistors and wires. With “scaling”, transistor performance and density typically improve and this has contributed to the previously-mentioned increases in IC performance and functionality. However, wires (interconnects) that connect together transistors degrade in performance with “scaling”. The situation today is that wires dominate the performance, functionality and power consumption of ICs.

3D stacking of semiconductor devices or chips is one avenue to tackle the wire issues. By arranging transistors in 3 dimensions instead of 2 dimensions (as was the case in the 1990s), the transistors in ICs can be placed closer to each other. This reduces wire lengths and keeps wiring delay low and wire.

There are many techniques to construct 3D stacked integrated circuits or chips including:
Through-silicon via (TSV) technology: Multiple layers of dice are constructed separately. Following this, they can be bonded to each other and connected to each other with through-silicon vias (TSVs).
Monolithic 3D technology: With this approach, multiple layers of transistors and wires can be monolithically constructed. Some monolithic 3D and 3DIC approaches are described in U.S. Pat. Nos. 8,273,610, 8,298,875, 8,362,482, 8,378,715, 8,379,458, 8,450,804, 8,557,632, 8,574,929, 8,581,349, 8,642,416, 8,669,778, 8,674,470, 8,687,399, 8,742,476, 8,803,206, 8,836,073, 8,902,663, 8,994,404, 9,023,688, 9,029,173, 9,030,858, 9,117,749, 9,142,553, 9,219,005, 9,385,058, 9,406,670, 9,460,978, 9,509,313, 9,640,531, 9,691,760, 9,711,407, 9,721,927, 9,799,761, 9,871,034, 9,953,870, 9,953,994, 10,014,292, 10,014,318, 10,515,981, 10,892,016; and pending U.S. Patent Application Publications and applications, Ser. Nos. 14/642,724, 15/150,395, 15/173,686, 16/337,665, 16/558,304, 16/649,660, 16/836,659, 17/151,867, 62/651,722; 62/681,249, 62/713,345, 62/770,751, 62/952,222, 62/824,288, 63/075,067, 63/091,307, 63/115,000, 2020/0013791, 16/558,304; and PCT Applications (and Publications): PCT/US2010/052093, PCT/US2011/042071 (WO2012/015550), PCT/US2016/52726 (WO2017053329), PCT/US2017/052359 (WO2018/071143), PCT/US2018/016759 (WO2018144957), and PCT/US2018/52332 (WO 2019/060798). The entire contents of the foregoing patents, publications, and applications are incorporated herein by reference.
Electro-Optics: There is also work done for integrated monolithic 3D including layers of different crystals, such as U.S. Pat. Nos. 8,283,215, 8,163,581, 8,753,913, 8,823,122, 9,197,804, 9,419,031, 9,941,319, 10,679,977, and 10,943,934. The entire contents of the foregoing patents, publications, and applications are incorporated herein by reference.

In addition, the entire contents of U.S. patent application publication 2018/0350823 and U.S. patent applications 62/963,166, 62/963,270, 62/983,559, 62/986,772, 63,108,433, 63/118,908, 63/123,464, 63/144,970, 63/151,664, and Ser. No. 17/151,867 are incorporated herein by reference.

Additionally the 3D technology according to some embodiments of the invention may enable some very innovative IC devices alternatives with reduced development costs, novel and simpler process flows, increased yield, and other illustrative benefits.

### SUMMARY

The invention relates to multilayer or Three Dimensional Integrated Circuit (3D IC) devices and fabrication methods. Important aspects of 3D IC are technologies that allow layer transfer. These technologies include technologies that support reuse of the donor wafer, and technologies that support fabrication of active devices on the transferred layer to be transferred with it.

### BRIEF DESCRIPTION OF THE DRAWINGS

Various embodiments of the invention will be understood and appreciated more fully from at least the following detailed description, taken in conjunction with the drawings in which:

FIG. 1 is an example illustration of a 7 nm 6 T SRAM bit-cell layout;

FIG. 2 is an example illustration of a memory structure having memory units laid out in a 2D repeating pattern;

FIGS. 3A-3D are example illustrations of various arrangements and customizations of the 2D repeating pattern memory structure of FIG. 2;

FIGS. 4A-4C are example illustrations of cut views of FIGS. 3B-3D illustrating various unit to unit and within unit connectivity;

FIGS. 5A-5E are example illustrations of word-line pin/pad connectivity lay outs and bit-line pin/pad connectivity lay outs;

FIG. 6 is an example illustration of extending the memory layout concept to a multi-level memory structure;

FIG. 7A is an example illustration of FIG. 43E of U.S. application Ser. No. 16/558,304;

FIG. 7B is an example illustration of a memory unit that includes memory and memory controller;

FIG. 7C is an example illustration of 4 memory units of FIG. 7B formed as an array;

FIG. 7D is an example illustration of a wafer sized array of units memory units;

FIGS. 7E-7G are example illustrations of cut views of a formation process of memory strata which can be stored and then later bonded to other device structures to form systems;

FIG. 8 is an example illustration of an overall process flow of designing the logic and memory;

FIGS. 9A-9G are example illustrations of a 3D strata formation flow which could form a 3D compute device;

FIGS. 10A-10D are example illustrations of various power delivery substrate architectures to effectively deliver power multiple levels of active devices via heterogeneous integrations;

FIG. 10E is an example illustration of utilizing voltage down converters or voltage regulators which could be distributed to each zone over a 3D SYSTEM;

FIG. 10F is an example illustration of example techniques to provide intentional stress release mechanisms which could be integrated into a 3D SYSTEM;

FIG. 11 is an example table illustrating wafer processing costs are highly dependent on the type of process line used;

FIGS. 12A-12B are example illustrations of a coupling level ready to be hybrid bonded to an over the circuit pin/pad structure;

FIGS. 13A-13B are example illustrations of phased integrations of various 3D systems and the forming of various M-levels;

FIGS. 14A-14E are example illustrations various level integrations to form various types of 3D systems;

FIG. 14F is example illustrations of various ESD protection functions connected to the nano-TSV and internal logic;

FIGS. 15A-15D are example illustrations of DieM-Levels being part of a 3D system with photonic X-Y connectivity;

FIG. 15E is a copy of FIG. 8 and FIG. 9 of Tam, Sai-Wang, et al. “Wireline/wireless RF-Interconnect for future SoC.” 2011 IEEE International Symposium on Radio-Frequency Integration Technology. IEEE, 2011;

FIG. 15F is a drawing illustration of various structures and data of on-chip transmission/interconnection networks;

FIG. 15G is a drawing illustration of an exemplary 3D system similar to the one illustrated in FIG. 14E with and an additional RF-M-Level;

FIG. 15H is an example illustration of an alternative 3D system device and structure to the serpentine structure illustrated in FIG. 15F;

FIG. 15I is an example illustration block diagram of the per unit TL processors of the base level of the RF-M-Level, with a DMA option;

FIG. 15J is an example illustration of alternative schematics describing data transfer direction change connections and logic;

FIG. 15K is a simplified example illustration of a connection between two TLs;

FIG. 15L illustrates a modified block diagram of FIG. 15I in which 4 units are aggregated to communicate with the RF-I fabric;

FIG. 15M illustrates an example of an oversized reticle and use of different field sizes for the TL and the (processor) circuit;

FIG. 15N is an example illustration of over-die interconnects, which may run greater than 10 mm, and multiple dies, which could be grouped, such as 4 dies;

FIG. 15O is FIG. 1 of a paper by Du, Jieqiong, et al. “A 28-mW 32-Gb/s/pin 16-QAM Single-Ended Transceiver for High-Speed Memory Interface.” 2020 IEEE Symposium on VLSI Circuits. IEEE, 2020;

FIG. 15P illustrates a cross-sectional view of a multi-tiered TL, illustrating two levels of X-direction TL and levels of Y-direction TL;

FIG. 15Q shows an example of a wafer-scale-engine presented by I. Cutress “Hot Chips 31 Live Blogs: Cerebras' 1.2 Trillion Transistor Deep Learning Processor” in order to save the wasted area, a non-rectangular 3D system could be considered;

FIG. 15R shows not only entire circular wafer but also half or quarter of a wafer could be used without losing any of die near the edge;

FIG. 15S is an example illustration showing that TL levels could be placed underneath and/or on top of processors and memory level(s);

FIG. 15T is an example illustration showing various areas of panels currently; however, the smallest panel size is still greater than the size of a 300 mm wafer;

FIG. 15U is an example illustration of a long-haul TL using an NoC-style topologies, a 3D torus;

FIG. 15V is an example illustration of a long-haul TL using an NoC-style topologies, a butterfly;

FIG. 15W is an example illustration of congestion-aware routing;

FIGS. 16A-16E are example illustrations of various heat removal techniques and structures which may be built-in to 3D systems; for example, SubstrateM-Levels in a 3D system could include multiple compute levels and memory levels with X-Y connectivity levels in-between, while the system heat could be managed by liquid cooling;

FIG. 16F is an example illustration showing wireless connecting of the 3D system to external devices, which could be attractive as it could share resources for both NOC and connectivity to external devices;

FIG. 16G is an example illustration of a 3D system with additional cooling liquid distribution structure;

FIG. 16H is an additional example illustration of a 3D system with additional cooling liquid distribution structure;

FIGS. 17A-17D are example illustrations of full M-Levels being formed via multiple steps of simple bonding and thinning, and then using TSV processing to form the vertical bus pillars through the levels-stack and then form the pin/pads;

FIGS. 18A-18F are exemplary illustrations of process steps which may be used to form Schottky Barrier S/D junctions, form a uniform silicide layer;

FIG. 18G is an example illustration bowing and twisting variation at top and bottom of a stacked 3D NAND structure;

FIGS. 19A-19E are exemplary illustrations of methods and structures which enable a 3D NOR-P wafer with multiple stacks of 3D NOR-P blocks properly connected;

FIGS. 19F-19H are exemplary illustrations of methods and structures which enable a 3D NOR-P wafer with metal induced recrystallized silicon channel.

FIGS. 20A and 20B are exemplary illustrations of some of the advantages of metallic bit lines in a 3D NOR-P structure and device;

FIG. 20C is an exemplary illustration of a 2×2 array 3D NOR-P structure used to illustrate various types of unselected cell sharing of various WL/BL/SL combinations;

FIG. 20D is an exemplary illustration of write voltages to such memory cells illustrated in FIG. 20C and is illustrated on a single cell for four situations;

FIG. 20E is an exemplary illustration of a 2×2 FG memory array connected to a sense amplifier in differing manners;

FIG. 20F is an exemplary illustration of the voltage development of a BL of a S/A according to the reading time;

FIG. 20G is an exemplary illustration of exemplified voltage conditions and associated energy band diagrams for the reading operation of the exemplary cells of FIG. 20C and for inhibits to the reading for unselected cells;

FIG. 20H is an exemplary illustration of bitline current versus wordline voltage characteristics for different memory states and read conditions of the exemplary cells of FIG. 20C;

FIG. 21A is an exemplary illustration of the wafer scale engine of Cerebras Systems Inc;

FIG. 21B is an exemplary illustration of a wafer scale 3D system which could include I/O pads along the circumference of the wafer edge; and

FIGS. 21C-21G are exemplary illustrations of wafer scale 3D system fixtures that could allow the system to be ‘naked’ and provide better thermal dissipation;

FIGS. 21H-21I are exemplary illustrations of various configurations of a liquid cooling bath for wafer scale 3D systems;

FIG. 21J is an exemplary illustration of a fixture for a naked wafer scale 3D system which includes an Ethernet port and power port;

FIG. 21K is an exemplary illustrations of a wafer scale 3D system designed to be cut in half and

FIG. 21L is an exemplary illustrations of the wafer scale 3D systems of FIG. 21K arrayed through a printed circuit board.

### DETAILED DESCRIPTION

An embodiment of the invention is now described with reference to the drawing figures. Persons of ordinary skill in the art will appreciate that the description and figures illustrate rather than limit the invention and that in general the figures are not drawn to scale for clarity of presentation. Such skilled persons will also realize that many more embodiments are possible by applying the inventive principles contained herein and that such embodiments fall within the scope of the invention which is not to be limited except by any appended claims.

Some drawing figures may describe process flows for building devices. The process flows, which may be a sequence of steps for building a device, may have many structures, numerals and labels that may be common between two or more adjacent steps. In such cases, some labels, numerals and structures used for a certain step's figure may have been described in the previous steps' figures.

The use of layer transfer in the construction of a 3D IC based system could enable heterogeneous integration where each of strata may include one or more of MEMS sensor, image sensor, CMOS SoC, volatile memory such as DRAM and SRAM, persistent memory, and non-volatile memory such as flash and OTP. Such could include adding memory control circuits, also known as peripheral circuits, on top or below a memory array. The memory strata may contain only memory cells but not control logic, thus the control logic may be included on a separate stratum. Alternatively, the memory strata may contain memory cells and simple control logic where the control logic on that stratum may include at least one of decoder, buffer memory, sense amplifier. The circuits may include the charge pumps and high voltage transistors, which could be made on a strata using silicon transistors or other transistor types (such as SiGe, Ge, CNT, etc.) using a manufacturing process line that is different than the low voltage control circuit manufacturing process line. The analog circuits, such as for the sense amplifiers, and other sensitive linear circuits, could also be processed independently and be transferred over to the 3D fabric. Such 3D construction could include “Smart Alignment” techniques presented in this invention or leverage the repeating nature of the memory array to reduce the impact of the wafer bonder misalignments on the effectiveness of the integration.

In patents such as, for example, U.S. patent application Ser. No. 15/173,395, layer transfer techniques called ELTRAN (epitaxial layer transfer) are presented and may be part of the formation process of a 3DIC. The ELTRAN technique utilizes an epitaxial process or processes over porous layers. Alternatively other epitaxial based structures could be formed to support layer transfer techniques by leveraging the etch selectivity of these epitaxial layers, such as the very high etch selectivity of SiGe vs. Silicon, and variations such as Silicon (single crystal or poly or amorphous), SiGe (mix of silicon and Germanium), P doped silicon, N doped silicon, etc. Alternately, these layer(s) could be combined with types of detachment processes, such as ‘cold splitting,’ for example the Siltectra stress polymer and low temperature shock treatment, to provide a thin layer transfer process.

Recently it become a very attractive concept for processing gate all around horizontal transistors and has become the target flow for next generation devices such as the 5 nm technology node. Some of the work in respect to selective etching of SiGe vs. silicon has been presented in a paper by Jang-Gn Yun et al. titled: “Single-Crystalline Si Stacked Array (STAR) NAND Flash Memory” published in IEEE TRANSACTIONS ON ELECTRON DEVICES, VOL. 58, NO. 4, APRIL 2011, and a more recent work by K. Wostyn et al. titled “Selective Etch of Si and SiGe for Gate All-Around Device Architecture” published in ECS Transactions, 69 (8) 147-152 (2015), and by V. Destefanis et al. titled: “HCl Selective Etching of Si1−xGex versus Si for Silicon On Nothing and Multi Gate Devices” published in ECS Transactions, 16 (10) 427-438 (2008), all of the forgoing incorporated herein by reference. Since the SiGe over Si substrate process is becoming mature, this facilitates using a SiGe layer as a sacrificial layer for production worthy 3D layer transfer.

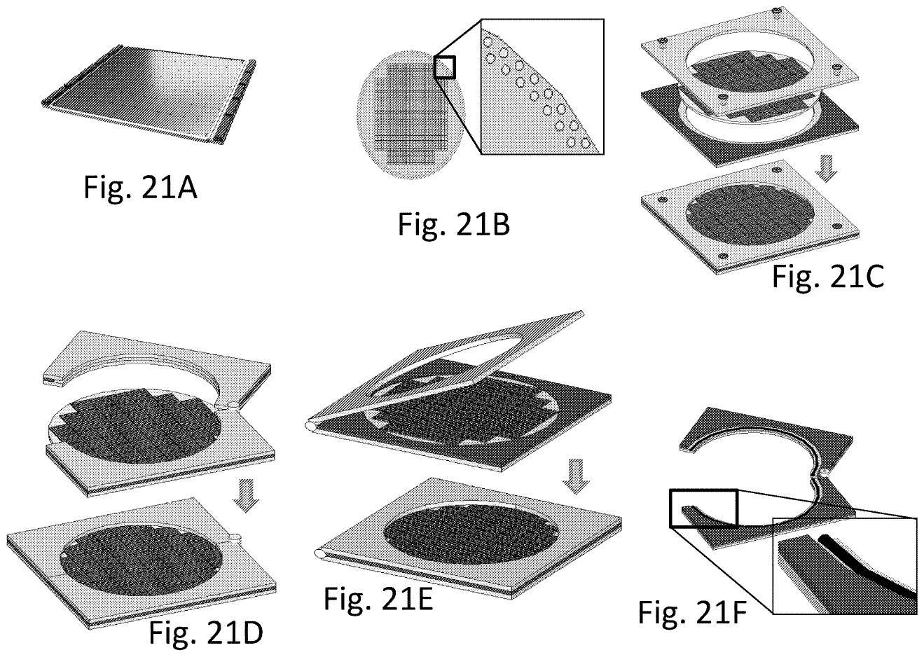

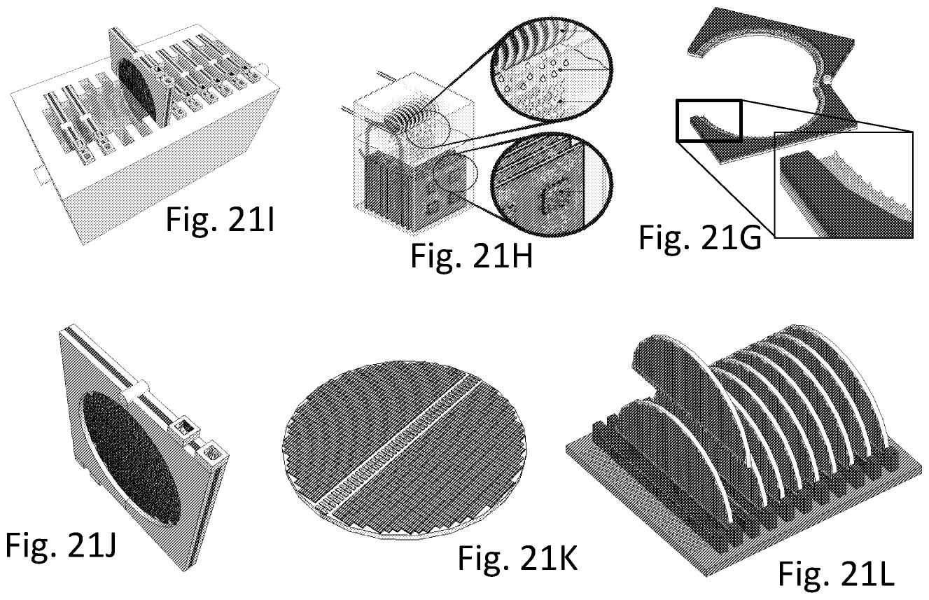

In at least U.S. Pat. No. 8,669,778, incorporated herein by reference, in respect to at least FIG. 22, a technique to have a generic memory array such as SRAM, DRAM, FRAM, RRAM, or MRAM customized for specific applications and be integrated as part of a 3D device flow was presented. In at least U.S. Pat. No. 9,021,414, incorporated herein by reference, flows and techniques to adapt an electronic design automation (“EDA”) tool for such a 3D structure are presented. In at least U.S. patent application Ser. No. 16/558,304, incorporated herein by reference, in respect to FIG. 21A to FIG. 25J, technique(s) to have a generic memory array integrated with logic utilizing hybrid bonding as part of a 3D device flow were presented. Herein a further variation of these concepts is presented. The 3D device could include a custom design logic level for which a memory level is integrated by use of a 3D integration using, for example, hybrid bonding. The memory level could be made fully custom to match the underlying custom logic, or by using a generic memory level, as presented herein, which has been customized by few added step to match the underlying custom logic. The memory level could be formed as an array of units in which the units are an array of bit-cells. The underlying custom logic could include the memory control circuit such as decoders and sense amplifiers.

In the following memory stacking alternatives, a few considerations are considered as important drivers. First, the objective is to maintain or minimize overall investment in using the memory stacking for custom devices. Accordingly, the memory array could be designed as a generic structure to be customized by very few custom steps, such as one or two metal layers and their associated via layer(s). Second, the generic memory structure uses conventional and simple copper interconnects which are usually defined by Chemical Mechanical Polishing-“CMP”, and not etching. In other words, the generic memory structure could be supplied by dedicated suppliers such as a semiconductor foundry and the generic memory structure can be purchased and customized by many customers and according to their demand at reduced cost for masks and other non-recurring costs (“NRE”).

Accordingly, the generic memory structure could be designed as an array of units. Each unit could be a small two-dimensional array of bit cells in the wafer plane. Later, if a product or customer requires a higher bit-cell density than the bit-cell density of a 2D single die, multiple generic memory wafers could be stacked to form a 3D stacked generic memory structure. As the identically designed and processed generic memory wafers are stacked, the memory unit is repeated in the vertical direction or along the out of wafer plane. Typically the number of rows in a unit could range from 32 to 1028 and the number of columns in the unit could range from 32 to 1028. In order to provide the flexibility and versatility to the customer with minimally compromising the cost, power, and performance, relatively smaller unit sizes such as 32×32 or 64×64 may be favored rather than the unit sizes such as 512×512. Herein, the smallest size of the unit will be referred as a ‘primitive unit’. If the generic memory wafer shall be considered for the 3D stacked generic memory wafer, the neighboring primitive unit could have some additional space for through silicon vias or through layer vias. The customization in terms of the memory unit size could be offered by adding a few custom process steps on top of the generic memory wafer before the wafer stacking step. The customization step could be an additional metallization step processed on the generic memory wafer, which bridges and stitches a few units into the desired size of the memory structure. The multiple primitive units stitched together to form a target size will be referred as a ‘stitched unit’. For example, four units of 32×32 primitive units can be connected to form a 64×64 stitched unit. In addition to the stitching process, a pin pad formation step could be included as part of these extra metal customization process steps. Then the customized memory wafer could be flipped and bonded, using for example hybrid bonding, to the logic substrate and form connections to pre-defined pads at the logic substrates connecting the memory to the logic.

The smallest memory structure could be designed with consideration of the bit-cell size and the precision of the hybrid bonding defining the minimum pitch and size for the bonding pads. The unit could be designed according to such a smallest memory structure or even smaller allowing more flexible placement and grid granularity.

Let's consider a bit-cell having width W and length L of total area W*L. Let's assume a hybrid bonding process with minimum pitch of H representing area for one connection H*H, wherein the area for one connection includes actual pad and space for the bonding. Let's assume the memory to be a 6T SRAM having one wordline for each cell width and two bit-lines for every bit-cell length. Let's assume the minimum array to have m cells along its width and n cells along it length. Accordingly the following formula represents the requirement for such a structure: m*W*2n*L>=m*H*H+n*H*H

As we can see the number of pads, and accordingly the required area for the pads, are growing according to m+n while the unit array area is growing by m*n. Accordingly given specific numbers and a choice of aspect ratio, a minimum array size could be defined for a specific case of bit-cell and with a hybrid bonding process.

As an example, recent reports on hybrid bonding, such as by: Jouve, A., et al. “1 μm pitch direct hybrid bonding with <300 nm Wafer-to-Wafer overlay accuracy.” 2017 IEEE SOI-3D-Subthreshold Microelectronics Technology Unified Conference (S3S). IEEE, 2017; and Global Foundries press release of Aug. 7, 2019 titled “GLOBALFOUNDRIES and Arm Demonstrate High-Density 3D Stack Test Chip for High Performance Compute Applications, indicate a hybrid bonding of 1 micron pitch (H=1 micron). And similar results and bonding techniques have been presented by Kim, Soon-Wook, et al. “Novel Cu/SiCN surface topography control for 1 μm pitch hybrid wafer-to-wafer bonding.” 2020 IEEE 70th Electronic Components and Technology Conference (ECTC). IEEE, 2020, the entire contents of the forgoing are incorporated herein by reference.

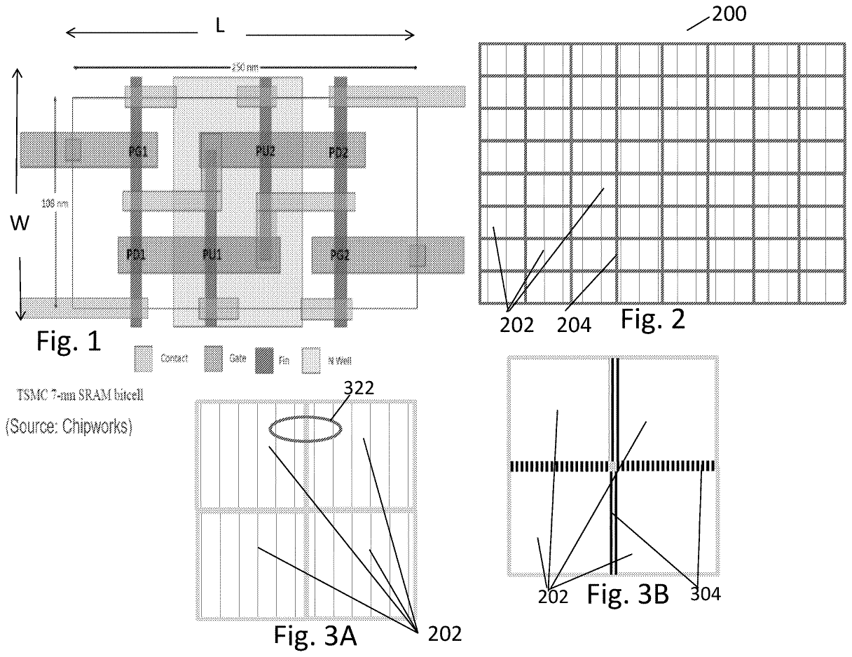

An example of a 7 nm 6 T SRAM bit-cell layout is illustrated in FIG. 1 showing a W=108 nm and L=250 inn. Following the above formula and an approximately square memory structure, the smallest memory structure that could be used for hybrid bonding could have:

$$m ∼ 100 and n ∼ 85.$$

FIG. 2 illustrates such an exemplary memory structure having primitive units 202 which for such an example could be set as the minimum array having an ~100*85 bit cell. The units could be placed with a bit-cell size space 204 between them forming a two dimensional repeating pattern 200 of generic memory.

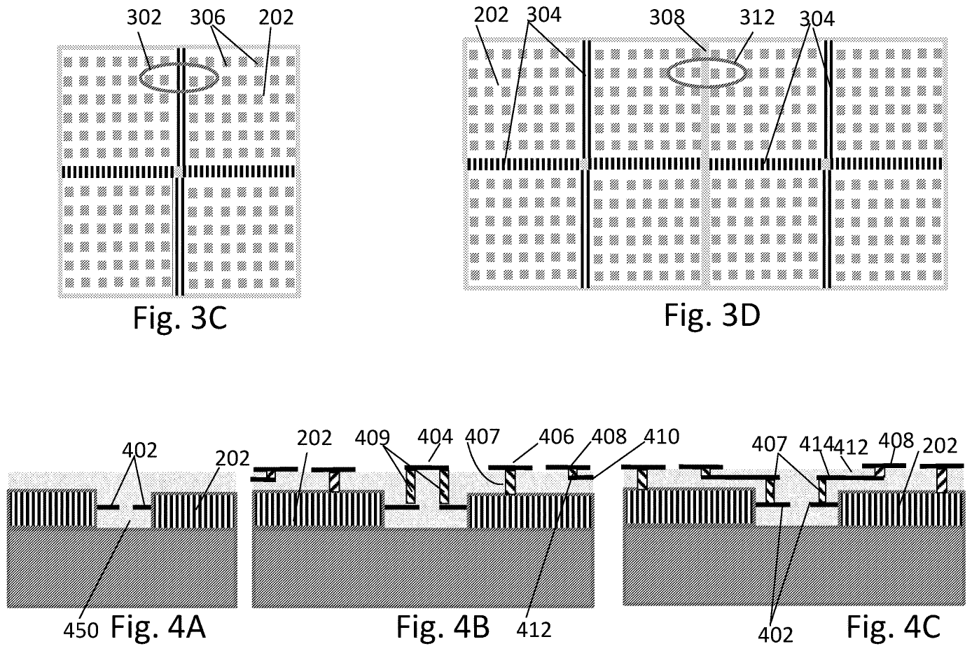

FIG. 3A illustrates four units 202 of the array of units such as in FIG. 2. These four units are arranged in a 2×2 configuration example.

FIG. 3B illustrates the four generic units 202 being customized to function as a memory structure by forming ‘bridges’ 304 (or strapping connections) between them such that the wordlines and the bitlines are connected so to control the 2×2 memory structure. The bridges connect the word-lines and bit-lines of adjacent units. The bridges could be copper, tungsten or other conductive metal or conductive material which is as conductive as copper or better.

FIG. 3C illustrates the further customization example attained by adding pads or pins 306 in preparation for the following step of hybrid bonding. The pads or pin could be copper, aluminum or other metal. The pad or pin 306 layer can be processed at the same step of the bridge layer. Alternatively, the pad or pin 306 layer could be formed on an upper level compared to the bridge layer so when the pad and pin 306 layers are exposed, the bridge layer resides inside the dielectric layer.

FIG. 3D illustrates the extension of the structure showing an additional 2×2 memory structure (for a total of two 2×2 memory structures) and the space 308 between them without bridges. Each 2×2 memory structure has four generic units 202 in this example.

FIG. 4A illustrates a cut view in the area marked by ellipse 322 of FIG. 3A. FIG. 4A shows a gap 450 in memory control line 402. Memory control line 402 could be a bit-line or a word-line, or in some cases another type of memory control line. The memory control line 402 is extended outside of the outer boundary of bit cell array.

FIG. 4B illustrates a cut view in the area marked by ellipse 302 of FIG. 3C. FIG. 4B illustrates bridge 404 with vias 409 linking the gap 450 and connecting the control line 402 of one unit 202 with another control line 402 from another unit 202. Pad/pins 406 and 408 show potential conductive hybrid bonding spots. Exemplary via 407 [for example, a thru silicon via (TSV) or a through layer via (TLV)] may connect pad/pins 406 to an underlying control line within an exemplary unit 202. As well, an electrically conducive connection from a pad/pin 408 thru via 407 to another control line 410 coming from the edge is further illustrated in FIG. 4D.

FIG. 4C illustrates a cut view in the area mark by ellipse 312 of FIG. 3D. The figure illustrates via 412 connecting the control line 404 from the unit edge with wire 414 and vias 407 and 412 to the pad/pin 406 for future bonding. FIGS. 4A, 4B and 4C illustrate a portion of the edge of generic units 202 and are exemplary in nature. Engineering design choices may create many variations of the connectivity concepts presented herein to optimize speed, power and cost of the envisioned system/device. For example, the pad/pin, via, control line segments, etc. shown in FIGS. 4A-4C do not need to be symmetric with respect to gap 450. Each portion of units 202 may have a completely different connectivity. As well, the connections between units 202 may be programmable, for example, by laser blowing or fusing fuses, or may be electrically programmed to be a conductive connection by an anti-fuse, or non-conductive by a fuse.

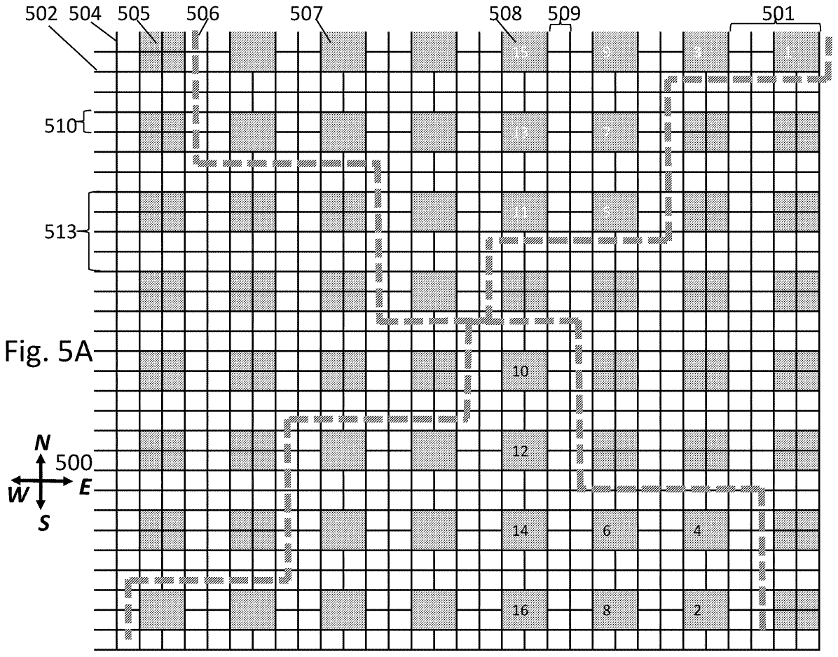

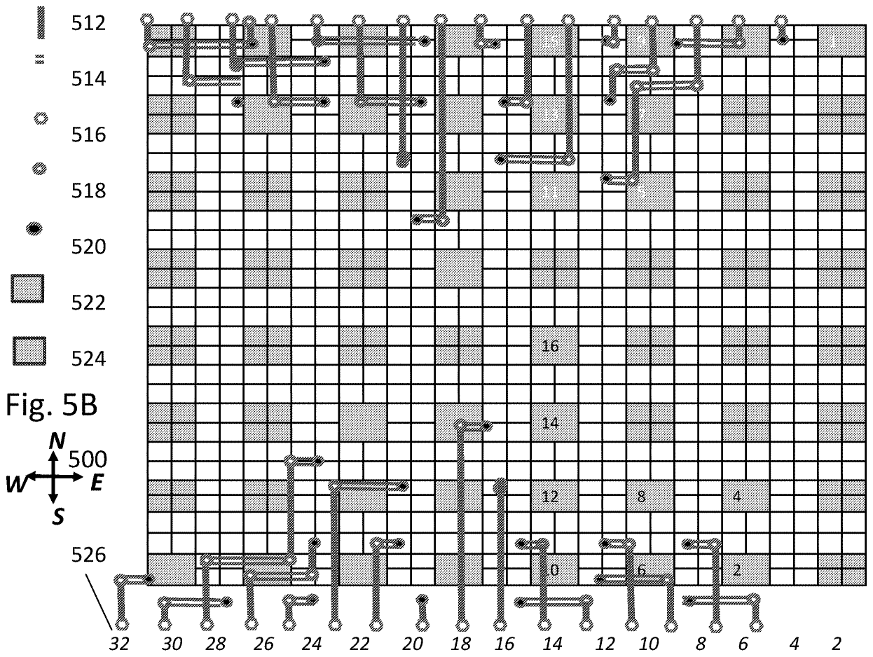

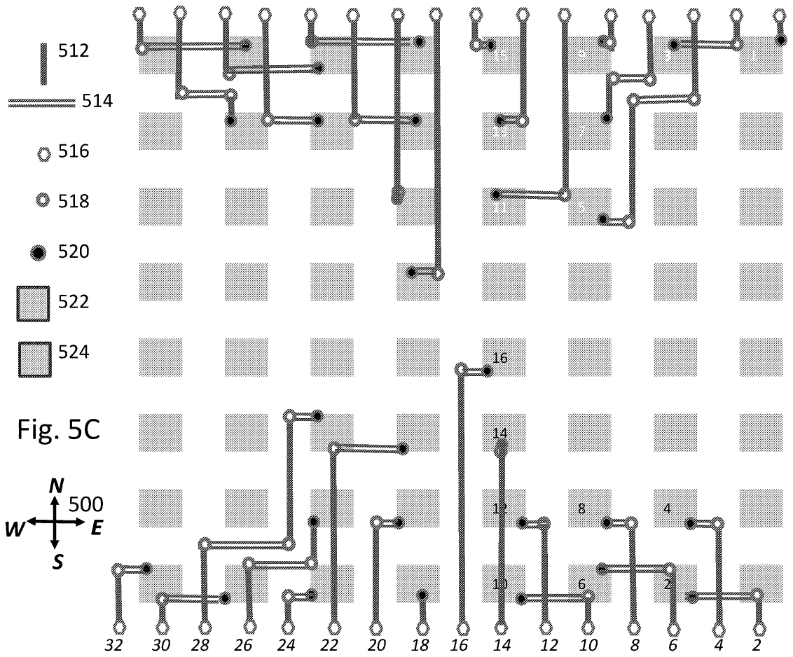

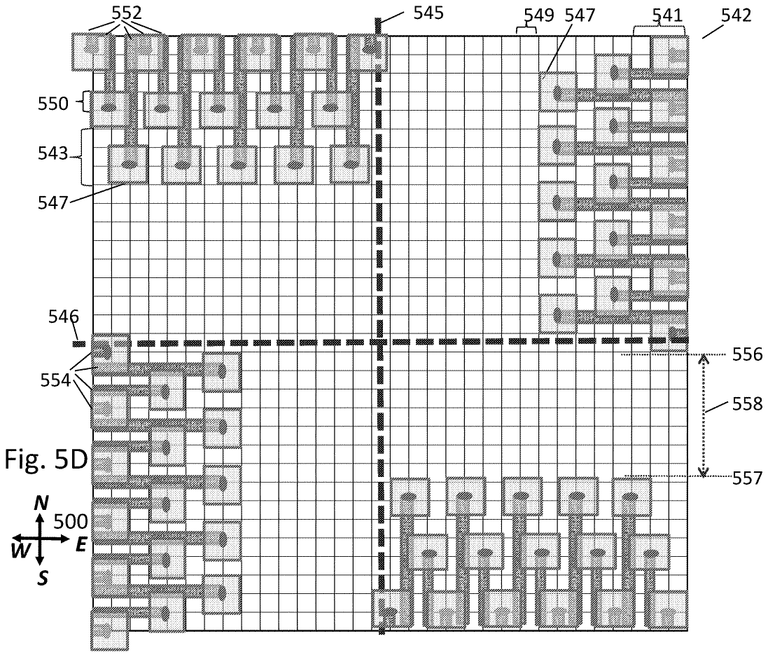

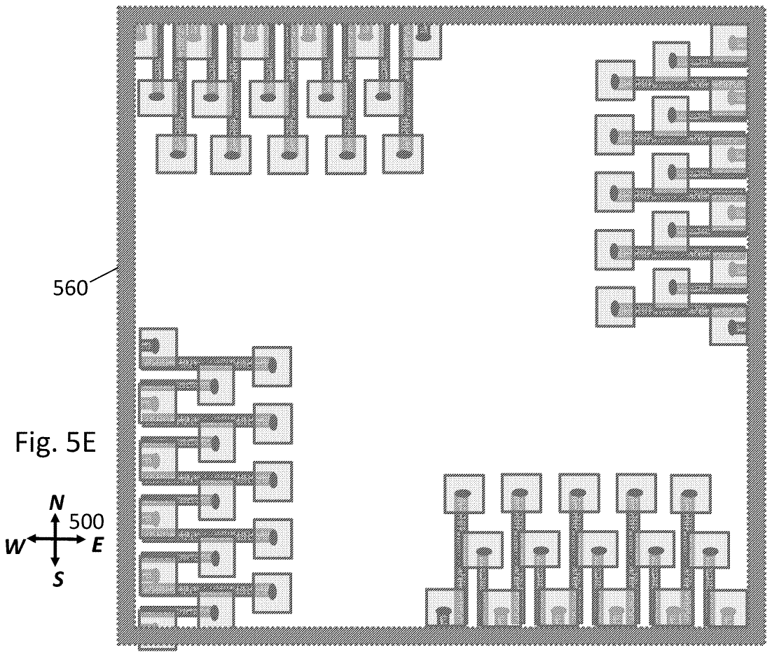

FIG. 5A-5C illustrates an example of a memory unit with a 3D pin/pads connectivity structure which is using two metal layers and a pin/pads layer.

FIG. 5A illustrates the pin/pads layer on top of a grid illustrating the underlying bit-lines 502 having pitch 510 (“BLP”), and word-lines 504 having pitch 509 (“WLP”). The hybrid bonding pin/pad pitch is 501 in W-E direction and 503 in the N-S direction, about 4 times courser than BLP and WLP, The fundamental concept is to re-distribute control lines which may have a tight pitch requirement into a two-dimensional metal pad array in a larger pitch to accommodate the hybrid bonding capability. In this example the bit-lines are the memory top metal in W-E cardinal 500 direction and the word-lines underneath in N-S cardinal 500 direction. In this example the memory cell size is about 2×BLP*WLP—two grid square if complementary cells requiring BL and BL/such as SRAM or about BLP*WLP—one grid square if the cell has only one BL such as DRAM, MRAM, PRAM, or RRAM. For simplicity, one grid squared is assumed to be one grid square for forthcoming explanation. The bonding alignment suggests a pad/pin of about two BLP by two WLP or 2×2 grid square 505, 507 which suggests a total area for one pad/pin of a 4×4 grid square. In other words, the one pad/pin occupies 16 bit cell areas; 4 bit cell areas of pin/pad and 12 bit cells are needed for space. In this example each memory cell has one word-line and one bit-line, such as is found in DRAM bit cells. The calculation for the minimum unit size could be adapted to other type memory cells accordingly as in the following. For this example the unit aspect ratio is about one-square unit. The BLP is about the same as WLP or P for the following calculation. Accordingly the area for one pin/pad is 4×4×P²=16P², the number of word-lines could be equal to the number of bit-lines or m for a square unit structure, than the formula suggests:

$$16 {P}^{2} * ( m + m ) <= mP * mP , or 32 <= m .$$

Accordingly the example of FIG. 5A illustrates a smallest unit of 32 bit-lines by 32 word-lines.

FIG. 5A illustrates 32 pin/pads 507 for the bit-line connectivity for which the first 16 bit-line addresses are numbered 508, and 32 pin/pads 505 for the word-line connectivity. It also illustrates with dashed lines 506 allocating the top surface to four zones, two for the pin/pads for the word-line connectivity and two for the bit-line connectivity. The specific pin/pad arrangement of FIGS. 5A-5C are exemplary, and specific arrangements may be designed according to engineering tradeoffs such as lithographic and bonding alignment accuracy and precision, critical speed nets, memory cell size and aspect ratio, etc.

FIG. 5B illustrates metal connection of the bit-lines. There is connection between each bit-line to one corresponding pin/pad. The connections are split into two groups. The even numbered 526 bit lines which are connected from the South using side via 516 while the odd numbered are from the North side. This leverages the availability of each bit-line on both sides of the unit. The connectivity layout is only an illustration. A qualified layout could be designed by a layout artisan in the art taking into account the design rules for the specific process. Such a layout could include extending the unit size to accommodate lay out limitations in such specific cases. In FIG. 5B the top metal is allocated to the pad/pins 522, 524. Connected with via 520 to the underlying metal layer 514 oriented W-E, connected with via 518 to the metal layer underneath 512 which is oriented S-N in FIG. 5B.

The connectivity layout (not shown) for the bit-line could be made in a similar fashion in the area left for it, or leverage the availability of the bit-lines oriented W-E being at the top of the memory array using direct vias rather than West, East side's access vias.

FIG. 5C illustrates the top three connectivity layers of FIG. 5B without the grid, for better visibility of the word-lines pin/pad connectivity lay out. The drawing symbol legends between FIGS. 5B and 5C are the same.

Although not drawn, many memory bit cells require power and ground lines, for example, such as SRAM. It should be understood that the bonding pad for the power and ground are allocated on top of bridge region 304 of Fig. The power and ground lines are often biased at static voltage without row or column individually control, the power and ground lines from multiple rows or columns are grouped together so only a few pads would be required.

The top surface of the logic wafer would have a pad/pin layout which is reciprocal to the memory wafer or die. The pad layout for the logic wafer and the memory wafer would be mirrored so that they can be properly F2F bonded and electrically connected later. The pad/pin of the logic wafer would be connected to the sense amplifier for bit-line and multiplexer for word-line pad.

Another alternative is to have a bit larger unit size to allow a regular pin/pad over the unit connectivity. Such could allow one metal layer for the routing and another one for the pin/pads layer. To illustrate this alternative, the unit structure of FIG. 5A and with better hybrid-bonding pitch (“H”) as is illustrated in FIG. 5D. The bonding pad pitch 541, 543 including pad/pin 547 is, for example, three times larger than the wordline pitch WLP 549 and the bitline pitch BLP 550 of memory array. The hybrid bonding connectivity structure resemble the one referenced in PCT/US2017/052359, incorporated herein by reference, as related to its FIG. 21A-21C, folded over the memory unit as is illustrated in FIG. 5D herein. The ratio, H/BLP, between the hybrid bonding pitch H and the bitline pitch BLP, could derive the number (rounding up) of columns of bonding pad/pin for the bitlines as is illustrated in FIG. 5D. Similarly, the ratio H/WLP, between hybrid bonding pitch H and the wordline pitch WLP, could drive the number (rounding up) of rows bonding pad/pin for the wordlines as is illustrated in FIG. 5D. As a result, the number of rows and columns for WL and the number of rows and columns for BL are respectively determined. So the top surface of the unit could be marked to four similar size quadrants by the N-S dashed line 545 and the W-E dashed line 546. The N-E quadrant 542 could be used for bonding pads/pin for half of the bitlines 554 while the W-S could be used for bonding pads/pin for the other half of the bitlines 554, and in similar way for the wordlines 552, W-N quadrant for the first half and the S-E for the other half.

To assess what could be the smaller unit size for such pin/pads connectivity, the following considerations could be addressed. The dashed line 556 represent the South direction edge of the N-E quadrant structure, while the dashed line 557 represent the North edge of the S-E quadrant connectivity structure. The distance between these structures 558 is required to avoid these structures getting too close. The length (in N-S direction) of the N-E quadrant structure is about ~n/2*BLP+H. In here, n is the number of bitlines in the unit. The width (in N-S direction) of the S-E quadrant structure is about ~H/WLP (round up)*H. For simplicity, let's assume that the wordline pitch is about equal to the bitline pitch and could be symbolized as P. The unit size in N-S direction is about n*P. Accordingly the formula representing the condition regarding 558 is: H/P*H+H+n/2*P<n*P, which could be written as: n>2H²/P²+2H/P. For example, let's assume H=1 micron and P=0.1 micron than n>220. Accordingly a memory array that is structured as array of units sized 200 μ*200μ with a control lines pitch of 0.1μ would have enough top of the unit area to form a pin/pads connectivity structure such as illustrated in FIG. 5D having n~2,000>>220. FIG. 5E is the illustration of FIG. 5D after removing the grid and other marks and adding marks for the borders of the underlying memory unit 560.

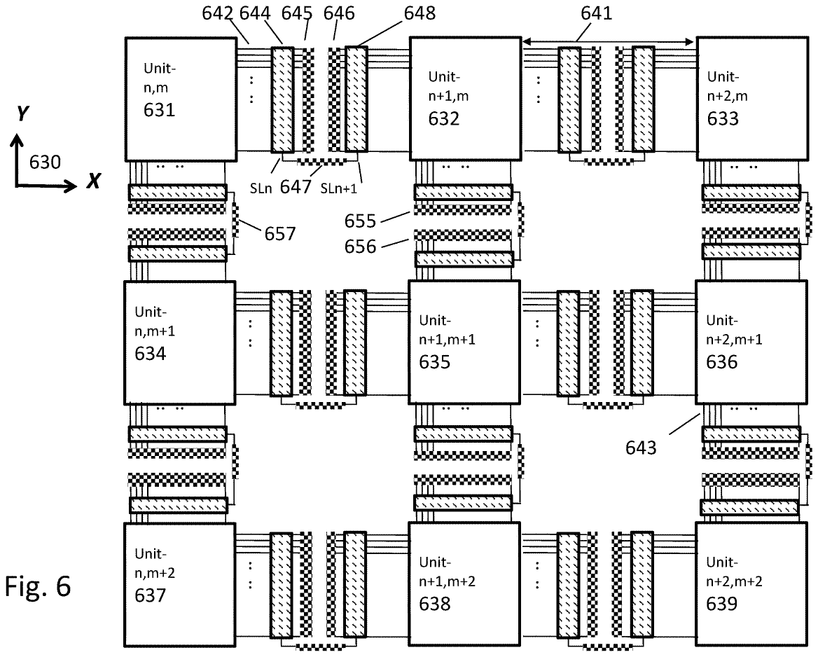

FIG. 6 illustrates extending the concept to a multi-level memory structure. Such could be utilized in cases in which the memory requirements are very high and a single level of memory would not offer enough memory. FIG. 6 is similar to FIG. 22F of U.S. application Ser. No. 16/558,304 incorporated herein by reference. The vertical pillars of the global control lines such as 2246 and 2258 of FIG. 22F (of Ser. No. 16/558,304) are replaced with two sets of vertical pillars 645, 646 as replacement of 2246, and 655, 656 as replacement of 2258, and so forth. And the bridging concept of FIG. 4B or the pad/pin extension for bonding of FIG. 4C could be used for the customization of multi-levels memory structure. The per-level selects 647, 657 could be connected to the control logic to enable full control of the specific level selected.

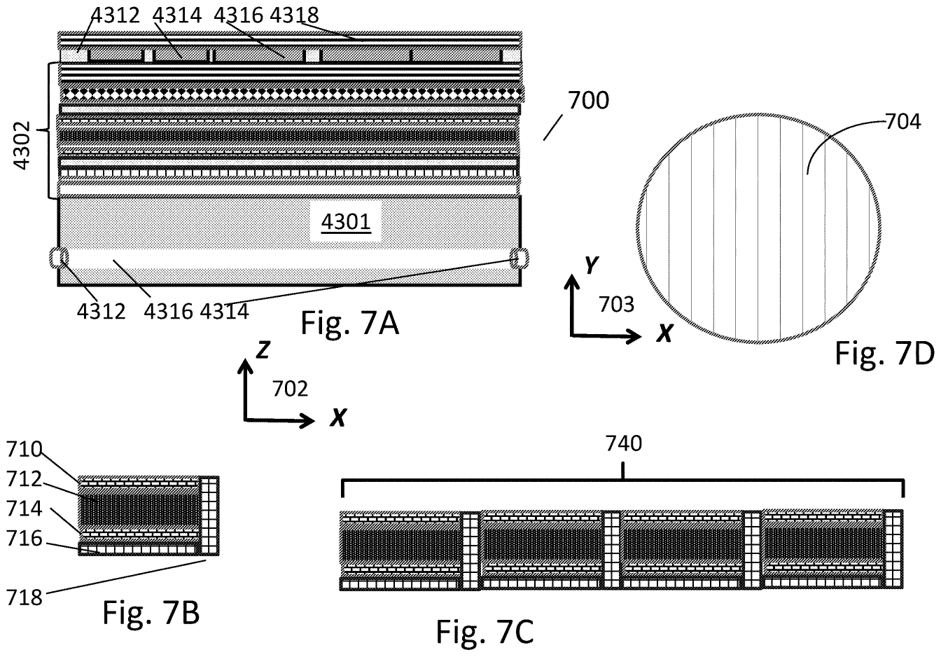

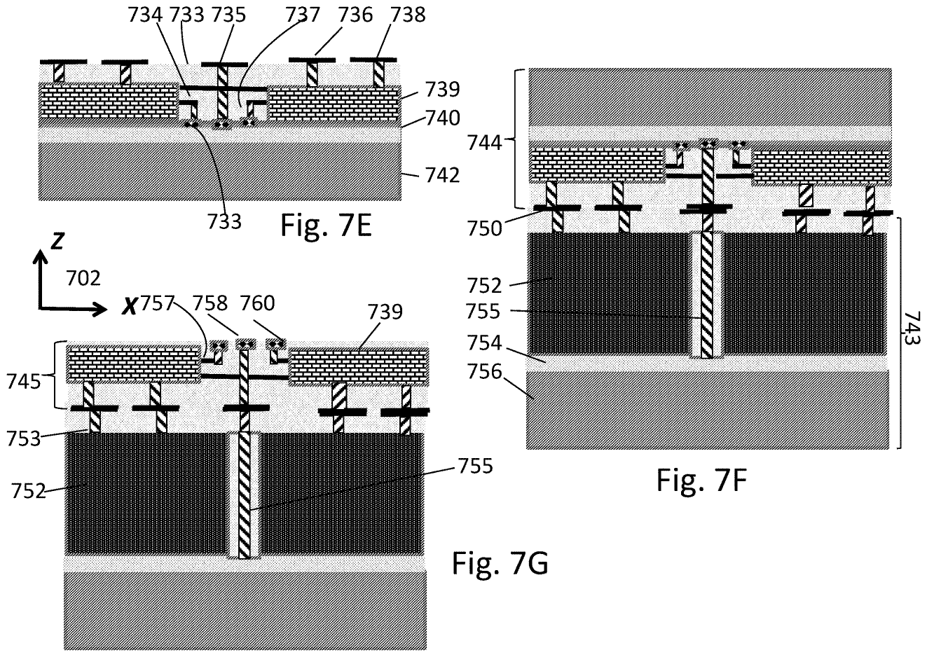

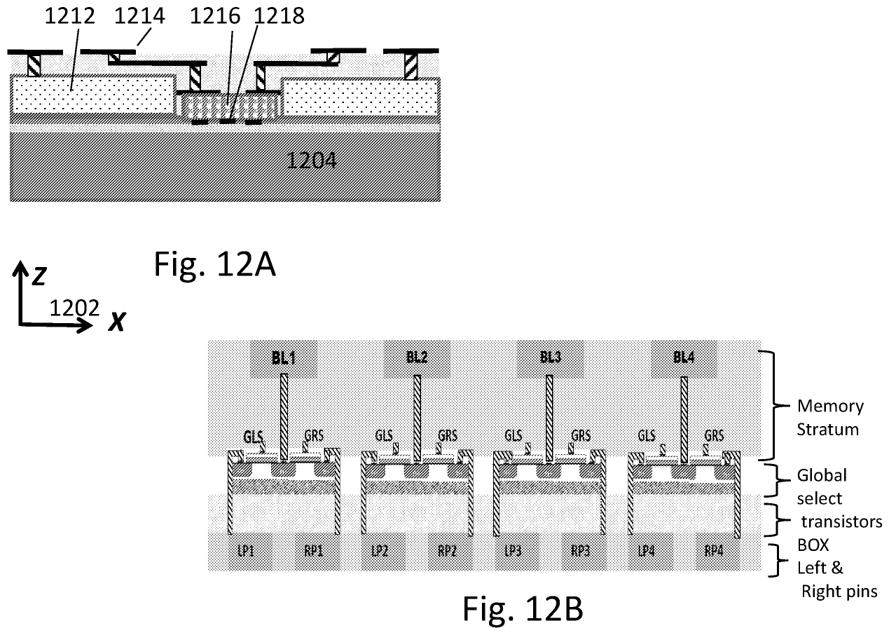

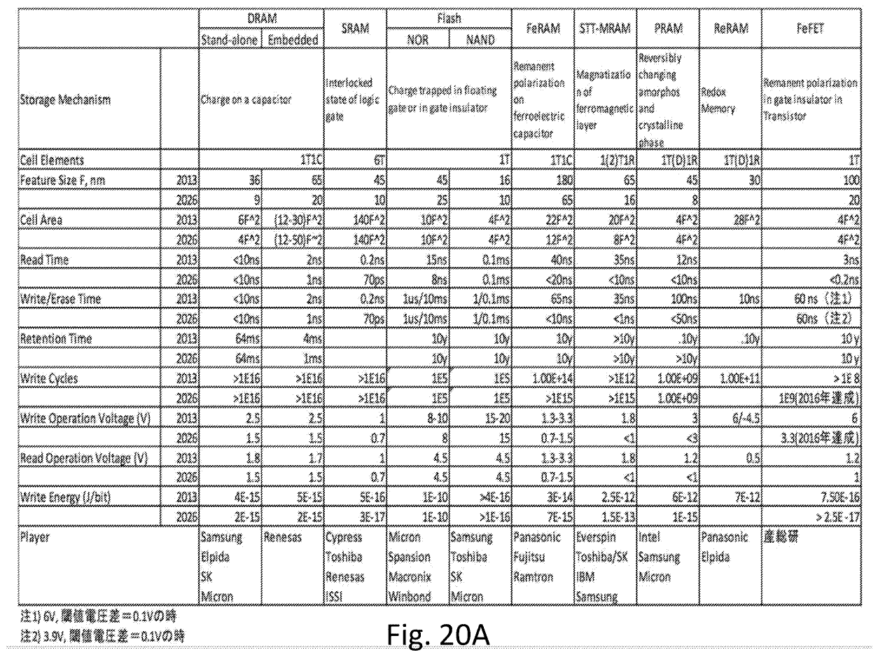

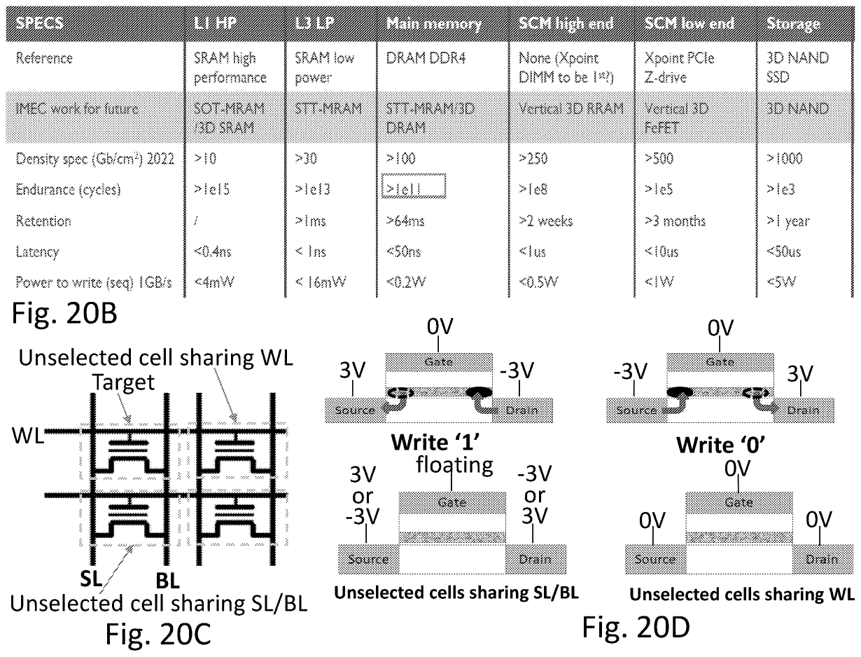

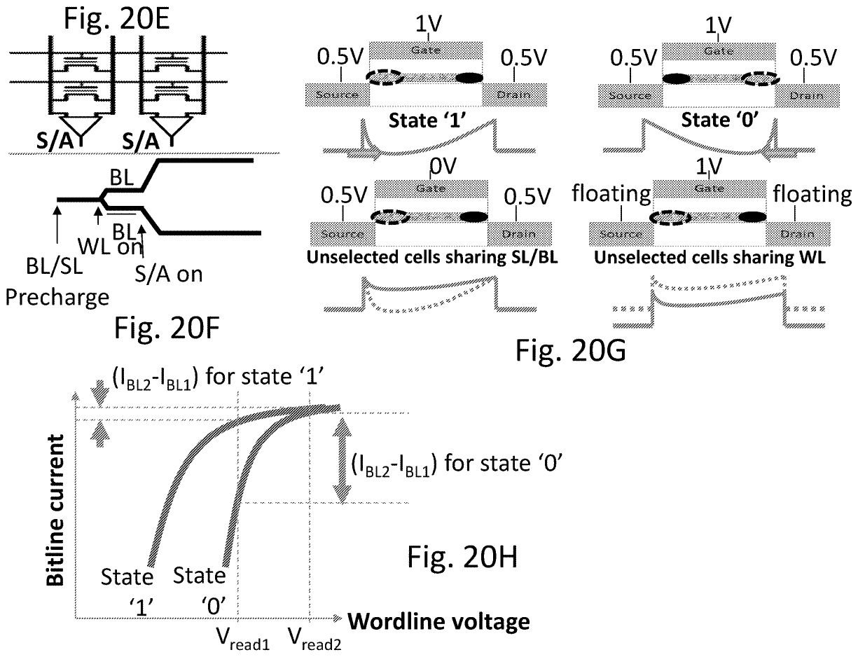

FIG. 7A is a copy of FIG. 43E of U.S. application Ser. No. 16/558,304, incorporated herein by reference. FIG. 7A illustrates a multi-level device that could comprise, logic levels, customize memory levels as presented herein to support such logic level as cache 1, cache 2, or last level cache type memory, additional levels of memory and levels of memory controls including decoding and sense amplifier circuits, these levels could be in the form of multi-level stacks of high speed memory such as DRAM, memory structures such as 3D NOR and storage structures such as 3D NAND. Additionally, the level(s) of global X-Y interconnection could utilize electromagnetic waves over transmission lines or wave-guides with the supporting RF or optical circuits. The various levels could include feed through connections to allow across level vertical connectivity. The use of layer transfer in the construction of such a 3D IC based system could enable heterogeneous integration wherein each strata/layer/level may include, for example, one or more of MEMS sensor, image sensor, CMOS SoC, volatile memory such as DRAM and SRAM, persistent memory, Ferroelectric Memory and non-volatile memory such as flash and OTP. Such could include adding memory control circuits, also known as peripheral circuits, on top or below a memory array. The memory strata may contain only memory cells but not control logic, thus the control logic may be included on a separate stratum. Alternatively, the memory strata may contain memory cells and simple control logic where the control logic on that stratum may include at least one of decoder, buffer memory, sense amplifier. The peripheral/control circuits may include the charge pumps and high voltage transistors, which could be made on a strata using silicon transistors or other transistor types (such as SiGe, Ge, CNT, etc.) using a manufacturing process line that may be, and often is, different than the low voltage control circuit manufacturing process line. The analog circuits, such as for the sense amplifiers, and other sensitive linear circuits could also be processed independently and be layer transferred over to the 3D fabric. Such 3D construction could include the “Smart Alignment” techniques presented in this invention or incorporated references, or leverage the repeating nature of the memory array to reduce the impact of the wafer bonder misalignment on the effectiveness of the integration. Such as presented in PCT/US2017/052359 (WO2018/071143), incorporated herein by reference in its entirety. Specifically for this discussion, in respect to its FIG. 11A to FIG. 12J, or using hybrid bonding techniques as presented in respect to its FIG. 20A to FIG. 25J. Hybrid bonding between levels reduces the process steps required in such a 3D integration but provides less flexibility for overcoming the misalignment challenge. “Smart Alignment” techniques allow overcoming such alignment challenges but will require via etches and deposition steps for such levels adding steps to the stacking process. The vertical connectivity challenge could be quite different between the various levels in the 3D stack structure. Stacking memory levels which have no in-level decoders could require vertical connectivity at word-lines, bit-lines pitch and so forth to the decoder's level, which is relatively more demanding than the connectivity of other levels in the stack. Accordingly the stacking process could be different to accommodate the alignment requirement between these levels. Also the source of alignment error could be different making the error sometimes smaller if the wafers are coming from the same process lines such as could be expected for the memory levels (for example, minimal stepper matching). These choices and the 3D engineering design could use the various 3D integration techniques presented herein the incorporated by reference art by an artisan in the art.

The memory strata could include multiple types and memory technologies and could be placed in various levels of the 3D device structure such as is illustrated in FIG. 7A. It could include high speed memory closer to the computing logic and high density memories closer to the X-Y interconnection fabrics. The high density levels could be in the form similar to what is known in the industry as 3D NAND, V-NAND, X-point memory, or Optane, while the high speed memory could be similar to what is called 3D NOR-P and presented in PCT/US2018/016759 and 62/952,222, both incorporated herein by reference. The memory stratum could be a structure of arrays of units. FIG. 7B illustrates such unit which could have a size of about 0.04 mm², about 0.1 mm², about 0.4 mm² about 0.1 mm², about 0.4 mm². Or even larger than about 1 mm². It could a structured array of units such as 2×2, 4×4, 8×8, 32×32, 256×256, 1024×1024 or any mix of these numbers such 16×64. The memory level could include the memory control circuits 710, 714 also called memory periphery circuits and about 100 feed-through per units 718 to support vertical connectivity throughout the 3D structure 700. The control circuits could be structured so that each memory unit has its own control on top 710 and/or below 714 the memory array 712. The connectivity between the memory control and the memory array could utilize hybrid bonding and pad/pin structure as been presented here in reference to FIG. 5A-5C or other structures such as been presented in the incorporated by reference art such as in PCT/US2017/052359, incorporated herein by reference, as related to its FIG. 21A-21C. The connectivity from the control circuit 714 to the other device level such as computing logic 716 could be relatively easier as for an area of a unit there could be need for few tens or very few hundreds of connections needed as the memory control circuits include the address decoders for the address portion within the vertical bus. So within the units the connectivity needs from the memory control circuits to the memory array, 2D or 3D, could include a few thousand of connections to the bit-lines and the word-lines about a hundred of connection for the feed-throughs and few tens to a few hundred for the layer select in the case of 3D memory. The few hundred additional connections could be added on top of the unit or by it side as even for pad/pin with 1 micron pitch over a side length of a unit which is 200 microns or more will add only single percents of overhead area to the structure. The memory stratum could be a standard module to be integrated with other structures to form custom or semi-custom product. The structure size could be a full wafer or any smaller structure such as even a single field of even smaller than 100 mm² size, as presented in PCT/US2018/52332, incorporated herein by reference. The industry supports stacking with various type of bonding including hybrid bonding of wafers or dies. The memory controller could include build in test and redundancy activation to be operated during device set up and operation. The activation and reporting of these built-in test and redundancy could be included as part of the function of these hundreds of connections and feed-through connections.

The bus for such a unit could be different for different units across the structure and so could be the size of the units in the structure. The bus could be 1, 2, 4, 8, 16, 32 or 64 bits which are common in the industry but could also be an extreme wide bus of few hundreds or even thousands of bits to support processor designs with an extremely wide data bus, or with additional on chip buffers to increase data speed from memory to processor level.

FIG. 7C illustrates tiling the unit structure of FIG. 7B thus forming an array of units 740. Such tiling could be across a full wafer or any portion of such. FIGS. 7A-7C are side-views along the X-Z 702 direction. FIG. 7D is a planar view along the X-Y 703 direction of a wafer sized array of units 704.

The process flow to form full 3D Heterogeneous integration such as is illustrated in FIG. 7A could include a few steps of wafer bonding and substrate removal such as been called “cut” using cut-layer or thinning using grinding and etch which could include using the cut-layer as an etch stop layer. This 3D structure formation could include mix and match bonding of various levels such as generic strata, semi-custom strata and full custom strata. The memory strata could include a step of forming a 3D NOR memory array and then bonding the memory control level to it. FIGS. 7E-7G illustrates such a process flow using a small section X-Z 702 cut view.

FIG. 7E illustrates a small section of the memory control circuit 739 (peripheral circuit). The section corresponds to the edge of two units. It illustrates four top bonding pin/pads 736,738 to be bonded to the memory pin/pads such as illustrated in FIG. 5E. It illustrates a feed through structure 735 and two bottom pin/pads 737 designated to be connected to the logic level. The base could include base silicon 742 and a cut-layer/etch-stop-layer 740. The bottom bonding pads could be placed in the region between units which could be cleared of active circuits. The bottom 737 pin/pads could be part of the first metal or the contact layer. Alternatively leveraging the etch selectivity of the cut-layer 740 they could be formed even below it (not shown) to simplify the later step of exposing them for preparing them as pin/pads. Other options do exist including allocating more area for these pins/pads and using a technique known as TSV. The structure includes top oxide 733 for protection and will be part of the future hybrid bonding.

FIG. 7F illustrates flipping and bonding the memory control circuit 744 (from FIG. 7E) on top of memory strata 743. The memory strata 743 could be an array 752 of 3D NOR-P or any of the other memory options previously discussed. Memory strata 743 could be formed over substrate 756 with its own cut-layer (also could be called etch-stop-layer) 752. The feed-through 755 could be placed between the memory units. The memory pin/pads 735,736, 738 from FIG. 7E could be connected to the control level pin/pads 750 using hybrid bonding.

FIG. 7G illustrates the structure after thinning the memory control circuit 744 to form memory control 745 by techniques such as grinding and etch-back leveraging the etch-stop layer or any of the other cut techniques previously presented herein or in the incorporated references. The pin/pads 758, 760 are exposed or being formed by opening the top via and forming the metallic top pin/pads using conventional semiconductor processes. The process steps which would be needed to form these pin/pads 758, 760 is a part of the overall flow design. It could be relatively very simple process in the case that the processing of the wafer as is illustrated in FIG. 7E include forming metal connections to the contact level 733, or it could include more steps to form vias down through the wafer back side all the way to the proper metal level of the proper signal line. FIG. 7G illustrates a small section of a full memory strata having the memory array and its control ready to be bonded on top of a logic wafer toward forming the type of structure illustrated in FIG. 7A. It could be expected that the number of connections from the memory control strata to the memory array 750 per unit could be few thousands to provide the control to the word-lines, bit-lines and other memory control lines. The number of feed-through 755, 758 per unit could be in the tens and so is the number of connections 760 to the processor logic level, as previously discussed.

The memory controller could be integrated using bonding techniques or by other techniques such as common with 3D NAND with periphery under cell (“PUC).

The memory strata could be set to function as dual port memory such for example one memory controller 714 is controlled by the underlying processing logic while the upper controller 710 may be controlled by an overlying processing circuit that could be part of the circuits operating to move data into the structure or out of the structure (“I/O”).

The memory strata could be set to function as a content addressable memory (CAM).

The stacking could utilize pin/pad connectivity as presented in reference to FIG. 5A-5E or other techniques such as smart alignment and electronic alignment as was presented in the incorporated by reference art, or any mix and match of these techniques.

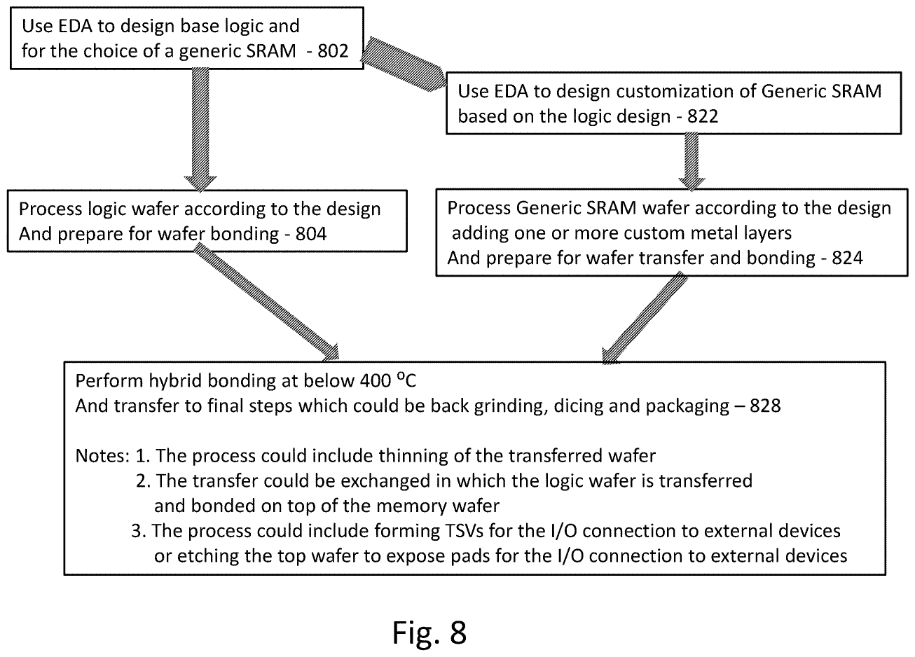

FIG. 8 illustrates an exemplary overall process flow of designing the logic wafer 802 and processing it 804. Design the customization of the memory wafer 822. There might be full set of generic wafers offering multiple process nodes and other memory option such as high density and high speed and so forth for the designer to choose from. The selected generic memory wafer may then be customized 824 for the specific design and then flipped and bonded using, for example, hybrid bonding 828 to the logic wafer.

The logic wafer and the generic wafer structure could include power line connections using the hybrid bonding as well. These power connections could be made at the unit level memory structure level and or die level. The figures do not show these power connections. The final processing in this step may include back grinding, dicing and packaging.

The generic memory could be customized to support more than one level of memory using techniques presented in the incorporated by reference art.

The EDA tool for such a 3D logic-memory design could incorporate techniques presented in at least U.S. Pat. No. 9,021,414, incorporated herein by reference. For the flow presented in FIG. 8, the EDA tool could include a grid for the memory decoder placement to support such a unit based generic memory fabric.

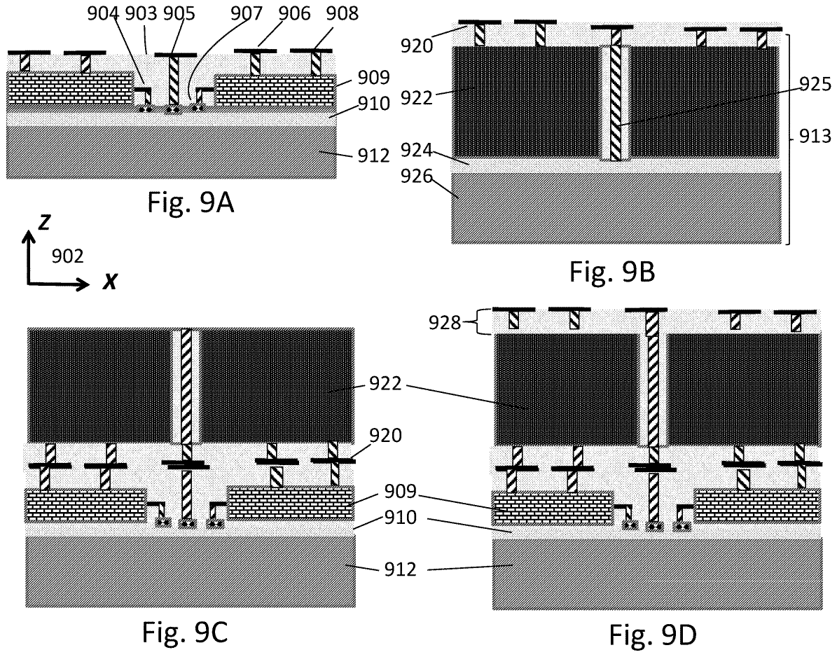

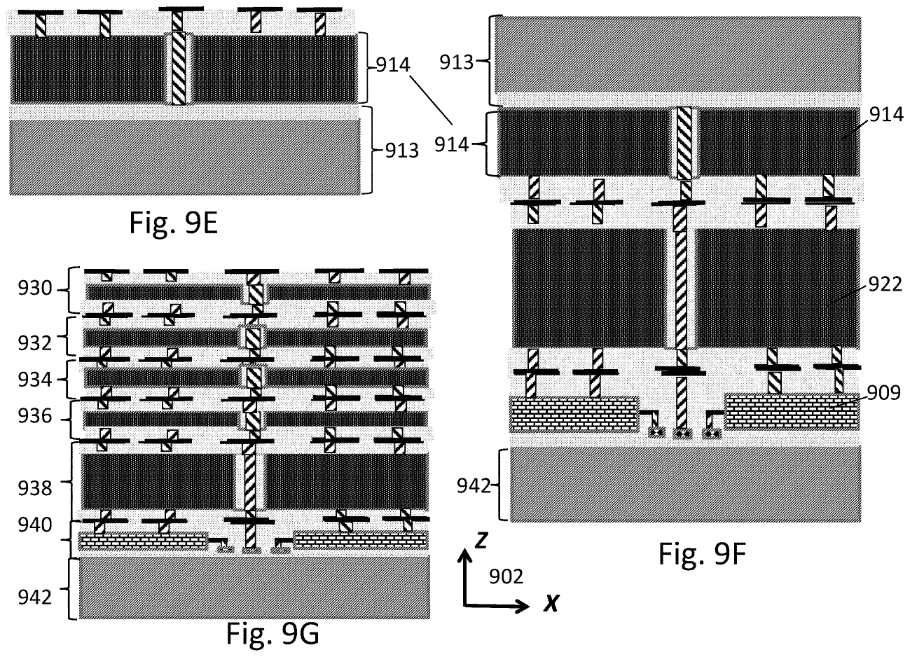

There are many options to form 3D systems using techniques such as been presented herein or in the incorporated by reference art. These techniques could include adding pin/pads over the memory unit such as is illustrated in FIGS. 5A-5D. Such could include stacking a few memory levels one on top of the other forming a 3D memory strata formed by stacking memory levels which could be 2D levels or 3D levels which could be a multilayer memory, for example, such as 3D NAND or 3D NOR and so forth. Such 3D structures could include sharing global memory control lines common between levels and independent layers or level select signal. Such memory 3D structures could be controlled by one or a few memory control layers controlling each of the memory layers using the common memory control pillars and the individual layer selects. Such 3D strata formation flow is presented in reference to FIG. 9A-9F herein.

FIG. 9A illustrates an X-Z 902 cut view of a small region of the memory control strata similar to the one in FIG. 7E. The structure includes a substrate 912 with etch-stop layer 910 and memory control circuits 909. The memory control circuits 909 structure could include ‘bottom’ connections 904,907 in between units for future connection to the processor logic level, and feed-through 905. It also includes over the control circuits the pins/pads 906, 908 for the ‘global pillars’ of the memory control lines. The global memory control connections do not look like pillars as the keep folding over the top of the unit surface to accommodate the relatively low pitch associated with the hybrid bonding.

FIG. 9B illustrates an X-Z 902 cut view of a small region of a 3D memory 922 built over a substrate 926 with etch-stop ‘cut-layer’ 924. As well, the structure includes units feed-through 925 and over the unit bonding pins/pads 920.

FIG. 9C illustrates the structures after transferring the memory structure 913 over the memory control structure of FIG. 9A and removing the substrate 926 such as by grinding and wet and/or dry etch using the etch stop layer 924 for a controlled etch stop.

FIG. 9D illustrates the structures after adding in pins/pads 928 over the 3D memory 922 units using a layout such as illustrated in FIG. 5A-5E.

FIG. 9E illustrates an X-Z 902 cut view of an additional small region of memory 914 built over a substrate with an etch-stop ‘cut-layer’ in between the units' feed-through and over the units' bonding pins/pads.

FIG. 9F illustrates the structure after transferring the 3D memory structure 914 over the structure of FIG. 9D, using hybrid bonding connecting the respective memory control lines such as wordlines, bitlines and so forth, and connecting the feed-through. Accordingly the memory control circuits 909 could be used to control the overlaying memory units of the first strata 922 and the overlaying memory strata 914. The memory strata could be designed with the same memory unit size and the same number of memory control lines and utilize a standard pin/pads layout to enable such system level integration using hybrid bonding. These memory strata could be 2D memory array or 3D memory array. They could be of very similar memory technology or in other cases different memory technology. The memory control could be 2D structure or a 3D structure. Many variations of mix and match could be constructed. As was discussed before the use of global bitlines in a 3D structure needs a control of the level select. Such level control needs to be properly connected in the memory control circuits 909. There are few options to do so such as:
A. Have an individual strata-select with direct connections to the memory control circuits. In such case the internal level select could be connected to a global level select connected to the memory circuits.
B. Each memory strata could have dedicated connections for its level select. It is expected that the number of level selects could be could be less than 100 so allocating area for pin/pad for each of them would be reasonable area overhead.
C. In a case that the objective is to stack the same type of memory strata multiple times then a good choice would be to use the technique presented in respect to FIG. 22A-22B of PCT/US2017/052359, incorporated herein by reference.

FIG. 9G illustrates the structure after removing the top substrate 913, adding pins/pads and repeating the flow by adding more memory strata 934, 932, 930. So the structure could include a carrying substrate 942, memory control strata 940, first 3D memory strata 938 and stack of four memory stratum 930, 932, 934, 936. The structure of FIG. 9G could be used as a memory building block to be integrated with computing logic strata to form a 3D computing structure.

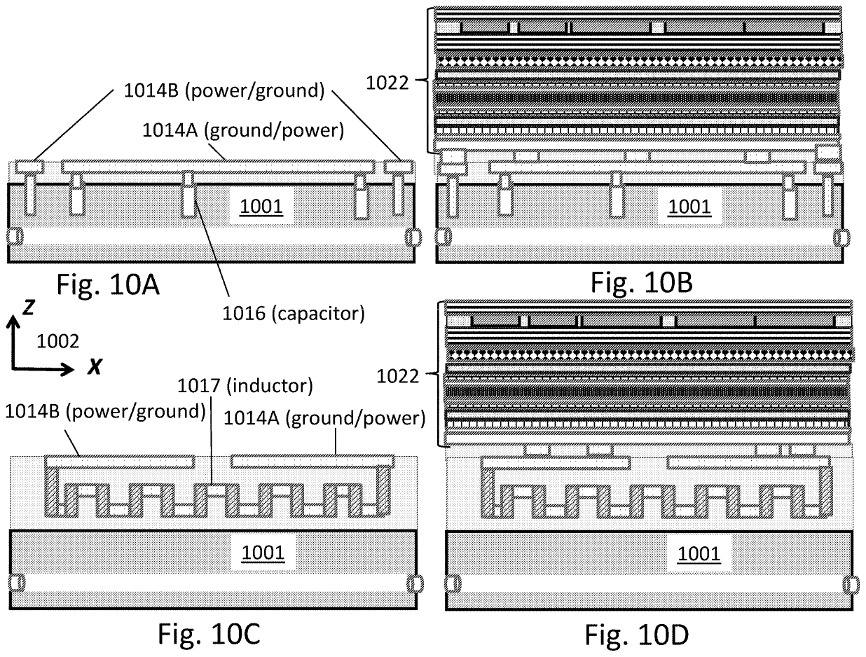

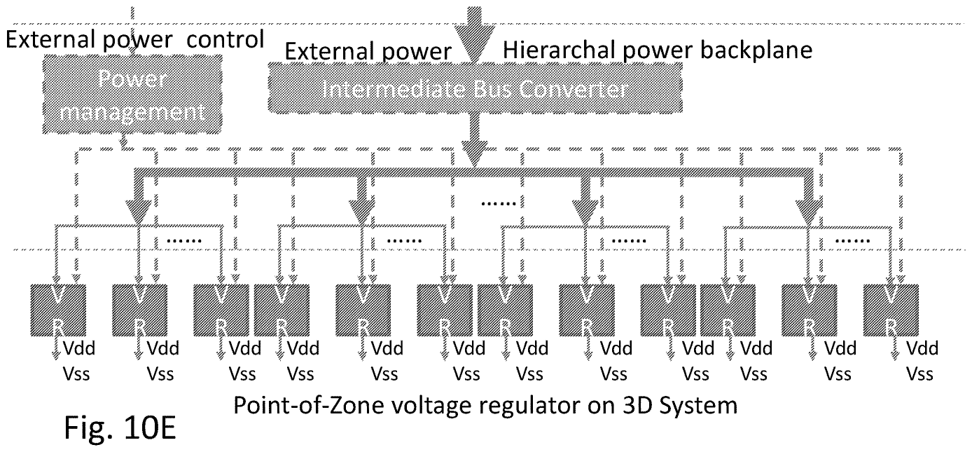

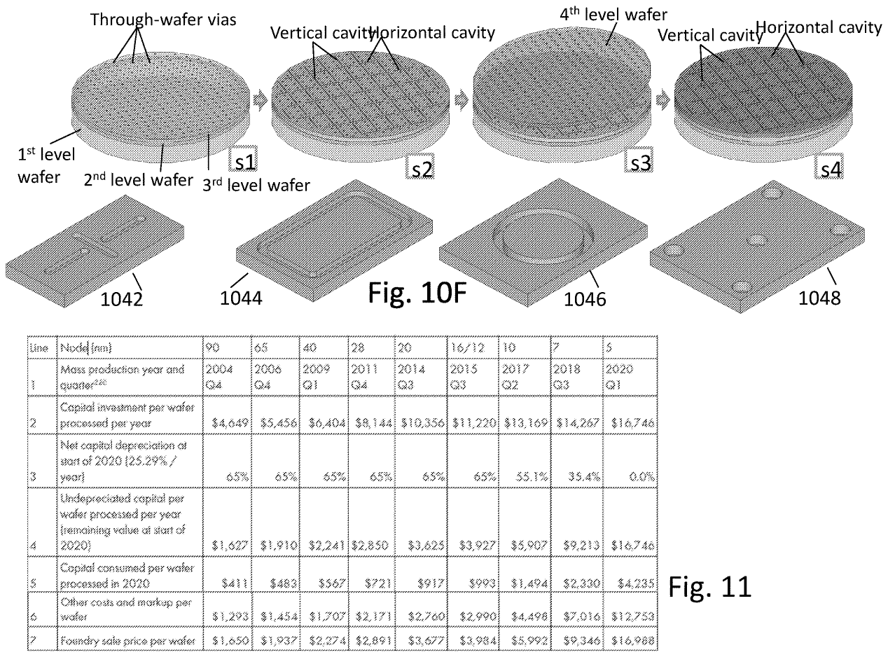

One of the challenges for 3D system having multiple levels of active devices is power delivery. The concept of heterogeneous integration could be extended to include substrate design to support power delivery. FIG. 10A, a vertical cut view 1002, illustrates a substrate similar to the one illustrated in FIG. 7A with added global power delivery structures. Such could include deep trenched capacitors 1016 and power distribution network (“PDN”) 1014. The deep trench capacitor can be formed inside a silicon wafer. In this case, the silicon substrate 1001 would be heavily doped to form a bottom electrode of the trench capacitor as shown in FIG. 10A. Alternatively, the deep trench capacitor can be formed within the oxide. In this case, a bottom electrode is can be a metal liner (not drawn). The structure of capacitor can be one of planar type, crown type, pillar type, or cylinder type. In cylinder type, the top plate electrode can be heavily doped (such as phosphorous or boron doped) polysilicon or silicon germanium. One side of capacitor electrode 1014A would connect ground/power line and another side of capacitor electrode 1014B would connect power/ground line. This could be formed using one thick metal layer, or multiple metal layers. Integrating trench capacitors in the PDN could be an effective way to reduce local voltage variation resulting from the circuits operation. FIG. 10B illustrates the structure after adding on the various levels of logic, memory, EM interconnect levels, and IO level 1022 which were illustrated in FIG. 7A. Such could include hybrid bonding and multiple steps of level transfers.

Another embodiment of this invention is to integrate inductor for power delivery network. Such could include MEMS or CMOS-BEOL based inductor 1017 can be an air, oxide, iron, or ferrite. When ferrite core is being used, the core material can be manganese-zinc, nickel-zinc, iron-silicon, or iron-silicon-aluminum. A structure of the inductor can be spiral type, thin film. One side of inductor electrode 1014A would connect ground/power line and another side of inductor electrode 1014B would connect power/ground line as shown in FIG. 10C. The core material of the inductor 1017, FIG. 10D illustrates the structure after adding on the various levels of logic, memory, EM interconnect levels, and IO level 1022 which were illustrated in FIG. 7A. Such could include hybrid bonding and multiple steps of level transfers.

Another embodiment of this invention is to integrate both capacitors shown in FIG. 10A and inductor shown in FIG. 10C simultaneously for power delivery network.

Power distribution is essential function to provide various voltages and currents to respective units in 3D wafer scale system (3D SYSTEM). The supply voltages could be engineered to be constant with a narrow variation range across the 3D SYSTEM. The power distribution system in 3D SYSTEM is very important for its reliable operation. From a static operation point of view, IR drop is highest near the center of 3D SYSTEM and lowest nearer the Vdd and Vss connections. However, IR drop is a dynamic phenomenon due to the time-varying power demand of respective circuit/memory blocks. In U.S. Pat. No. 8,273,610 in reference to its FIG. 162, the entire contents of U.S. U.S. Pat. No. 8,273,610 is incorporated herein by the reference, a hierarchical power distribution system is supplemented over a 3D SYSTEM. An alternative technique is to distribute a supply voltage that is at least 10% greater than the required voltages of the circuit blocks. The overdriving power supply could be able to accommodate the worst-case dynamic IR drop. Such could include a voltage down converter or voltage regulator which could be distributed to each zone over the 3D SYSTEM, for example, as illustrated in FIG. 10E. The zone herein could refer to a block, die, or unit. The voltage regulator (“VR”) could be a DC-DC converter, Low-Drop-Out (LDO), or other form of power regulators. Such a voltage regulator could be dedicated to stabilize the power supply to its own non-isolated zone. By doing so, the power management could have a high granularity and individually controlled for different load blocks. Another alternative could be a multi-staged distributed power architecture. Another level of power distribution or a single intermediate bus converter could be added between the external power and point-of-zone VR. The intermediate bus converter could be a separate (isolated) voltage regulator, for example, such as a DC-DC converter, Low-Drop-Out, or other forms of power regulators. The intermediate bus converter could be a discrete module that is relatively loosely regulating the external voltage and it could be integrated within the hierarchical power backplane. Alternatively, the point-of-zone VR may have a digital interface and some programmability, where the control takes place through its digital interface from a central controller within a 3D SYSTEM, or the signal(s) into and out of 3D SYSTEM could be an external control signal.

In 3D SYSTEM, a donor wafer and a host wafer can have different coefficients of thermal expansion. The donor wafer to host wafer bonding process should control stress and warpage to engender reliable donor to host connections. The host wafer herein could refer to either a single wafer or multiple level stacked structures. It has been studied in, Qiu, Yuanying, et al., “Thermal Analysis of Si/GaAs Bonding Wafers and Mitigation Strategies of the Bonding Stresses,” Advances in Materials Science and Engineering 2017 (2017), the entire contents are incorporated herein by a reference, that a bonding process at room temperature reduces stress compared to a process that requires an elevated temperature; as well, the study showed that bonding a thinner wafer, such as less than 1 μm-thick, reduces stress compared to bonding of a thicker wafer. Stress could also be dynamically occurring during the operation of a 3D SYSTEM in the field due to uneven heating of the structure during operation. Furthermore, as multiple wafers are stacked the stress could accumulate, at least proportionally greater as a number of levels increase. Techniques to help via an intentional stress release mechanism could be integrated in such 3D SYSTEM as is illustrated in FIG. 10F. Step s1 shows a host wafer with three levels stacked and connected with neighboring levels with through wafer via such as through silicon via (TSV) or nano-TSV. In order to incorporate a damping function to mitigate stress accumulation, arrays of stress damping trenches aligned in horizontal and vertical directions are patterned as shown in Step s2. Then, another wafer is subsequently bonded and transferred onto the host wafer as shown in Step s3. According to a desired number of levels, a stress damping trench is formed on the uppermost level as shown in Step s4, followed by subsequent wafer transfer(s). Other types of stress release structures, for example, such as trenches or holes could be formed such is illustrated in SR(Stress Relief) structures: dis-continuous linear SR trenches 1042, square or rectangular SR trenches with rounded or champhered corners 1044, circular or ellipsoidal SR trenches 1044, and stress damping SR holes 1048.

Level transfer and hybrid bonding may need special interconnect layer for the formation of pad/pins as illustrated in FIG. 5A-5E. Forming such structure underneath the active circuit could require first to perform a level transfer and substrate removal as is for example illustrated in FIG. 9B-9D. Wafer processing costs is highly dependent on the type of process line used as is illustrated in the table of FIG. 11. The table of FIG. 11 was published in APRIL 2020 in a report titled “AI Chips: What They Are and Why They Matter, An AI Chips Reference”, Authored by Saif M. Khan, Alexander Mann, incorporated herein by reference. It shows order of magnitude cost and price difference from 90 nm line to 5 nm process line. Accordingly it might be useful to construct special coupling level which could include electronic alignment capabilities similar to those presented in reference to FIG. 1A-FIG. 3C, of PCT/US2018/052332, incorporated herein by reference. Such coupling level could help building a heterogeneous integrated 3D system in which a memory level could in between unit bottom pins similar to 907 of FIG. 9A and over the units top pads such as 906, 908. Using the coupling level the in between units pins 907 could be coupled to over the circuits pads structure like the one illustrated in FIG. 5A, just using hybrid bonding.

A 3D system like 700 could be constructed with all of the level been custom made for that specific system or with many of the levels being generic utilizing an agreed standard for pin/pads location and unit size. Accordingly the coupling level could be made to comply with such 3D heterogeneous integration standard. In some cases, the over the circuit pin/pad location could be part of a standard while the in-between unit pin/pads or control line could be left custom to better fit the specific memory or other type of circuit technology.

FIG. 12A is a section X-Z 1202 cut view of coupling level. Over a removable substrate 1204 a switchable bottom pin/pad 1218 are constructed following the concept presented in reference to FIG. 1A-FIG. 3C, of PCT/US2018/052332. The transistor selection 1216 could be similar to the illustration FIG. 12B which is of FIG. 2E of PCT/US2018/052332. The selected signal, called there BL1-BL4, could be connected to over the circuit pin/pad structure 1214, which could be formed according to a standard. The coupling level could have a very simple control circuit 1212 to perform the electronic alignment selection such as between GLS to GRS. The structure could include larger pin/pads for power supply connection, not shown. The control circuit 1212 could utilize two connected test pin/pads in the target level to measure connectivity and accordingly select between which GLS to GRS. Additional larger pin/pad could be use to connect optional level select control pin. Such level select control signal could be used to disable both GLS and GRS. Such level select could be useful for a case in which it is harder to form level select in the target wafer as presented in respect to DRAM as discussed in reference to FIG. 26A of U.S. Ser. No. 16/558,304, incorporated herein by reference.

While use of a coupling level with level select or the technique discussed in reference to at least FIG. 26A of U.S. patent application Ser. No. 16/558,304 (U.S. Patent Publication 2020/0176420 A1) are an alternative to level select within a memory level, it might be preferred to add the required additional process step for the memory level process in order to have level select within it. The type of level select could be engineered as part of the design of such M-Level. Such a design could accommodate single transistor types such as n-type and some relaxed select transistor spec compensated by other element of the M-Level such as design of the sense amplifier to support in memory level, level select as presented in reference to at least FIGS. 22C-22E of U.S. patent application Ser. No. 16/558,304 (U.S. Patent Publication 2020/0176420 A1).

FIG. 12A illustrates the coupling level ready to be hybrid bonded to an over the circuit pin/pad structure. If the need is to bond to in-between pin/pad structure then a carrier wafer could be used to flip the structure so it will bond first to in-between pin/pad structure.

The use of level transfer in 3D integration is often referred to as parallel device integration rather than sequential integration. In parallel device integration, both wafers are processed separately (usually after transistor formation and some metallization) and then after, integrate them using a major process step, for example, such as, with hybrid bonding. This concept could be further extended to a method to integrate a 3D system, for example, such as, in reference to FIG. 7A herein. Such a 3D system may utilize more than one type of memory and memory technology accordingly. The most common memory in computing systems are SRAM or Ferro Electric memory being developed by FMC for the ultra-fast memory such as cache, DRAM for the majority of the fast memory such as main memory, and NAND flash for the high density memory such as data storage. Systems may include NOR type flash for the program code storage and other types of memories such as cross-point memory, MRAM, or RRAM. In a 3D heterogeneous integrated system, these memories could be integrated by level transfer of a memory wafer processed in the proper wafer fab line utilizing the specific processing required for that memory technology. The parallel integration process could be used to accomplish the integration in phases. A First phase could be processing the needed wafers in the proper fab line which may include front end of line processing (transistors) and back end of line processing (interconnects). The Second phase could include level transfer to form a ‘master level’ or ‘memory level’, which could be called the M-Level.

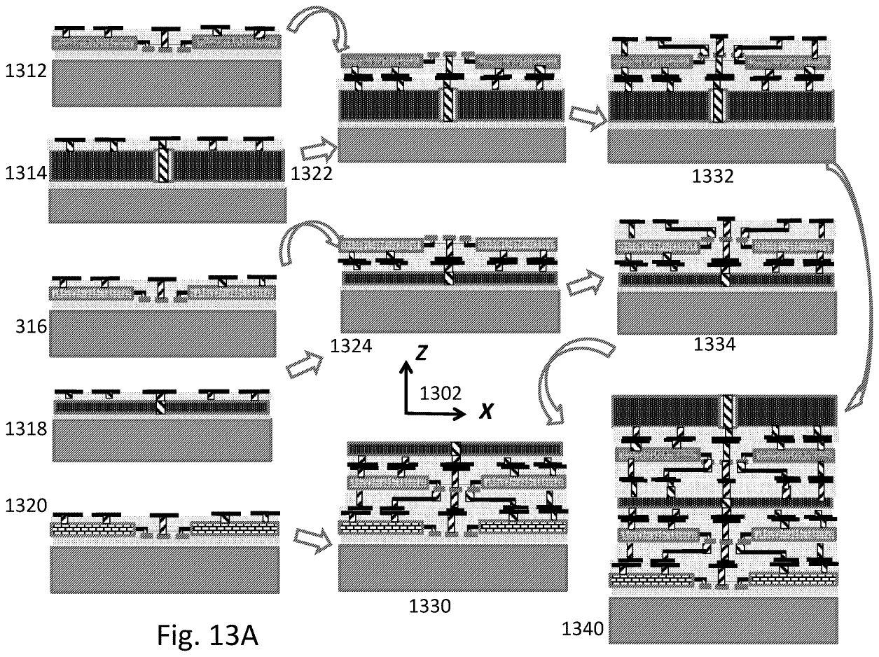

Accordingly a memory control wafer (perhaps formed via the first Phase) could be transferred on top of the memory wafer (perhaps formed via the first Phase, likely in a different fan line) to form an M-Level wafer. M-Level wafer may be stored whilst awaiting use in a 3D system. After the formation, and perhaps stockpiling of M-level wafers, these M-Levels could be transferred and integrated to form a desired 3D system, as one example is illustrated in FIG. 13. The memory control could comprise circuits (also known as ‘memory periphery’ especially in 2D devices) such as decoders, sense amplifiers, charge pumps, self-test logic and similar memory control circuits. It could include vertical connections to the memory level providing the word-lines, bit-lines, level select and so forth. The memory control could use hybrid bonding connection techniques such as been presented in reference to FIGS. 4A-4C, FIGS. 5A-5E and FIGS. 12A-12B herein, and FIG. 21A to FIG. 27D of U.S. patent application Ser. No. 16/558,304, publication 2020/0176420, and FIG. 1A to FIG. 3C of PCT application PCT/US2018/52332, all incorporated in their entirety herein by reference.

FIG. 13A is an X-Z 1302 side view illustration of a wafer region. It illustrates a phased integration of a 3D system. In the first phase, each of the wafers is processed in its respective process line such as a logic line for the processors level 1320, DRAM line for the fast memory 1318, DRAM memory control 1316, 3D NAND line for the high density memory 1314, and 3D NAND control logic circuits 1312. Alternatively, DRAM memory control logic wafer 1316 can be processed from a logic fab which is different from the DRAM line. Likewise, 3D NAND control logic wafer 1312 can be processed from a logic fab which is different from the 3D NAND line. DRAM memory wafer 1318 may include only memory cells. Alternatively, DRAM memory wafer 1318 could include memory cells and some core logic function such as sense amplifier and row/column decoder. 3D NAND wafer 1314 may include only memory cells. Alternatively, 3D NAND wafer 1314 may include memory cells and some core logic function such as sense amplifier, row/column decoders, and control line select gates. The DRAM memory control logic circuit 1316 and 3D NAND control logic circuit 1312 includes at least one of data buffer, address buffer, control buffer, mode resistor, error-correction control circuit, built-in test.

In the second phase, the M-Levels are formed by flip and bond (hybrid bond) the DRAM control circuit 1316 over the DRAM circuit 1318 and substrate backside cut such as by using at least one of etching, grinding, or polishing the DRAM control substrate resulting in a bonded structure 1324, and adding in the pin/pads level resulting in M-Level for the DRAM 1334. Similarly flip and bond the 3D NAND control circuit 1312 over the 3D NAND circuit 1314 and substrate backside cut such as by using at least one of etching, grinding, or polishing the 3D NAND control substrate resulting in a bonded structure 1322 and adding in the pin/pads level resulting in M-Level for the DRAM 1332. Then in the third phase, the DRAM M-Level 1334 is flipped and bond over the processor level 1320, cut the DRAM substrate resulting in a bonded structure 1330, then add in as needed pin/pads structure and follow by flip and bond the NAND M-Level 1332 over the structure 1330, and cut the NAND substrate resulting in a bonded structure 1340.

The memory control signals such as data path, address, and commend lines could be shared between DRAM M-Level 1334 and 3D NAND M-Level 1332. The DRAM M-Level 1334 and 3D NAND M-Level 1332 could have their own dedicated control signals.

FIG. 13B is an X-Z 1302 side view illustration of an alternative phased integration to form a 3D system. M-Level for the DRAM 1334 and M-Level for the 3D NAND 1332 may be processed separately and perhaps banked. The DRAM M-Level 1334 and 3D NAND M-Level 1332 are flipped and bonded over the processor level 1320 in, for example, a side by side arrangement (other arrangements are possible, touching edges, only touching one corner, etc., all determined by engineering and manufacturing considerations), forming 3D system structure 1350.

It should be noted that the use of DRAM or 3D NAND herein is representative of high speed/volatile memory or high density/non-volatile memory. As other memory technologies are becoming useful, for example, such as SRAM, cross-point memory, PCRAM, RRAM, FRAM, and MRAM, these memories could be integrated in a 3D System just as well as the presented concept.

As previously presented, a 3D system could be constructed utilizing industry standards for unit size and pin/pad locations. The use of structures such as the M-Level could allow adhering to the standard while keeping flexibility for system architecture. Such could be the aggregating of multiple units in an M-Level for a specific application by that level control circuit.

Such a flow could have many variations including where within one M-Level are included multiple memory levels first being bonded to form first a 3D memory structure such as presented in reference to at least FIG. 21H, FIG. 25C, FIG. 25J, and FIG. 26A of U.S. patent application Ser. No. 16/558,304, publication 2020/0176420, incorporated in its entirety herein by reference.

With an M-Level integration the 3D system vertical connectivity per unit could be scaled down to a bus format. Accordingly, the vertical bus connectivity could include address lines which could be decoded to the word-lines, bit-lines by the memory control circuits of each M-Level. The system level vertical connectivity per unit could count about a hundred lines rather than thousands of lines. The feed through concept such as feed-through per units 718 of FIG. 7B herein could be used for such vertical per unit bus. The vertical lines or pillars could be allocated, for example, to 32 data, 34 Addresses, 4 system types, 16 controls, and 14 feed-throughs. Specific systems could use more or less than 100 pillars lines bus per unit. Such vertical busses could utilize techniques common in the industry for computer system busses, such as multiplexing data or address lines or use of an industry standard such as AMBA, Avalon and so forth. A range of industry On-Chip bus standards are reviewed in a paper by Mitić, Milica, and Mile Stojčev. “An overview of on-chip buses.” Facta universitatis-series: Electronics and Energetics 19.3 (2006): 405-428, incorporated in its entirety herein by reference.

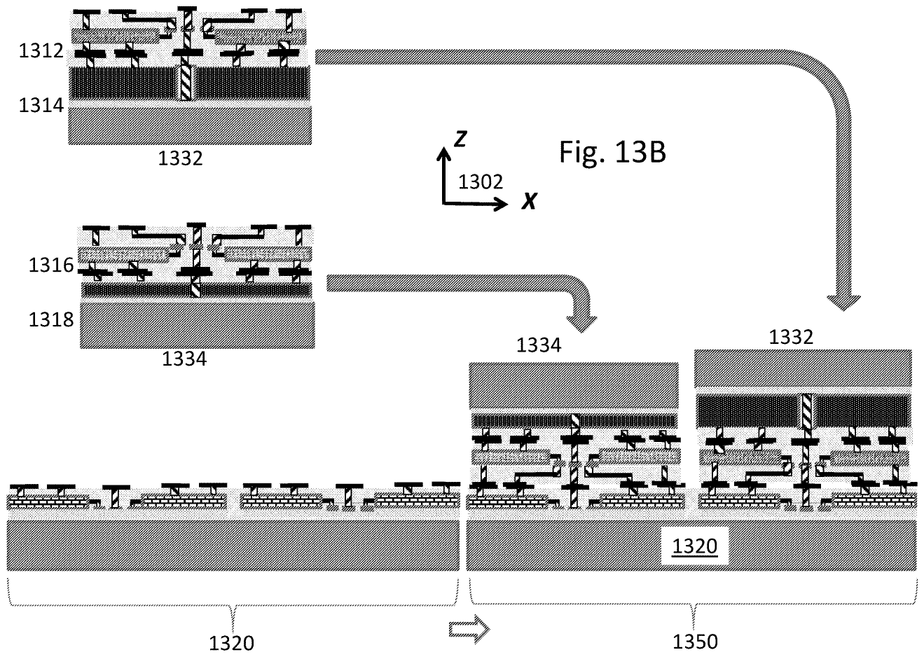

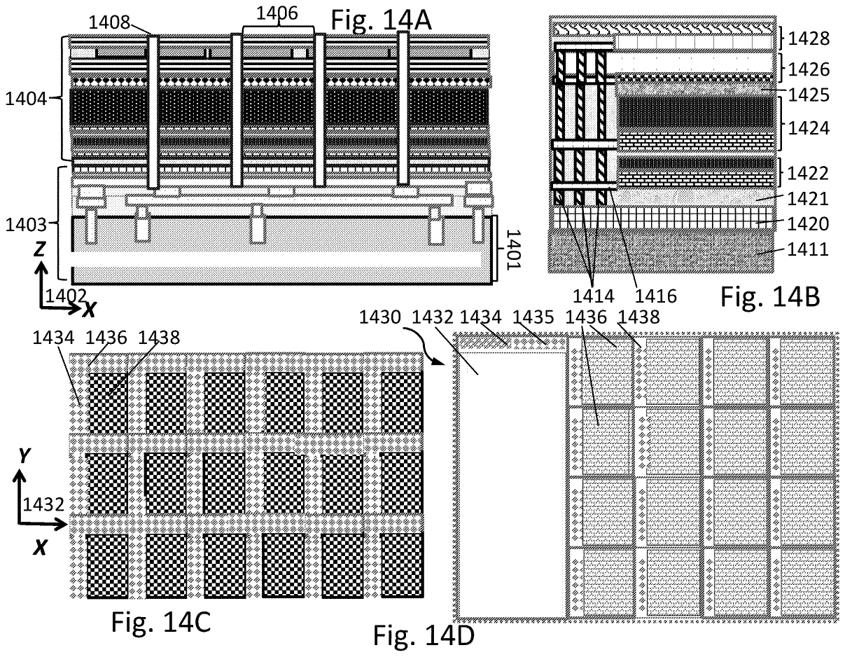

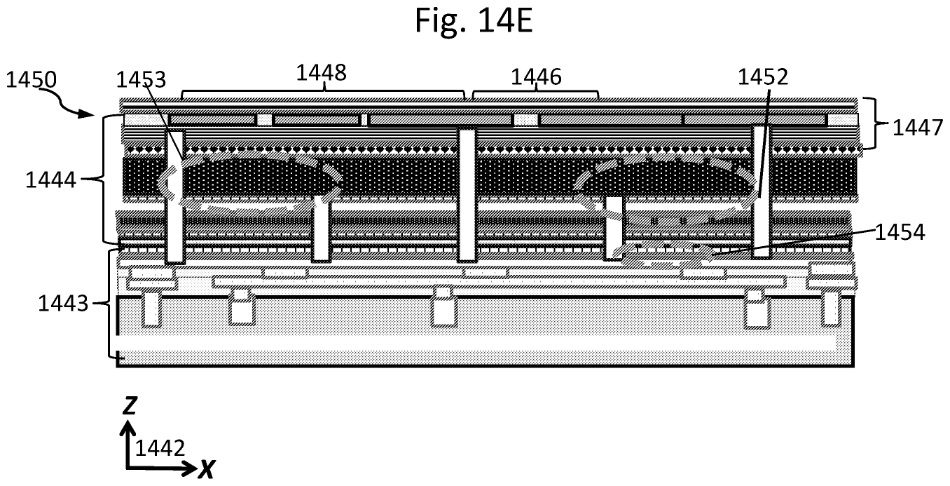

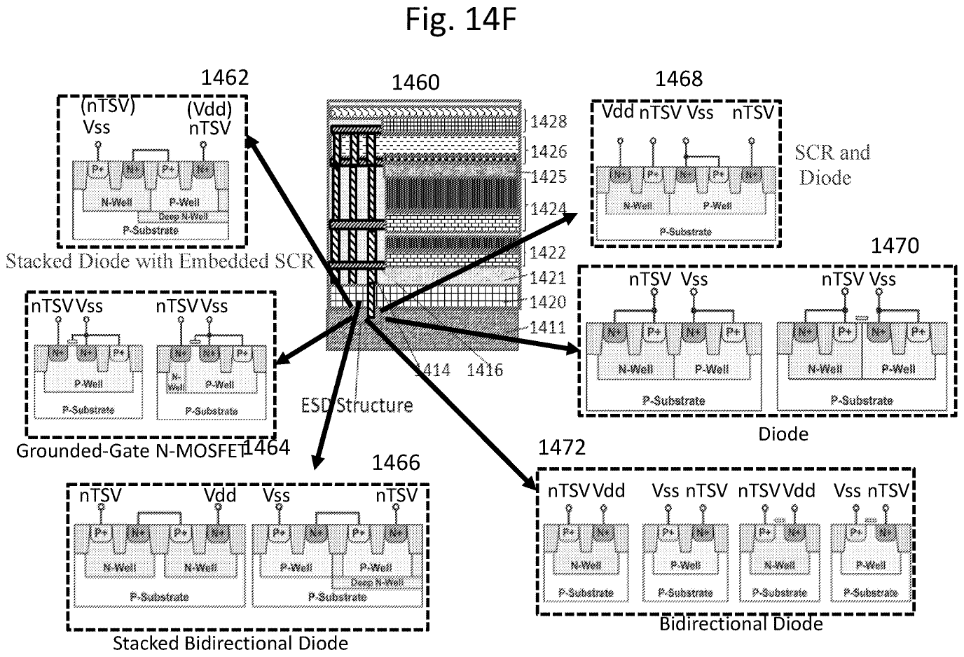

FIGS. 14A-14B are vertical X-Z 1402 cut view illustrations of a region of such 3D system, at different scaling factors. FIG. 14A shows few units 1406 and the vertical bus 1408 in-between. The 3D system could be constructed over a functional substrate 1403 including a heat removal structure, trench capacitors or integrated inductors, and power distribution network(s) as previously discussed and a stack of heterogeneous integration of levels and M-levels 1404 as previously discussed. In addition to the vertical bus the system could include a power bus to support distribution of power to the various levels. The vertical power bus could be in the same unit side or at the others sides. Other vertical common pillars could be used, for example, such as a common clock, and test signals. The unit side size could be 200 μm as often referenced herein or other sizes including different sizes both in X direction and in Y direction, for example, such as about 0.1 mm. about 0.2-0.4 mm. about 0.4-0.8 mm, about 0.8-1.2 mm, about 1.2-1.6 mm, about 1.6-2.2 mm, about 2.2-3.5 or even larger than about 3.5 mm.

FIG. 14A illustrates the use of redundancy for the vertical pillars 1414 for such bus common vertical connectivity. FIG. 14B shows that three vertical pillars 1414 are carrying the same signal of the vertical bus and are wired together to common horizontal signal 1416 fed into the M-level to be used. The M-level control circuit could include decoders and other control circuits including bus de-multiplexing, level select, power generation including voltage pumps circuits and other circuits such as often called memory periphery circuits.

FIG. 14B illustrates a portion of a 3D system having a functional substrate 1411, a processors level 1420, a high speed M-level 1422, a high density memory M-level 1424, horizontal electromagnetic interconnect M-level 1426, and input output M-level 1428 to connect the 3D system to external devices. The 3D system could also include a thermal isolation layer 1421 to isolate the processor heat from the overlaying memory level, and shielding layer 1425 to protect the underlying levels from the EMI noise that could be associated with the electromagnetic interconnect M-level 1426.

The 3D system of FIG. 14A-14B could include coupling level(s) such as previously discussed or a coupling level to interface the industry standard used in the system to a level or M-level built for other standards. Such a coupling level could be considered as standard to standard coupling level.

FIG. 14C is a horizontal cut X-Y 1432 illustration of a region of a 3D system, showing a sub array of 6×3 units 1438 with their associated side vertical pillars of bus lines 1434 and 1436; these could include their redundancies pillars. While FIG. 14C illustrates the vertical bus pillars 1434, 1436 as blocking the gap between units it could be expected that the design of such 3D system could be made to support connectivity X-Y connectivity between adjacent units and across units (not shown). These designs could be made by engineers in the art to accommodate the tradeoffs associated with the vertical pillars, pin/pads design rules and number of vertical pillars and their redundancies, unit size and other system considerations and design rules.

Additional alternative to accommodate bonding misalignment while still using hybrid bonding could be the technique presented in reference to at least FIGS. 93A-94C of U.S. Pat. No. 8,395,191, incorporated in its entirety herein by reference.

An additional advantage of the use of M-level concept is for pre-testing. In reference to at least FIG. 86C of U.S. Pat. No. 8,395,191, incorporated in its entirety herein by reference, a concept of contact-less or wireless testing has been presented. Such could be used to perform testing of an M-level designated to be integrated to a 3D system. Probe test or other form of tests including use of self-test and scan based testing could be used to test a level and mark any unit that has a fault that could not be overcome by the unit level redundancy. Such pretesting could be an important part of 3D system integration to enable overall system yield. Furthermore, M-Level may include post-package repair function by containing redundancy rows and columns of memory cells, address map/re-map blocks, built-in test, anti-fuse. M-Level may even further include soft-post package repair circuit. In addition, M-Level may also include on-chip error-correction circuits.

In such manufacturing operation there are multiple advantages and operational alternative options following such levels and M-level tests prior to performing the 3D integration using, for example, such as hybrid bonding. One option is to select high yield levels and M-levels for 3D integration while lower yielding levels could be used for other applications such as standard memory products or other standard functions. The lower yielding level could be integrated also in 3D techniques to a structure with fewer levels in which such yield loss could be acceptable or repaired. Another option is to performing matching of levels to maximize the 3D system yield by matching levels for minimal yield loss by aligning the faults so as many faulty units are overlaying other faulty units. The unit based 3D system architect in which each units has its own vertical connectivity and power delivery could be used to support functional overall system even if some of the units do have faults and should be disabled. This could be considered as a redundancy or agile system reconfiguration. So, using test such as scan based or other types of Build-In Test (“BIST”) the system disables units that could not be repaired with their built-in redundancy.

FIG. 14E vertical X-Z 1442 cut view illustrations of a region of an alternative 3D system 1450 which includes a mixed ‘grain’ M-level 1444 and functional substrate 1443. In such alternative the upper region of an M-level could have courser unit partitions 1448 than the lower level partitions 1446. The upper M-Level could include a level or levels which includes high density memory, for example, such as, 3D NAND type memory. Such memory is associated with far longer access times and could support the system performance with reduced vertical connectivity. Other variation of the 3D system modularity could be useful in some applications.

An additional option with the 3D system is illustrated in FIG. 14E is to move the process rather than the data, namely a memory centric architecture. For years the common practice has been to bring the data to the processor to compute a required instruction. As the amount of data keep growing, an alternative approach could be more efficient and it is to bring the processing units to the data. In a 3D system as presented herein, a massive amount of data could be stored in the 3D system, forming pooled memory. As an example, the data related to the U.S. (United States) could be stored in locations marked by US data (bubble) 1452 and data related to Europe could be stored in locations marked by Europe data (bubble) 1453. So if a search or other operation is to be done to U.S. data, the proper program could be transferred to the processors close to the U.S. data, marked by close processors (bubble) 1454. In some systems the processor could include programmable logic such as FPGA gates and related structure of programmable logic. Accordingly, the proper bit-stream to program the configurable logic could be transferred to the close processors (bubble) 1454 in proximity to the data designated for the processors 1452. Another variation of this concept could be for solving a problem in which a massive amount of data is required to be processed and then followed to a follow-on process such as in deep neural network. In such case it might be more efficient to store the processed data near to the original data (bubble) 1452 and move in a new program to the close by processors (bubble) 1454 for the next processing step. Thus, processing energy will be significantly lower due to the close proximity of data and processor, and the raw performance will be greater.

The processors level could itself be an M-Level with the processor program memory and L 1 cache level could be integrated using 3D technologies as been presented here and in the incorporated by reference art.

The 3D system as has been presented herein in reference to FIG. 13A to FIG. 14E is about various heterogeneous constructions of a modular 3D system. The M-Levels may have very high connectivity between the memory control level and the memory level with hundreds or thousands of vertical connections per unit for the bit-lines and the word-lines, and additional control as needed for example, such as, level select. Such vertical connectivity could utilize hybrid bonding and pin/pads structure(s) similar to the one presented herein in reference to FIGS. 5A-5E, or such as has been presented in reference to at least FIG. 21H, FIG. 25C, FIG. 25J, and FIG. 26A of U.S. patent application Ser. No. 16/558,304, publication 2020/0176420, incorporated in its entirety herein by reference. It could also use techniques such as been referenced herein, such as, for example, as electronic alignment. It could also use other techniques such as been reference as smart alignment in the incorporated by reference art. Such rich vertical per unit connectivity could be used within the M-Levels, while at the 3D system far more relaxed vertical connectivity could be used leveraging the vertical bus per unit concept—reference, for example, FIG. 14A-14C herein. Accordingly each level in the 3D system could support the vertical connectivity of the bus per unit. Some levels could support it as a feed-through and others also via a connectivity bus or busses between levels in the system. Reference to FIG. 7G the vertical bus signal 758 is illustrated as feeding the memory control 739 of the M-Level and also as feeding through 755 to the memory level 752. As previously discussed, the design of a memory level could include the design of the feed-through pillars to support the connectivity of the vertical per unit system bus. Accordingly the 3D system could include moderate vertical connectivity per unit such as about hundred pillars per unit bus and rich connectivity within the M-Levels such as a thousand pillars per unit to support the connections between the memory control level and the memory array of the word-lines and bit-lines 753. Different vertical connectivity techniques and alignments techniques could be used for the vertical busses and the per M-Level internal vertical connectivity.

In some 3D systems the vertical connectivity could include more than one vertical bus per unit. These vertical buses could have different functions, for example, such as one vertical bus connecting memory M-Levels to the processors level which could be called M-bus. And an additional vertical bus connecting the X-Y connectivity M-Level to the processor level which could be called C-Bus. For example, the M-bus in some systems might not even be extended to the X-Y connectivity M-Level, and the C-bus in some systems might not just feed through the memory M-Level. The C-bus could be similar to the M-bus or very different, for example, such as utilizing different industry bus standards and so forth. The bus per function could be extended to a bus for high speed memory which could be called SM-bus and a bus for high density memory which could be called DM-bus. The SM-bus could be designed for high speeds, for example, such as using a wide data within the bus of more than 16 pillars for data while the DM-bus could be designed for high integrity with, for example, built-in redundancy and error correction features.

In some systems the unit could have subunits such as been illustrated in FIG. 14D, an X-Y 1442 cut view illustration of an example of a unit 1430 with sub-unit for communication processor 1432 and 16 sub-units 1436 of AI processors. The communication processor 1432 could have a C-bus 1434 for communicating with the X-Y connectivity M-Level, and a M-bus to connect it to its overlaying memory. The AI processors 1436 could have an M-bus to connect it to its overlaying memory. Additionally the processors level could have a horizontal bus (not shown) connecting the AI processors to the communication processor 1432. The sub units 1436 could have a side size of 100 μm or other sizes as was referenced herein previously for unit size. The system could include a mix of different types of units optimized for the different type of tasks. Many other variations of these concepts could be designed by an engineer in the art to construct a 3D system capable of efficient parallel processing and also serial processing with across-the-system effective connectivity.

An additional alternative is to extend the M-bus to far larger number of data pillars, for example, such as 80, 160 or even more than 320. Such extended M-bus increase the data communication between the processing level and the memory level for supporting an increase in overall processing speed/performance.

With an extra wide data within the bus and units level partition of the memory array, a memory level based on 3D NAND technology could provide a reasonable data rate to serve in the role of high speed memory for the system. Such 3D NAND technology could be modified to utilize extreme thin tunneling oxide, thereby giving up retention time to gain faster write and erase time and far better endurance as discussed in at least U.S. Pat. No. 10,515,981 and PCT application PCT/US2018/016759, incorporated herein by reference. Modifying 3D NAND technology for Ultra-Low Latency memory is been practiced in the industry by Samsung with their product line called Z-NAND. Such a concept could be further enhanced by use of extremely thin tunneling oxide, a very wide data bus, and partition of the memory array to hundreds of units leveraging stacking of memory control over the 3D NAND memory arrays as has been presented herein and in some of the incorporated references.

In general, the 3D system presented herein could resemble prior systems which used to connect chips and packages employing Printed Circuit Board (“PCB”). Many of the system architectures of those PCB integrated systems could be mapped to the vertical 3D system presented herein.

The M-Level concept could be extended beyond memory to other functional elements of the 3D system. Such could be the X-Y interconnect using electromagnetic waves. Connectivity M-Level could include a control level, modulation and decoding level and the transmission lines/waveguides levels. So the bus vertical connectivity could be used by the X-Y interconnect controller which could then propagate the information to the X connectivity channels and the Y connectivity channels.

For a thin wafer transfer process, electrostatic chuck is becoming popular as a wafer hander due to its long-term electrostatic holding capability and reversible attachment of thin wafer. When stacking wafers to configure wafer scale 3D systems as shown in FIG. 13A degradation of a transistor oxide could occur due to electrostatic discharge (ESD) current stress. Such gate oxide degradation could result in functional failure and lead reduced lifetime. In order protect the gate oxide from hybrid bonding process of nano-TSV, an ESD protection function could be connected to the nano-TSV. FIG. 14F illustrates a magnified view of ESD protection function connected to the nano-TSV and internal logic. There are multiple ESD structure know in the art which could be utilize to support 3D System manufacturing. These ESD structure are commonly quite large. Herein, nano-TSV and vertical bus pillar could be referred interchangeably. For 3D System and to support vertical bus pillars as is illustrated in FIG. 14B, these structures could be scaled down by factor of 1:10 or even 1:100 to be laid in a rectangular of about 1×1 μm² or if multiple vertical pillar 1414 are designated to support the same signal as redundancy such as in FIG. 14B. Then, a common ESD could support them and could have a rectangular size of about 2×2 μm². FIG. 14F illustrates the structure of Fig. B 1460 with multiple ESD alternative structure 1462,1464, 1466 1458, 1470, 1472. Depending on the type of wafer face side to be bonded, the connection could be front-to-front, front-to-back, or back-to-back. The ESD protection function could be a single device or a circuit. The ESD protection function shunt or bypass ESD current with limited voltage drop. In conventional CMOS, the ESD protection for I/O pads are widely used as shown in, and incorporated herein as references, Lin, Chun-Yu. “Low-C ESD Protection Design in CMOS Technology.” Electrostatic Discharge—From Electrical breakdown in Micro-gaps to Nano-generators. IntechOpen, 2019 and Wang, Albert Z H. On-chip ESD protection for integrated circuits: an IC design perspective. Vol. 663. Springer Science & Business Media, 2006. Similar ESD devices or ESD circuits could be used in this invention. Assuming that the internal circuit operates between Vdd and Vss, EDS function does not turn on in the normal voltage region. The ESD function shunts ESD current for the ESD induced voltage greater than Vdd. A common ESD protection function could be a diode, MOSFET, silicon controlled rectifier (SCR), and their combinations as exemplified in FIG. 14F. Several options, but not limited to, are illustrated as a cross-section view. An option of ESD function could be the Grounded Gate N-type MOSFET 1464, where the gate, source, and body are grounded to keep it off during normal operation. Such type of ESD is previously studied in, Lee, Jian-Hsing, et al. “The dynamic current distribution of a multi-fingered GGNMOS under high current stress and HBMESD events.” 2006 IEEE International Reliability Physics Symposium Proceedings. IEEE, 2006, incorporated herein as reference. Another option of ESD function could be silicon controlled rectifier (SCR) 1468, which consists of PNP BJT and NPN BJT. A positive-feedback mechanism of cross-coupled PNP and NPN results in ESD shunt. The NPN and PNP BJTs could be bounded by either shallow trench oxide or a dummy gate. Such type of ESD is previously studied in, Ker, Ming-Dou, and K-C. Hsu. “Overview of on-chip electrostatic discharge protection design with SCR-based devices in CMOS integrated circuits.” IEEE Transactions on device and materials reliability 5.2 (2005): 235-249, incorporated herein as reference. Another option of ESD function could be a SCR device with trigger terminal connected to the base of one of BJT. The trigger terminal could further be coupled with another device such as gate of MOSFET, substrate, and a diode. The example of GGNMOS-coupled SCR is drawn as an example 1464. A diode type ESD forms unidirectional discharging path. Dual-diode type ESD 1470, which uses two unidirectional ESD devices, could form a bidirectional discharging path. In CMOS process, n-type well and p+ diffusion and p-type of well and diffusion can result in bidirectional ESD as drawn in Bidirectional Diode. n+ and p+ diffusion region could also be separated by either STI or dummy gate. In another example of ESD, the diodes could be stacked to reduce parasitic capacitance or provide higher trigger voltage as drawn in Stacked Bidirectional Diode. Such type of ESD is previously studied in, Son, Minoh, and Changkun Park. “Electrostatic discharge protection devices with series connection using distributed cell-based diodes.” Electronics letters 50.3 (2014): 168-170, incorporated herein by reference. In another example, a SRC could be embedded within a stacked diode as drawn in Stacked Diode with Embedded SCR 1462, as previously studied in, Lin, Chun-Yu, et al. “Improving ESD robustness of stacked diodes with embedded SCR for RF applications in 65-nm CMOS.” 2014 IEEE International Reliability Physics Symposium. IEEE, 2014, incorporated herein by reference. Another example of ESD offers the bidirectional discharging in a single ESD device. A cross-sectional drawing in SCR and Diode shows that the SCR paths is responsible for ESD discharging between nTSV and Vss and the diode path is responsible for ESD discharging between nTSV and Vdd.

A mini ESD which could be such as about 1:100 of conventional ESD could be integrated at each M-Level to support their vertical bus pillar. M-Level could be designed to be pre-tested to support various integration strategy as previously discussed. Testing process could be associated with electrostatic charge and proper ESD could be important to support M-Level pre-testing and integration strategies. If needed a full level with conventional ESD could be integrated as an ESD level for application which may need protection from high voltage ESD. The scale down ESD could be design by engineer in ESD design to support such M-Level according to the design choice of that M-Level silicon final (after transfer bonding and thinning) substrate thickness.

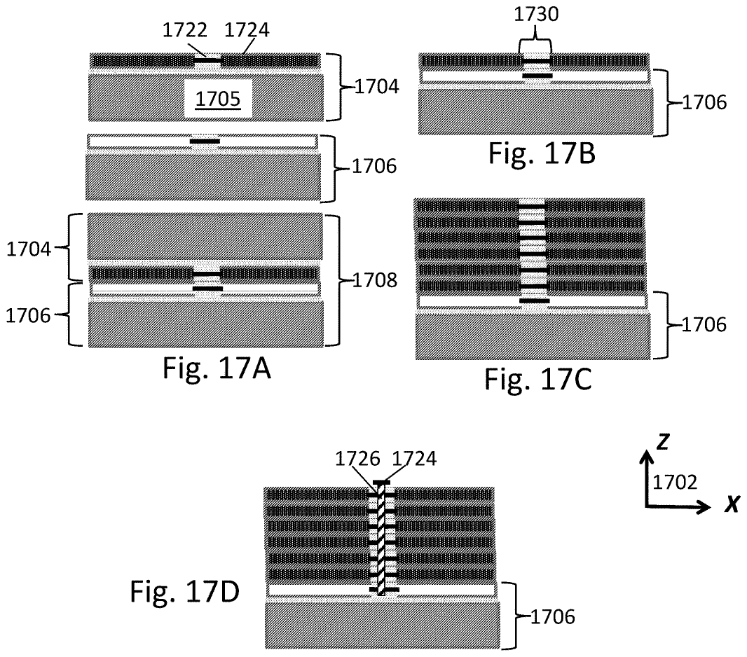

Wafer scale 3D systems as presented herein would likely need redundancy and yield repair or yield agility to become a commercially viable technology. Such has been presented herein and in the incorporated by reference art including multiple techniques such as in reference to FIGS. 35A-35C, FIGS. 38A-38C of U.S. patent application Ser. No. 16/558,304 (publication 2020/0176420), incorporated herein by reference. Additional 3D based redundancy and repair technology has been presented in reference to FIG. 17 and FIG. 24A to FIG. 44B of U.S. Pat. No. 8,994,404, incorporated herein by reference. Each M-Level in the 3D system could include its own self-test and repair technology, as is known in the art for memory and mission critical circuits. Additional techniques for 3D systems could include adding redundancy M-Level such as a second back up level for the X-Y connectivity M-Level. Or adding a redundancy vertical bus per unit. These redundancy levels could be connected in so they are used to enhance the system and provide fault tolerance, agility for defects, and graceful ageing.

The 3D system as presented herein is utilizing many units which have processor memory and able to interconnect utilizing X-Y connectivity level. Such systems are sometimes referred to as a ‘network on chip’ (NoC). Such a system could manage defects by either calling spare units to be activated to replace defective units or provide an advance task allocation capability to distribute the work load to the available good operational units. Concepts for such complex systems with self-repair and operational agility are well known in the art and are in use such as with server farms and other multi computer systems. Such technologies could include use of a circuit known as a “watch dog” in which good operational units would periodically trigger the watch dog circuit announcing that the unit is in good operational condition. If the watch dog is left too long without such trigger, it could activate a unit fail safe mode. Therefore, once a failed unit is detected, the watch dog circuit could activate a controlled vertical bus disconnect to isolate the failed processor from the vertical bus to avoid the failed unit from affecting the operation of other units of the 3D system. In such a situation the circuit could also initiate a processor reboot to overcome temporary faults and revive unit operation. If the fault is permanent then in addition to bus isolation the watch dog circuit could control the processor central operating clock circuit to further reduce the damage of the faulty unit processor and reduce its power consumption. In addition the 3D system could include system procedures in with periodically each of the unit is been ping by the 3D system task allocator processor. And if a unit is deemed faulty by the task allocator processor then a recovery operation could be activated to assign a spare unit to replace the faulty unit. Alternatively the 3D System could include agility to reallocate the system task between the operating units. An artisan in the art of large scale multi computers system could design such built-in test, detection, and recovery technology into the design of the 3D system.

Another alternative for such 3D systems is to have levels constructed by multiple die transfer instead of one wafer transfer as been presented in reference to FIG. 43A-43E of U.S. patent application Ser. No. 16/558,304, publication 2020/0176420, incorporated herein by reference. Such die level transfer could also utilize a technique called ‘Collective Die to Wafer Direct Bonding’ as presented in a paper by Inoue, Fumihiro, et al., “Advanced Dicing Technologies for Combination of Wafer to Wafer and Collective Die to Wafer Direct Bonding.” 2019 IEEE 69th Electronic Components and Technology Conference (ECTC). IEEE, 2019; also, by Nick Flaherty titled “Collective die-to-wafer bonding with sub-2 μm accuracy for 3D packaging” EE News Europe, Oct. 19, 2020; and by Brandstatter, Birgit, et al. “High-speed ultra-accurate direct C2 W bonding.” 2020 IEEE 70th Electronic Components and Technology Conference (ECTC). IEEE, 2020; all of the forgoing are incorporated in their entireties herein by reference. Such a die level transfer could utilize the M-Level concept to have the die transfer to a base level forming an M-Level which could be called DieM-Level and then transferred together onto the 3D system stack.

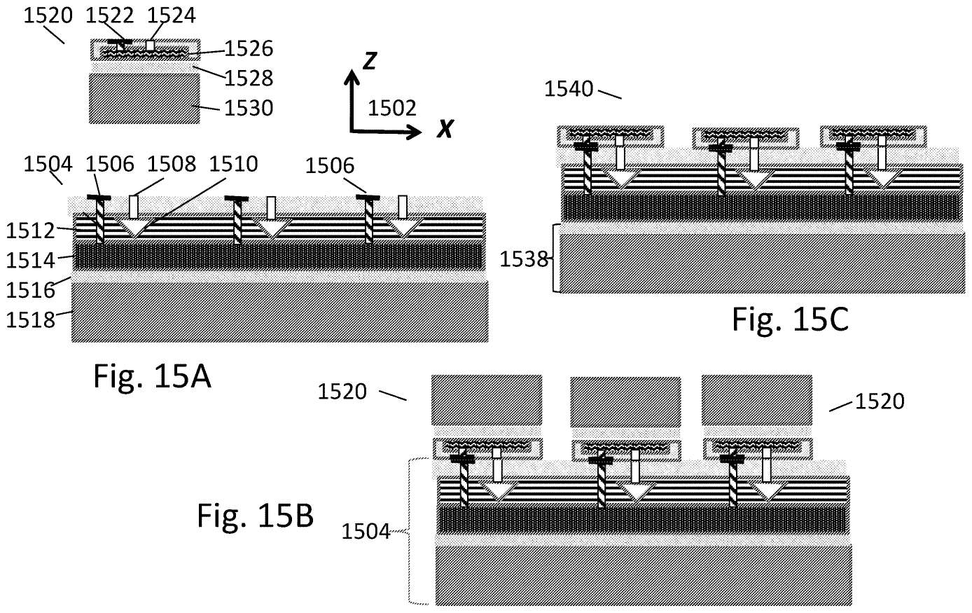

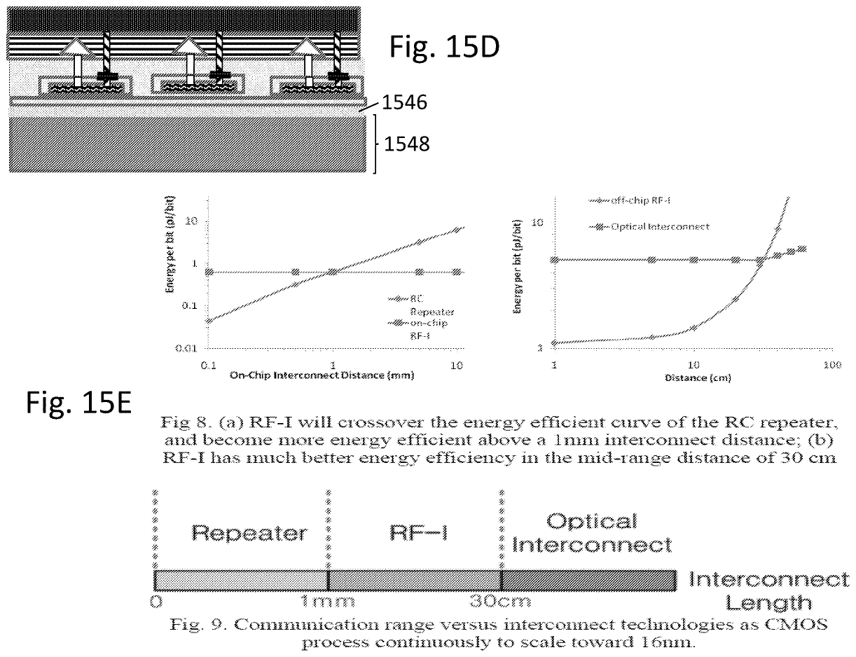

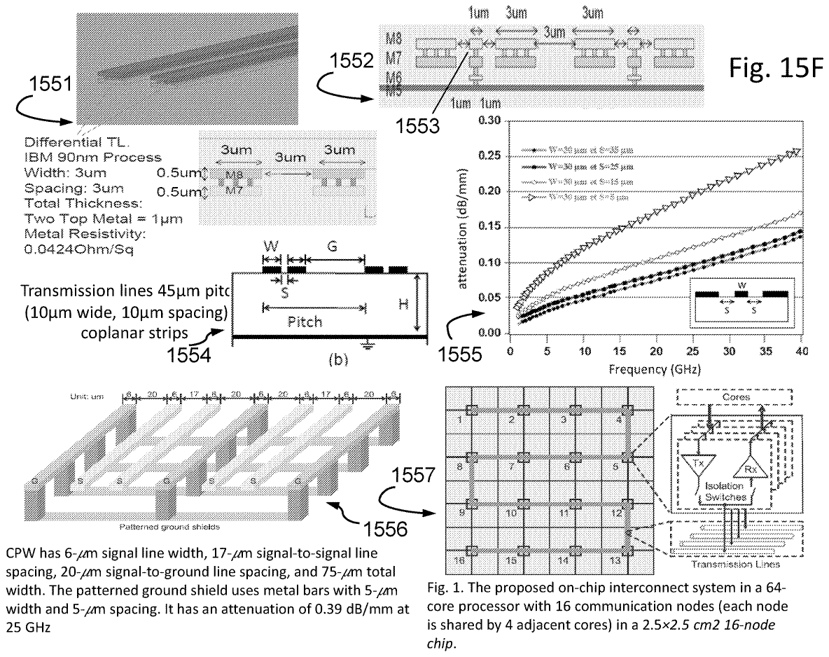

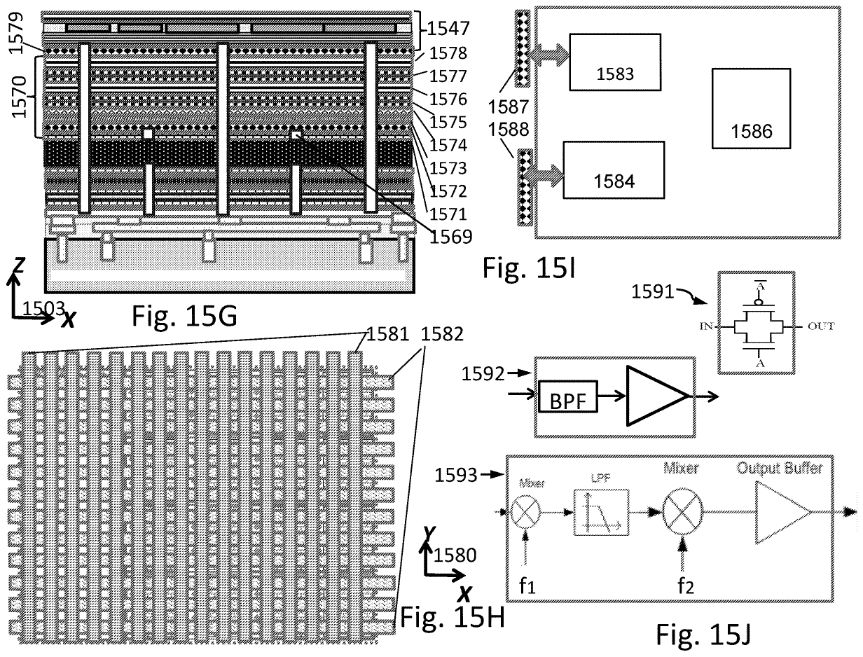

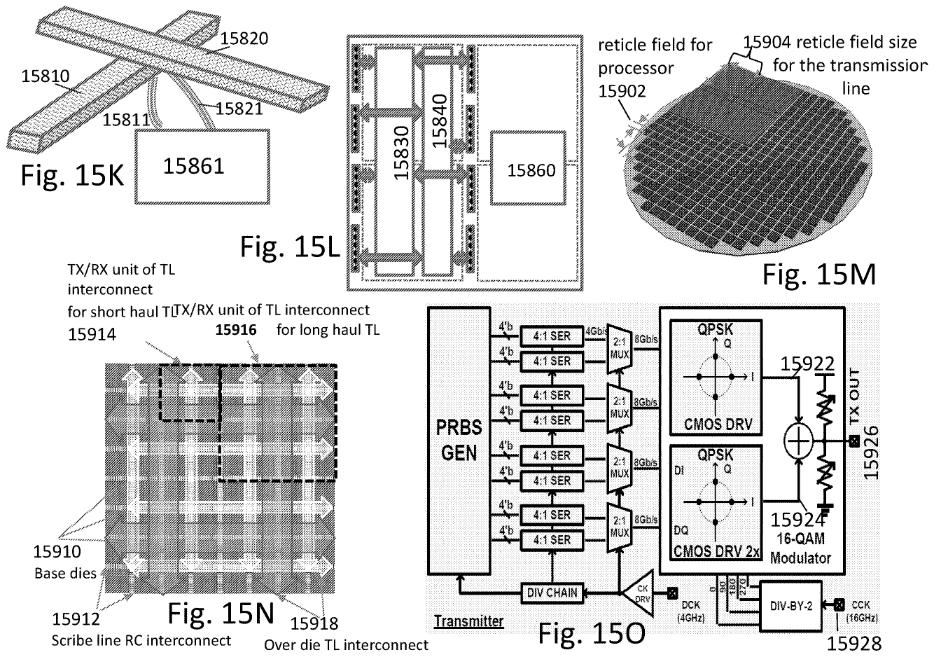

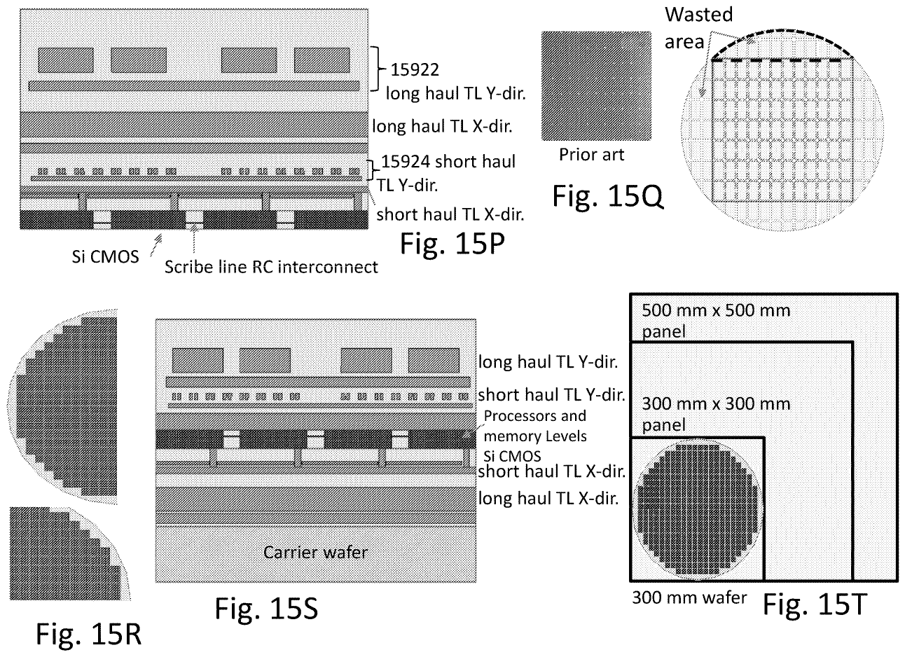

Such DieM-Level concept could be used for an X-Y connectivity M Level utilizing lasers, photodetectors, and waveguides as was presented in reference to at least FIG. 35A to FIG. 37B of U.S. patent application Ser. No. 16/558,304, publication 2020/0176420, incorporated herein by reference. Such DieM-Level may be implemented by silicon photonics which includes the photodetectors made by silicon-germanium alloy. The wavelength of the photonic connectivity may be about 1.3 um or about 1.5 um, but other useful wavelengths may be possible. Such DieM-Level could be part of a 3D system such as reference numeral 1447 of FIG. 14E herein. An example is presented in reference to FIG. 15A-15D herein which are X-Z 1502 cut view illustrations.

FIG. 15A illustrates a drive and control wafer 1504 having waveguides 1512 positioned over control and drive circuits 1514 over a cut-layer such as SiGe 1516 over a substrate 1518. The drive and control wafer 1504 could include vertical connection pads 1506 for connecting the drive and control wafer 1504 to one or more laser diodes die 1520, which could be bonded on top, and transparent via 1508 to guide the laser beam to the beam splitter and direction change assembly 1510 and thus guide the laser beam(s) to the appropriate waveguides. Techniques for processing such waveguides and optical interconnect structures are known in the art such as been presented in at least U.S. Pat. Nos. 5,485,021, 5,987,196, 6,791,675, 7,203,387, 8,548,288, 9,197,804; and in a paper by Lo, Shih-Shou, Mou-Sian Wang, and Chii-Chang Chen. “Semiconductor hollow optical waveguides formed by omni-directional reflectors.” Optics Express 12.26 (2004): 6589-6593, all of the forgoing are incorporated herein by reference. The laser diodes die 1520 could also be built on a substrate 1530 with optional cut-layer 1528. The laser diodes die 1520 could include many diodes each with its pin/pad connection in transparent vias output and support structures such as ground/power connections. The laser diodes could be built on crystal 1526 that is a good fit for laser generation for example, such as GaAs, InP, GaSb, GaN, etc. The crystal layer 1526 may be different material from the substrate 1530. For example, the crystal laser 1526 may be a crystalline direct bandgap semiconductor grown on a silicon substrate 1530 through a buffer layer. Alternatively, a piece of crystalline direct bandgap semiconductor that so-called die is transferred and bonded onto a silicon substrate 1530. The laser diodes die could include pin 1522 and transparent via 1524. In many cases the crystals used for laser diodes are not available on 300 mm wafer and accordingly die level transfer could be preferred for 3D integration applications.

FIG. 15B illustrates the bonding of a few laser diodes die 1520 on top of a drive and control wafer 1504.

FIG. 15C illustrates the bonded structure 1540 after thinning the substrate of the laser diodes dies 1520. If the laser diode dies 1520 are built with a cut-layer built-in then such a cut layer, for example cut-layer 1528 shown in FIG. 15A, could be used for this thinning step. Many of the crystals used for laser diodes are built using epitaxial growth on top of another crystal. Such a process could be used to form an etch stop cut-layer between the carrying substrate and the diode laser crystal. Following the thinning process other process steps could be used, for example, such as conformal oxide deposition, for filling the gaps between the laser diodes dies and then CMP to provide planarization. If needed, then steps to form connections pin/pads on now the top surface could be utilized.

FIG. 15D illustrated the structure of FIG. 15C after it was flipped over another substrate 1548 with cut layer 1546 and having its substrate 1538 removed. The structure of FIG. 15D could be made ready as a DieM-Level by adding the pads/pins for the C-bus future vertical connection (not shown).

Optical X-Y interconnect could also utilize silicon wafer making it easier to integrate into 3D system as presented here. Such as been presented in and in papers such as by Xu, Kaikai, et al. “Silicon light-emitting device for fast optical interconnect and fast sensing applications in the GHz frequency range in standard IC technology.” Optoelectron. Adv. Mater.—Rapid Commun. 11 (2017): 164-166, and by Snyman, Lukas W., et al. “Stimulation of 700-900 nm wavelength optical emission from Si AMLEDs and coupling into Si 3 N 4 waveguides using a RF silicon integrated circuit process.” OSA Continuum 3.4 (2020): 798-813, both are incorporated herein in their entirety by reference.

The thinning of the dies substrate after they have been bonded to the target wafer as is illustrated in the step between FIG. 15B to FIG. 15C could be accomplished with grinding and wet-chemical/plasma etch back. For silicon based dies, a SiGe based cut-layer could enable extreme thinning to even below 500 nm final thickness. In some cases the thinning of the dies substrate could use other forms of etch stop or could be done to less extremes such as to 20 or 10 μm level without the use of a cut layer. This would be engineered to determine the optimum process for the particular product and structure needs. Much of these engineering tradeoffs and possibilities have been discussed in various constituents of the incorporated by reference.

Some technologies and process flow for the integration of optical wave guides has been presented in U.S. patents such as in at least 10,587,026 and 10,770,414, both are incorporated herein in their entirety by reference.

In some 3D systems the demand for X-Y connectivity could justify adding an RF connectivity M-Level which will be called herein an RF-M-Level. While optical connectivity could provide excellent bandwidth and minimal cross talk it is relatively bulky and utilizes elements that are not common with silicon wafer processing. Optical connectivity could be utilized for relatively long X-Y connectivity such as longer than 150 mm while RF connectivity could be preferred for the range of 10 mm to 300 mm. Some 3D systems could utilize more than one technology for X-Y connectivity just as more than one type of memory technology could be desired, as presented here in FIG. 15E which is a copy of FIG. 8 and FIG. 9 of Tam, Sai-Wang, et al. “Wireline/wireless RF-Interconnect for future SoC.” 2011 IEEE International Symposium on Radio-Frequency Integration Technology. IEEE, 2011, the forgoing incorporated herein by reference.

RF-Interconnect (RF-I) has been presented as the preferred technology for interconnecting many cores on-chip supporting NoC as outlined in publications such as Kaplan, Adam Blake, and Glenn Reinman. Architectural integration of rf-interconnect to enhance on-chip communication for many-core chip multiprocessors. Diss. University of California, Los Angeles, 2008; by Chang, M-C. Frank, et al. “RF interconnects for communications on-chip.” Proceedings of the 2008 international symposium on Physical design. 2008; by Chang, M. Frank, et al. “CMP network-on-chip overlaid with multi-band RF-interconnect.” 2008 IEEE 14th International Symposium on High Performance Computer Architecture. IEEE, 2008; by LaRocca, Tim, Jenny Yi-Chun Liu, and Mau-Chung Frank Chang. “60 GHz CMOS amplifiers using transformer-coupling and artificial dielectric differential transmission lines for compact design.” IEEE journal of solid-state circuits 44.5 (2009): 1425-1435; by Tam, Sai-Wang, et al. “A simultaneous tri-band on-chip RF-interconnect for future network-on-chip.” 2009 symposium on VLSI circuits. IEEE, 2009; and by Wu, Hao, et al. “A 60 GHz on-chip RF-interconnect with λ/4 coupler for 5 Gbps bi-directional communication and multi-drop arbitration.” Proceedings of the IEEE 2012 Custom Integrated Circuits Conference. IEEE, 2012; all of the forgoing are incorporated herein in their entirety by reference. The transmission line configuration suggested and copied from that work is illustrated by 1551 and 1552 of FIG. 15F. Such Transmission Lines (“TL”) could have a pitch of about 12 μm and be formed on top of an active CMOS circuit utilizing the upper metal layers such as M7 and M8. These publications suggest that a group of such TLs could be laid-out in a serpentine topology connecting many computing cores as is illustrated in 1557 of FIG. 15F herein.

Additional work such as published by Maekawa, Tomoaki, Hiroyuki Ito, and Kazuya Masu, “An 8 Gbps 2.5 mW on-chip pulsed-current-mode transmission line interconnect with a stacked-switch Tx.” ESSCIRC 2008—34th European Solid-State Circuits Conference. IEEE, 2008; by Carpenter, Aaron, et al. “A case for globally shared-medium on-chip interconnect.” Proceedings of the 38th annual international symposium on Computer architecture. 2011, Carpenter, Aaron, et al. “Enhancing effective throughput for transmission line-based bus.” 2012 39th annual international symposium on computer architecture (ISCA). IEEE, 2012; and Carpenter, Aaron, et al. “Using transmission lines for global on-chip communication.” IEEE Journal on Emerging and Selected Topics in Circuits and Systems 2.2 (2012): 183-193, all of the forgoing are incorporated in their entirety herein by reference. These works suggest similar concepts but with wider TL as is illustrated in 1554 of FIG. 15F with a pitch of about 45 μm.

Follow-up work such as published by Drillet, Frederic, et al. “Flexible radio interface for NOC RF-interconnect.” 2014 17th Euromicro Conference on Digital System Design. IEEE, 2014, incorporated herein in their entirety by reference, demonstrate similar concepts but with wider TL as is illustrated in 1556 of FIG. 15F with a pitch of about 75 μm.

These on-chip RF-I could be applied to 3D systems as presented herein such as is illustrated in FIG. 15G. The serpentine concept could be changed to an X-Y connectivity fabric similar to the structure illustrated in FIG. 33A of U.S. application Ser. No. 16/558,304, incorporated herein by reference. The choice of the TL configuration could be engineered to accommodate the X-Y size of the 3D system and other parameters such as the size of the units and the demand for X-Y connectivity. While the shape of the TL as is illustrated in FIG. 15F is of coplanar strips, other variations have been developed which could be integrated for such 3D system. The TL could be structured as repetitive bands in the X direction overlaid by repetitive bands in the Y direction. The bands could include mix of TL shapes such that have tight pitch for shorter distances and such with wide pitch and low attenuation for longer distances. These bands of TL as the path over the units could include drop connections for each unit or have some TL that would skip some units, providing choices for system architecture and use protocols. An important aspect of such TL is the strong relation between the TL attenuation per mm length and the carrier wave frequency and the TL pitch, as is illustrated by the chart 1555 of FIG. 15F.

The engineering of such a 3D system could include utilizing the high frequencies for relatively short distance connectivity and the lower frequencies for relatively longer distance connectivity. In some cases it could be engineered that one TL could be used in one zone of high frequency local connectivity and a far away zone could utilize the same frequency for another local connectivity, thus leveraging the attenuation effect of the signal of the first zone. TL width and thickness could be tuned similarly, with wider and thicker lines for longer distance and higher frequencies.

FIG. 15G is an X-Z 1503 cut view of a 3D system similar to the one illustrated in FIG. 14E. FIG. 15G illustrates an additional RF-M-Level 1570 disposed below the optical X-Y interconnect M Level 1547. The process forming the RF-M-Level 1570 could be similar to the one illustrated in FIG. 13A just that 1314 could be a level of array of RF receivers, transceivers and support circuits with metal layer of TLs in the X direction and TLs in the Y direction. 1312 could be a level of RF-oriented processors designed to support the corresponding communication protocols for the various communication links. Accordingly the RF-M-Level 1570 could include a level 1572 of the RF-oriented processors, level 1573 could provide RF shielding and RF matching level such as high defect substrate, level 1574 could provide the RF receivers, transceivers, and support circuits. This level could utilize RF-oriented crystals such as SiGe. Level 1575 could provide bundles of Y direction oriented TLs, Level 1576 could provide bundles of X direction oriented TLs, Level 1577 could provide bundles of Y direction oriented TLs, and Level 1578 could provide bundles of X direction oriented TLs. Substrate designed to support RF circuits on top are known in the art and often offered as SOI high resistivity (HR) substrate or as a Trap-Rich HR substrate, for example, such as presented by Neve, Cesar Roda, and Jean-Pierre Raskin. “RF harmonic distortion of CPW lines on HR-Si and trap-rich HR-Si substrates.” IEEE Transactions on Electron Devices 59.4 (2012): 924-932, incorporated herein by reference in their entirety. Another option is to utilize porous layer as presented in a paper by Sarafis, Panagiotis, and Androula G. Nassiopoulou. “Porous Si as a substrate for the monolithic integration of RF and millimeter-wave passive devices (transmission lines, inductors, filters, and antennas): Current state-of-art and perspectives.” Applied Physics Reviews 4.3 (2017): 031102; and Gautier, Gaël, and Philippe Leduc. “Porous silicon for electrical isolation in radio frequency devices: A review.” Applied Physics Reviews 1.1 (2014): 011101, all of the foregoing are incorporated herein by reference in their entirety. Integrating such RF-friendly substrates could help reduce power and improve performance of such 3D systems and could utilize the architecture and the layer transfer techniques presented here and in the incorporated art.

One of the advantages of RF X-Y interconnect is the relatively easier access for drop-in and drop-off signals. The TLs maintain a large distance between conductors as is illustrated in FIG. 15F. Accordingly there is enough room to have a via, such as, for example, via 1553, go through the TLs from the transceiver or to the receiver. Multiple levels of TLs could be placed one on top the other and be connected to level 1574—the RF receivers transceivers and support circuits. These vertical connections are short and could have acceptable attenuation even if the conductor width connections are about 1 μm, and could be impedance matched for optimal power transfer.

The connection to the TLs could include a transistor switch to reduce the impact of the un-activated connection as presented in reference to FIGS. 2, 6, 7 of the paper by Hamieh, Mohamad, et al. “A new interconnect method for radio frequency intra-chip communications using transistors-based distributed access.” Microwave and Optical Technology Letters 61.2 (2019): 297-302, incorporated herein in their entirety by reference. Another alternative for a multi-drop TL utilizes λ/4 directional couplers such as presented in a paper by Wu, Hao, et al. “A 60 GHz on-chip RF-interconnect with λ/4 coupler for 5 Gbps bi-directional communication and multi-drop arbitration.” Proceedings of the IEEE 2012 Custom Integrated Circuits Conference. IEEE, 2012, incorporated herein in their entirety by reference. Electromagnetic coupling to TL is also presented in U.S. Pat. No. 7,889,022, incorporated herein by reference in its entirety.

The levels 1572 of the RF oriented processors and level 1574 of the RF receivers-transceivers and support circuits could be structured as units aligned and corresponding to the unit structure below and connected to it using the vertical buses. The BEOL (back end of the line) could be adapted to support the TLs such as having thickness of more than 0.5 μm for the layers allocated for the TLs. The TLs metal thickness could be adapted to be more than about 0.8 μm or about 1.4 μm or even more than 2 μm. The TLs have been illustrated in FIG. 15F and the associated publications were designed to fit into common CMOS process lines such as the IBM 90 nm process to support integration with the underlying SOC circuits. For the 3D system such as is illustrated in FIG. 15G it may be preferred to have a dedicated process flow to support processing of RF-M-Levels.

The TL bundle as is illustrated in 1557 of FIG. 15F is a serpentine connecting 64 core processor, with 16 communication nodes. A serpentine shape has been proposed by multiple publications with others proposing a U shape, Z shape, and X shape. These publications suggest use of RF-I at a chip level and preferred to have the TLs connecting all center nodes in the system. Such approach could be applied to 3D systems suggested herein. Yet, the 3D system herein could be made far larger than a chip size as previously discussed herein, for example, such as by reticle size or 50 cm×50 cm or 100 cm×100 cm or larger than 200 cm×200 cm like full scale wafer or panel size. For such large area 3D systems, such an approach might be less attractive, especially for a 3D systems large array of relatively small units with areas such as 200 μm×200 μm. An alternative is illustrated in FIG. 15H, top view X-Y 1580, with TL lines going in X direction 1582 and TL lines going in Y direction 1581, each could have connection to its underlying units (not shown). With a length of 200 cm one TL could have 1,000 drop off connections to its underlying units. To provide connection between two units within the 3D system, an X-oriented TL and a Y-oriented TL could be used.

The use of an X-oriented TL and a Y-oriented TL could be done by direct connection or alternatively by utilizing the underlying 1572 TL processor.

FIG. 15I illustrates a block diagram of the per unit TL processors of the base level 1572 of the RF-M-Level 1570. It could include a processor 1583 having the function of connecting to the per unit vertical bus 1587 and accordingly connect to one of the overlaying TLs to transfer data to or from another unit in the system. The 3D system could utilize communication protocols for each of the communicating link types being used. Such as communication protocol for the vertical bus 1597 and communication protocol for the between units RF interconnect.

An additional processor 1584 could be a Direct Memory Access Processor (DMA). Such processor could utilize direct access to the underlying memory to transfer blocks of data from or to another unit in the system. The 3D system could include an additional memory control level 1571 to provide a second port to the memory bank and a dedicated memory access bus 1569 and 1588.

An additional processor 1586 could be used to facilitate data transfer from an X-oriented TL to a Y-oriented TL. These processors could serve the system-level interconnect and leave the base-level processor to data processing. This approach could help provide system level integration for a 3D system having 1,000,000 processing units each with its own memory and communication links.

There are several options to transfer data, for example, from a TL going in the X direction to a TL going in the Y direction. Once the system selects the unit at which the direction change should take place, the corresponding direction change processor 1586 will control and manage the X to Y connection. FIG. 15J illustrates a few alternative schematics for such a connection. A simple approach is the use of a transmission gate 1591. In some cases, such as when one frequency is being used on a TL, at the signal drop point an amplifier could be added with minimal additional overhead. Such a circuit functions similarly to a programmable via which is simple but might be less attractive if the TL carries multiple data signals modulating multiple carrier frequencies. An approach that could be used with such multiband connections is frequency band allocation. Such a band allocation approach was presented such as in U.S. Pat. No. 9,806,787 and in a paper by Oh, Jungju, Milos Prvulovic, and Alenka Zajic. “TLSync: support for multiple fast barriers using on-chip transmission lines.” 2011 38th Annual International Symposium on Computer Architecture (ISCA). IEEE, 2011, incorporated herein in their entirety by reference.

An alternative concept is to have drop-off signals from the source TL and then use a programmable band-path filter (BPF) to transfer only the selected carrier frequency then re-amplify the signal such as with programmable gain amplifier 1592 and then connect the amplified signal to the destination TL. An approach that could be used for such TL programmable connectivity is to allocate the frequency band used for signal designated for TL connectivity. Such could include allocating the lower frequency band for TL connectivity such as X-Y. Lower frequencies could have lower attenuation and better fit for longer signal path. This concept could be extended to include a lower band designated as a broadcast channel such as one-to-many. Then, a low band could be used for longer signal paths such as X-Y connectivity, and the mid to higher band to single TLs connectivity. In some cases such as when one frequency is being used on a TL, the signal drop point could be an amplifier with minimal additional overhead. Amplifiers or BPFs and transmission gates could be designed together, with one each direction (X-to-Y and Y-to-X) allowing one direction to be used at a time, but still exploit the bidirectionality of the TL waveguides.

Another alternative scheme is to first reconstruct the data stream from the drop-off signal from the source TL and then re-modulate the data with the destination carrier frequency 1593 and drop it to the destination TL. This way the system can choose a different carrier for the first TL and a different one for the second TL. A higher level of flexibility could be achieved with more support circuit for a direction-change processor 1586, which could include full data drop and store followed by full data transmit. This way the carrier frequency and the data time transmit slot could be changed as the data are transferred from the first TL to the second TL connectivity in which the data is demodulated and routed as digital data which could include a short time store often called a queue. This is very common in data switches and routers and also been presented on chip circuits such as U.S. Pat. No. 7,362,125 and a paper by Deb, Dipika, et al. “Cost effective routing techniques in 2D mesh NoC using on-chip transmission lines.” Journal of Parallel and Distributed Computing 123 (2019): 118-129, incorporated herein in their entirety by reference.

FIG. 15K is a simplified illustration of a connection between two TLs 15810, 15820. So for example in FIG. 15H any cross between an X direction TL 1582 and a Y direction TL 1581 could include a programmable connection option using the underlying unit processor 1586 to form the data transfer-connection. The connection could utilize techniques such as discussed in reference to FIG. 15J. The system could include data routing connections while changing direction or changing TL with the same orientation. The drop-off and the wires 15811, 15821 to and from the data routing processor 15861 could include transistor-controlled connection(s) to the TL or other drop off/on technique such as λ/4 as discussed here before. The connection wires 15811, 15821 are for the signal and its return and for differential pair TL for both signals and their returns.

As is illustrated in FIG. 15E the preferred choice of interconnect technology is highly dependent on the length of the route or the distance between the elements being connected. For the 3D system as presented herein the X-Y connectivity could utilize wires with their RC for relatively short interconnect such as between neighboring units (0.2 to 2 mm), RF-I across longer routes (1 to 300 mm) and optical for longer routes (over 100 mm). The use of these technologies could include use of mix technologies such as use of RF signals to modulate optical signals as presented in U.S. Pat. No. 10,502,987 incorporated herein by reference in its entirety.

The X-Y connectivity could utilize multiple levels each support one of these connectivity technologies. Many of the incorporated by reference art herein suggest RF-I between nodes and wire (RC) connectivity to these nodes. FIG. 15L illustrates a modified block diagram of FIG. 15I in which 4 units are aggregated to communicate with the RF-I fabric. A processor 15830 having the function of connecting four vertical buses of the four aggregated units connecting to one of the overlaying TL to transfer data to or from another units in the system. Processor 15840 could be Direct Memory Access Processor (DMA). Such a processor could utilize direct access to the four underlying unit's memory to transfer blocks of data from or to another unit in the system. Additional processor 15860 could be used to facilitate data transfer from an X oriented TL to a Y oriented TL, or between TL with the same orientation having different functions such as long and short connectivity. The engineering of the 3D system X-Y interconnect could include aggregating 2×2, 3×3,4×4 or other configurations of units using wires before moving on to TL connectivity. Such engineering could consider the size of the units and the cost in performance of adding drop off/on to the TLs. The 3D system could include combinations of these techniques including connection to the TL from units and from unit aggregators.

In addition, with a standardized structure for vertical bus locations, a mix and match of elements in the 3D system could be used. Levels of processors and memory could utilize different levels of X-Y connectivity or different levels of memory and so forth, the modularity of the concept could be extended to support different 3D system sizes by dicing it according to the application needs. The 3D system structures presented here could support modularity and customization in X-Y and Z.

The interconnect layer could also be connected to its own built-in self-test and watchdog circuits, as large RF wires may have internal errors, both transient or permanent. The interconnect layer connected to built-in-self-test could further include a training module and on-die-termination. A terminal resistor for impedance matching in the transmission line may be located inside the silicon chip. The impedance value of the terminal resistor could further be fine and coarse tuned in order to countermeasure the process, voltage, and temperature variations. The training and calibration circuit determines an optimal termination impedance to reduce signal reflectance and compensate for the variability. These watchdog circuits could send test messages and in the case of erroneous messages, redirect traffic away from the faulty lines. Redundant interconnect lines could be available, as the RF-M-level would contain enough area to accommodate duplicates. As these large wafer-scale systems would require longevity, these fault tolerant test and redundancies will extend their lifetime and allow for graceful degradation techniques.

Traditionally, the optical field area of a reticle for the lithography step is identical across the entire process, which determines the maximum size of a die. In order to implement the TL spanning across multiple dies, the optical field area of the reticle for processing the TL could be greater than the optical field area of the processor die 15902 due to the relatively low resolution requirements of the TL features. FIG. 15M illustrates an example of an oversized reticle 15904. Additionally a plurality of oversized reticle TL patterns could be stitched to form the pattern for the entire TL layer. FIG. 15M illustrates the 4× reticle sized large area chip. Furthermore, a one-to-one contact aligner or near non-contact aligner could be used for the lithography for TL.

The TL layers could be processed at the same fab with the processor wafers; alternatively, the TL layers could be processed at a different fab such as at a dedicated packaging fab. Such TL layer processing could be done as a part of redistribution layer (RDL) process. The TL implemented using dedicated packaging fab can offer thicker metal and dielectric than those in logic or RF lines. In such case, an organic resin such as a polyimide could be used as dielectric. A thick resin could help isolate the TL layers from a silicon wafer substrate. As a result, the increased Q-factor may reduce the power consumption and reduce the transmission attenuation. Such TL processing has been presented by Balachandran, Jayaprakash, et al. “Extending on-die wiring hierarchy with wafer level packaging concepts.” Proceedings of the IEEE 2004 International Interconnect Technology Conference (IEEE Cat. No. 04TH8729). IEEE, 2004; by Balachandran, Jayaprakash, et al. “Wafer-level package interconnect options.” IEEE transactions on very large scale integration (VLSI) systems 14.6 (2006): 654-659.; by Itoi, Kazuhisa, et al. “On-chip high-Q spiral Cu inductors embedded in wafer-level chip-scale package for silicon RF application.” 2004 IEEE MTT-S International Microwave Symposium Digest (IEEE Cat. No. 04CH37535). Vol. 1. IEEE, 2004; and by Lahiji, R. R., et al. “Low-loss coplanar waveguide transmission lines and vertical interconnects on multi-layer parylene-N.” 2009 IEEE Topical Meeting on Silicon Monolithic Integrated Circuits in RF Systems. IEEE, 2009, all of the forgoing are incorporated herein by reference in their entirety.

In one embodiment of the present invention, hybrid interconnect across the device, is presented. As illustrated in FIG. 15N, the hybrid multi-die interconnect uses direct RC interconnect for connecting neighboring dies through scribe line 15912 and multi levels of overlaying TL interconnect for connecting a separated die 15910. The RC portion could be called scribe-line interconnects and the TL portion could be called over-die interconnects 15918. The scribe line interconnects link a short distance such as less than 1 mm for which normal RC interconnection could be efficient. The scribe line link protocol can include high speed parallel interconnects. The over-die interconnects may run greater than 10 mm, and multiple dies could be grouped, such as 4 dies 15914 as is illustrated in FIG. 15N or greater than 4, as a unit of TX/RX of TL interconnect 15916. The TL link protocol may use high-speed SerDes, for example, such as DDR memory bus, USB, and PCIe.

In another embodiment of the present invention, a multi-tiered TL is presented. For example, for short-haul connection 15924 may use many TL lanes such as x4, x8, x16, or x64 lanes per channel and long-haul connection 15922 with thicker conductors and larger spaces between conductors may use less TL lanes such as x1 or x2 lanes. FIG. 15P illustrates a cross-sectional view of a multi-tiered TL, illustrating two levels of X-direction TL and levels of Y-direction TL. Each of the various technologies, in particular the TL and photonics, could also be arranged with varying topologies based on the needs of the system or subsystems, including high-radix routers. These routers could be contained in the communication layer with available area in order to amplify and direct signals. These topologies serve as a possible alternative to direct X-Y routing. These long-haul TLs as illustrated in FIGS. 15P and 15S could use additional NoC-style topologies, for example, a 3D torus as shown in FIG. 15U or a butterfly as shown in FIG. 15V but could include other network topologies as well. Studies of these networks can be found in previous literature in Jiao et al., “Performance Analysis and Optimization for Homogenous Multi-core System based on 3D Torus Network on Chip,” IEEE NEWCAS 2010; and Kim et al., “Flattened Butterfly Topology for On-Chip Networks,” IEEE Computer Architecture Letters 2007”, all of the forgoing are incorporated herein by reference in their entirety. Traditionally, the semiconductor processor as well as the so-called wafer scale engine has been rectangular. FIG. 15Q shows an example of wafer-scale-engine presented by I. Cutress “Hot Chips 31 Live Blogs: Cerebras' 1.2 Trillion Transistor Deep Learning Processor”, incorporated herein by reference. However, in order to save the wasted area illustrated in FIG. 15Q, a non-rectangular 3D system could be considered where the multiple dies are connected by on-wafer TL. As exemplified by FIG. 15R, not only entire circular wafer but also half or quarter of a wafer could be used without losing any of die near the edge, even for a large area chip.

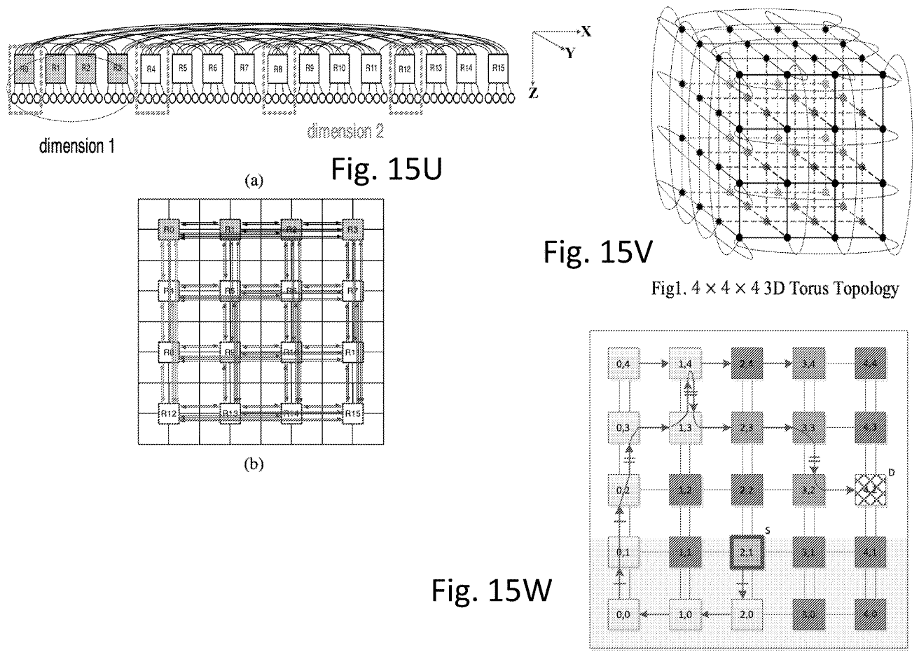

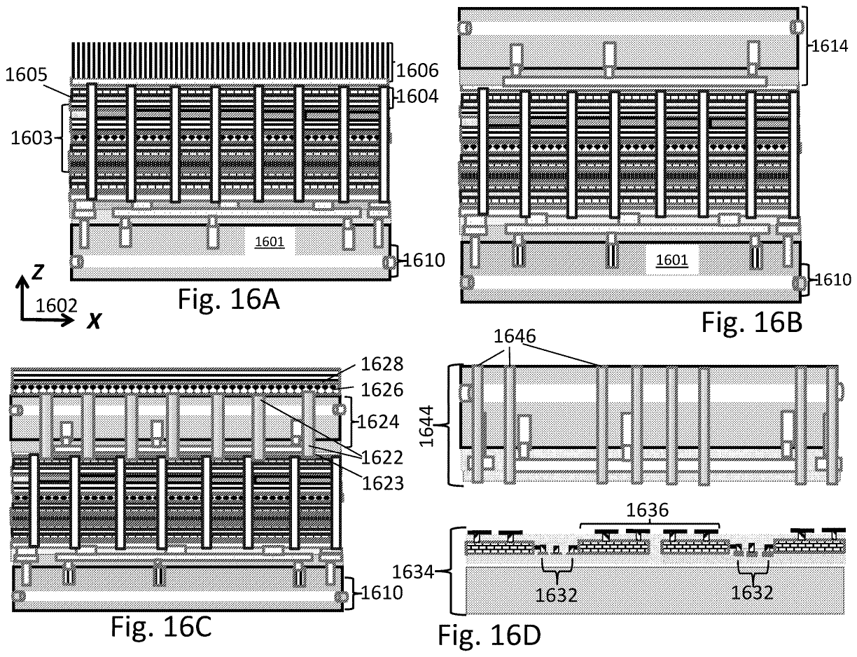

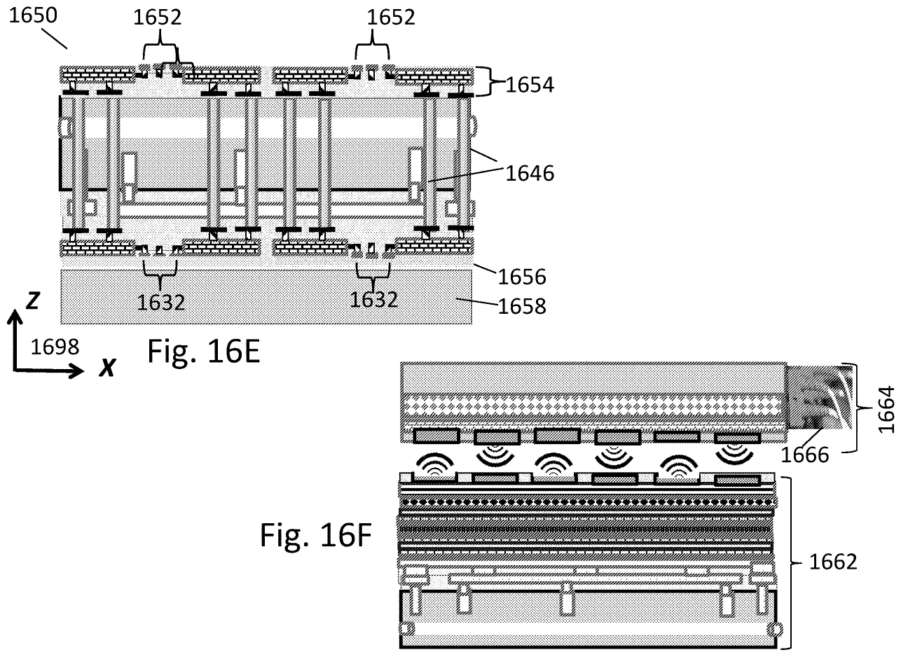

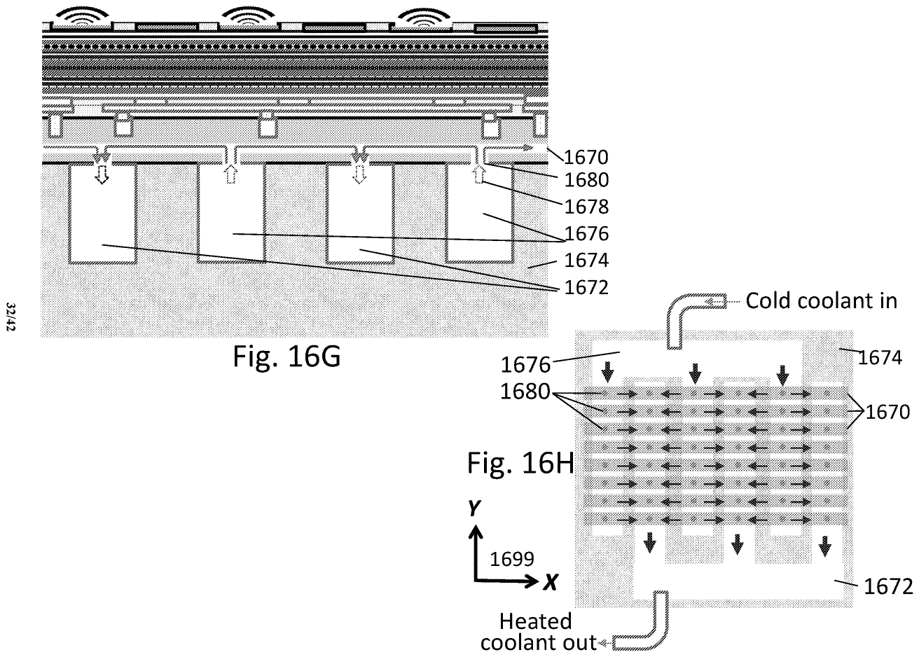

TL levels could be placed underneath and/or on top of processors and memory levels as is illustrated in FIG. 15S using the technique of level transfer as has been presented herein. Such use of a round wafer or a section of a round wafer further benefits from using small unit sizes such as about 200×200μ² or about 150×150μ². The use of arrays of relatively small units further enhances the utilization of the round shape with rectangular units. Furthermore, the use of wireless interconnect as presented herein with reference to FIG. 16F in which a mating wafer provides the connection of the 3D system to other system and supports full use of wafer round shapes without the need to waste portions of the wafer associated with a square final product shape.

Recently, a technology beyond the wafer level packaging (WLP), a panel-level-packing (PLP) is emerging offering a lower cost fan out. In the PLP, a large square panel or an LCD substrate is used. Various areas of panels are provided; however, the smallest panel size is still greater than the size of a 300 mm wafer as shown in FIG. 15T. The multi-tiered TLs that span across multiple dies can be fabricated on the PLP substrate, and then the entire CMOS wafer could be transferred and bonded to the PLP substrate.

The transition of data stream from one TL to another could be part of the overall system data routing. It could be part of a direction change such as from X to Y (or from Y to X) or going on the same direction but moving from long TL to a short TL (or from short TL to long TL). As is illustrated in FIG. 15F, TL could be engineered at a different pitch with a tradeoff between density and attenuation 1555. The 3D system could be structured with a TL designed to support data transfer over a long distance like federal highways with optional transition to shorter TL such as state freeways and then once converted back to voltage type signaling with RC lines, the connectivity is like local roads. This concept could include transitions to and from optical waveguide 1547 for very long data transfer. Another transition could utilize structures such as 1593 to move data from one frequency carrier to another.

Additional aspect that could be included with RF-I is the use of a low frequency carrier to support, for example, the system management including routing assignments. As we can see from the frequency vs. attenuation chart 1555 (part of FIG. 15F), a low carrier frequency could have very low attenuation making it a good fit for system control and broadcasting functions. Accordingly in such a 3D system a source unit can broadcast data by using a TL in one direction-column as a source and then use an orthogonal TL for each row to broadcast the data. These could be structured, for example, as a full system broadcast or as a per defined region selective broadcast.

For broadcasts, the TL network could use its broadcast capability to quickly disseminate packets in the X direction, then fan-out to the Y direction. The same could be done in reverse for all-to-one, all-to-all, or other multicast operations where multiple senders are sending correlated messages, such as acknowledgement messages or barrier synchronization. This could be done with existing structures as shown in FIG. 15G.

The messages could be aggregated in the processors or network interfaces in the RF-level then be sent as a combined message to reduce congestion and improve throughput for large multicasts. As nodes which share the X direction TL 1582 in FIG. 15H respond to many-to-one messages, the interface between the X and Y TLs 1581 and 1582 could retain the messages in a buffer. After some period of time, the buffer could combine the responses into a single larger message and send it as one in the Y direction 1581, thus responding with less congestion. The buffer could be in the interface as part of the amplification and routing of the system 15861 as demonstrated in FIG. 15K.

This could be done using software control mechanisms or routing protocols which could be built in the hardware. The many-to-one levels could be independent levels such as 1579 of FIG. 15G or integrated as part of the RF-M-Level 1570. The use of aggregation in large-scale supercomputer-size interconnection networks has been demonstrated at the macro-scale by Chen, et al. “Looking Under the Hood of the IBM Blue Gene/Q Network,” IEEE SC 2012 and Bui, et al., “Scalable parallel I/O on Blue Gene/Q supercomputer using compression, topology-aware data aggregation, and subfiling,” Euromicro Conference on Parallel, Distributed, and Network-Based Processing 2014, all of the forgoing are incorporated herein by reference in their entirety.

The conventional on chip TLs use coplanar waveguides. Additional technologies have been developed and could be engineered as improvements. In a paper by Feng, Zijun, Nan Li, and Xiuping Li. “Characterization of CMOS on-chip transmission lines towards sub-THz regime.” 2015 IEEE MTT-S International Conference on Numerical Electromagnetic and Multiphysics Modeling and Optimization (NEMO). IEEE, 2015, incorporated herein in its entirety by reference, a TL named grounded coplanar waveguide (GCPW), showed attenuation as low as 0.06 dB/mm, 0.08 dB/mm and 0.04 dB/mm, supporting sub-THz (over 100 GHz) carrier wave connectivity. In a paper by LaRocca, Tim, Jenny Yi-Chun Liu, and Mau-Chung Frank Chang. “60 GHz CMOS amplifiers using transformer-coupling and artificial dielectric differential transmission lines for compact design.” IEEE journal of solid-state circuits 44.5 (2009): 1425-1435, incorporated herein in its entirety by reference, it suggests artificial dielectric strips to provide substrate shielding and increase the effective dielectric constant up to 54 for further size reduction. An additional variation of a hybrid between the CPW and the CPWG leads to the shielded CPW (SCPW). The SCPW does not have a solid ground plane below the signal path but a grid of metal segments connecting the two coplanar ground paths which acts as a shield, by Lourandakis, Errikos, et al. “Parametric analysis and design guidelines for mm-wave transmission lines in nm CMOS.” IEEE Transactions on Microwave Theory and Techniques 66.10 (2018): 4383-4389, incorporated herein in its entirety by reference. Another variation for a new comb slow wave grounded coplanar waveguide (comb-S-GCPW), with an effective dielectric constant of 140 leading to a size reduction of 83% compared to a traditional CPW has been proposed by Bjorndal, Øystein. Millimeter wave interconnect and slow wave transmission lines in CMOS. MS thesis. 2013, incorporated herein in its entirety by reference. An additional approach supports an ultra-slow-wave on-chip coplanar waveguide (CPW) transmission line with inter-digital loaded stubs and floating strips providing smaller size and lower loss comparing to traditional on-chip CPW transmission lines, by Arigong, Bayaner, et al. “An ultra-slow-wave transmission line on CMOS technology.” Microwave and Optical Technology Letters 59.3 (2017): 604-606, incorporated herein in its entirety by reference.

An additional technology that could be integrated into such 3D systems is a ‘one to many’ interconnect utilizing surface wave interconnect, such as been detailed in publications by Karkar, Ammar, and Alex Yakovlev. “Leveraging Wire-Surface Wave Interconnects Architecture for one-to-many traffic in Network-on-chip” and Karkar, Ammar, et al. “Network-on-chip multicast architectures using hybrid wire and surface-wave interconnects.” IEEE Transactions on Emerging Topics in Computing 6.3 (2016): 357-369, all are incorporated herein in their entirety by reference. As presented Surface wave (SW) or Zenneck surface wave is a heterogeneous electromagnetic (EM) wave supported by a metal-dielectric surface. The designed surface is a waveguide that traps the EM signal in a two-dimensional media instead of three-dimensional free space. As a result, the E-field decay rate in the SWI from the source horizontally along the boundary is around (1/√d) which makes the SWI technology attractive option to add in addition to the TLs interconnection levels. The one-to-many levels could be independent levels such as 1579 of FIG. 15G or integrated as part of the RF-M-Level 1570. Another alternative to add broadcast capability for such 3D System is using wireless technology such as presented by Abadal, Sergi, et al. “Broadcast-enabled massive multicore architectures: A wireless RF approach.” IEEE micro 35.5 (2015): 52-61, incorporated herein in its entirety by reference.

The 3D System X-Y interconnection could include multi-levels of electromagnetic interconnects such as RF-I using TLs of different size length and orientation, level of SWI for the broadcast portion of the X-Y connectivity, and optical waveguides for the longer portion. Such a heterogeneous X-Y connectivity could support a large chip/device area such as wafer scale integration of large array of units of the 3D systems connecting hundreds of thousands or even millions of computing elements. The management of the system could utilize units that are designated as system manager or as a distributed network of computing. Technologies developed for a server farm could be adapted to help organize and operate such a 3D system.

Multiple interconnection technologies could be used in a synergetic way to allow improved overall system connectivity. Such could be utilized effectively in a 3D system as presented herein which could be used to add on the 3D system stack levels optimized to support different interconnection technology, such as RF, normal wires, SWI, and optical interconnect. Such a hybrid approach has been presented by Krishna, Tushar, et al. “NoC with near-ideal express virtual channels using global-line communication.” 2008 16th IEEE Symposium on High Performance Interconnects. IEEE, 2008; and by Oh, Jungju, Alenka Zajic, and Milos Prvulovic. “Traffic steering between a low-latency unswitched TL ring and a high-throughput switched on-chip interconnect.” Proceedings of the 22nd international conference on Parallel architectures and compilation techniques. IEEE, 2013, all of the foregoing are incorporated herein by reference in their entirety.

In the recent years the concept of surface wave for RF-I has been further developed. That led to development of “transmission and detection of the surface plasmon polariton (SPP), one special TM-polarized surface-wave localized onto the metal/dielectric interface. By artificially designing periodical sub-wavelength metal strips onto the metal line, or called spoof SPP, one can establish and propagate TM-mode surface wave signal between the metal and dielectric at sub-THz region, as presented by Liang, Yuan, et al. “D-band surface-wave modulator and signal source with 40 dB extinction ratio and 3.7 mW output power in 65 nm CMOS.” ESSCIRC 2018—IEEE 44th European Solid State Circuits Conference (ESSCIRC). IEEE, 2018; Liang, Yuan, et al. “On-chip sub-terahertz surface plasmon polariton transmission lines with mode converter in CMOS.” Scientific Reports 6 (2016): 30063; Liang, Yuan, et al. “An energy-efficient and low-crosstalk sub-THz I/O by surface plasmonic polariton interconnect in CMOS.” IEEE Transactions on Microwave Theory and Techniques 65.8 (2017): 2762-2774; by Joy, Soumitra Roy, et al. “Spoof plasmon interconnects—communications beyond RC limit.” IEEE Transactions on Communications 67.1 (2018): 599-610; by Qi, Zihang, Xiuping Li, and Hua Zhu. “Low-loss BiCMOS spoof surface plasmon polariton transmission line in sub-THz regime.” IET Microwaves, Antennas & Propagation 12.2 (2017): 254-258; by Shi, Zihao, Yizhu Shen, and Sanming Hu. “Spoof surface plasmon polariton transmission line with reduced line-width and enhanced field confinement” International Journal of RF and Microwave Computer-Aided Engineering (2020): e22276; by Chen, Qian, et al. “Multi-Channel FSK Inter/Intra-Chip Communication by Exploiting Field-Confined Slow-Wave Transmission Line.” 2020 IEEE International Symposium on Circuits and Systems (ISCAS). IEEE, 2020; and by Singh, Surya Prakash, Nilesh Kumar Tiwari, and M. Jaleel Akhtar. “Spoof surface plasmonic transmission line with high isolation and low propagation loss.” Applied Optics 59.5 (2020): 1371-1375, all are incorporated herein in their entirety by reference. These in-between metal conducting TLs and dielectric conduction waveguides provide an attractive option having the relatively ease of on chip integration of RF-I and low cross talk of optical interconnect. These spoof SPPs could use conventional coplanar strips (CPS) guide to feed the signal in and out as detailed in the above incorporated by reference art.

These spoof SPPs could be designed to support a sub-THz carrier wave or far lower frequencies such as been published by Kianinejad, Amin, Zhi Ning Chen, and Cheng-Wei Qiu. “Low-loss spoof surface plasmon slow-wave transmission lines with compact transition and high isolation.” IEEE Transactions on Microwave Theory and Techniques 64.10 (2016): 3078-3086; by Shen, Sensong, et al. “A novel three-dimensional integrated spoof surface plasmon polaritons transmission line.” IEEE Access 7 (2019): 26900-26908; and by Ye, Longfang, et al. “High-efficient and low-coupling spoof surface plasmon polaritons enabled by V-shaped microstrips.” Optics Express 27.16 (2019): 22088-22099, all are incorporated herein in their entirety by reference.

The 3D System X-Y interconnect and the connectivity on system network could utilize knowledge and tools developed for large integrated computing systems such as server farms. Additional work includes work that is known for Network on Chip—NOC, such as by Manevich, Ran, et al. “Designing single-cycle long links in hierarchical NoCs.” Microprocessors and Microsystems 38.8 (2014): 814-825, by Lahdhiri, Habiba, Jordane Lorandel, and Emmanuelle Bourdel. “Threshold-based routing algorithm for RF-NoC OFDMA architecture.” 2019 14th International Symposium on Reconfigurable Communication-centric Systems-on-Chip (ReCoSoC). IEEE, 2019; by Spyropoulou, Maria, et al. “Towards 1.6 T datacentre interconnect technologies: the TWILIGHT perspective.” Journal of Physics: Photonics 2.4 (2020): 041002; and by Lahdhiri, Habiba, et al. “Framework for Design Exploration and Performance Analysis of RF-NoC Manycore Architecture.” Journal of Low Power Electronics and Applications 10.4 (2020): 37, all are incorporated herein by reference in their entirety.

The industry is constantly advancing the communication technology to support better use of communication media such as TL with higher data transfer per second at lower power per bit of data. To do so, advanced data modulation technologies have been developed such as presented in a paper by Du, Jason Y. “Radio Frequency Modulated Signaling Interconnect for Memory-to-Processor and Processor-to-Processor Interfaces: An Overview.” arXiv preprint arXiv:1612.06522 (2016); by Hamieh, Mohamad, et al. “Sizing of the physical layer of a rf intra-chip communications.” 2014 21st IEEE International Conference on Electronics, Circuits and Systems (ICECS). IEEE, 2014; and by Chang, Mau-Chung F., et al. Multiband Radio Frequency Interconnect (MRFI) Technology For Next Generation Mobile/Airborne Computing Systems. University of California, Los Angeles Los Angeles United States, 2017, all are incorporated herein by reference in their entirety. Such advanced modulation techniques could be used for the X-Y connectivity of the 3D system. The TLs used for X-Y connectivity could have multiple drop-offs. So as the TL runs over various units it could have connection to allow data to be transferred to the underlying unit or data to load up from the underlying unit. Multiple TL can run in parallel over the same row or column of units with connectivity to all or some of the underlying units. The connectivity to the underlying units could split between the parallel running TL to share the data transfer load between these parallel running TLs. The modulation techniques could allow many channels of data to run over the same TL without interfering with one another. These modulation channels could be allocated as part of the 3D system setup procedure or be dynamically allocated as part of the system operation. The other communication technologies could be used to manage such allocation as part of the 3D system control structure. These could include the use of broadcast technology or utilizing a low frequency band to transfer the control information to support better overall X-Y connectivity.

Multiband communication in TLs could also be used for congestion management. Routers could be designed to include traffic monitoring and adaptive routing algorithms. One or multiple frequency bands could be reserved for these routers if traffic congestion on a link is high, ensuring forward progress of communication. Elbrahimi, et al., “HARAQ: Congestion-aware learning model for highly adaptive routing algorithm in on-chip networks,” Int'l Symp. on Networks-on-Chip 2012, incorporated herein by reference, includes an algorithm for learning from traffic patterns and adjusting accordingly. FIG. 15W illustrates this congestion-aware routing as the message avoids high congestion areas. In the TL network, these X and Y directions would be similar to FIG. 15K.

An alternative for a 3D system could include adaptive allocation of channels within TLs. Thus a unit could use more channels of a TL to transfer at a higher data rate or leave some channels to other units and reduce its own data rate for that chosen time period. To illustrate some of these ideas we can reference FIG. 15O which is FIG. 1 of a paper by Du, Jieqiong, et al. “A 28-mW 32-Gb/s/pin 16-QAM Single-Ended Transceiver for High-Speed Memory Interface.” 2020 IEEE Symposium on VLSI Circuits. IEEE, 2020, incorporated herein by reference. FIG. 15Q illustrated 16 QAM modulation circuits which combine two QPSK modulation sub-circuits. In a 3D system the data routing processor 15861 could use the combined signal 15926 to drive one TL or have a programmable option to use one part of the modulated signal 15922 for one TL and another part 15924 for another TL, these two TL could run in parallel or be designed with one going in the X direction and another going in the Y direction. The 3D system having multiple TLs overlaying the same unit could leverage advanced signal modulation techniques generated by a relatively complex modulation circuit sharing resources and driving multiple TLs. Such advanced modulation techniques could utilize clock circuits for example, such as those marked in FIG. 15O as CCK 15928. The CCK clock could be shared by multiple units or even be shared throughout the 3D system X-Y connectivity to support advanced and efficient data modulation techniques for better X-Y connectivity. The distribution of the clock signal could be accomplished by using a conventional clock tree, an advanced type such as Harmonic resonant clocking, or by using some of the TLs fabric.

An additional alternative is to construct the X-Y interconnect as a hierarchy having at least 3 steps. First break into X direction(s) and Y direction(s), then to global lines, and finally to local lines. For example, a 3D system having a rectangular shape of 259.2×259.2 mm² having array of unit size 0.2×0.2 mm², results in an array of 1296 by 1296 units. An advantage of the proposed X-Y interconnect hierarchy is to reduce the number of drop-off locations and the associated attenuation. Accordingly the global TL could have 36 drop-off locations from which the data could be transferred to a local TL having 36 drop-off locations arriving to the destination unit, 36×36=1296. The global TL could be structured with thicker and/or wider metal to have a minimum attenuation and thus effectively cover the full length of the 3D system ~259.2 mm. The drop-off to drop-on could utilize the structure as presented in respect to FIG. 15J, and could also provide a signal re-buffering function if engineering tradeoffs and considerations demand. Such hierarchical X-Y connectivity could be in addition to other X-Y connectivity structures presented herein, which would be engineered for the specific 3D system requirements.

An additional consideration of such a 3D system is heat removal from the upper levels, for example, such as, the stack of heterogeneous integration of levels and M-levels 1404 of FIG. 14A herein. U.S. Pat. No. 8,674,470 incorporated herein by reference in its entirety, teaches the use of the power lines to provide heat removal paths from a level in a 3D structure to the bottom most or top most surface where the heat could be removed by air or fluid conduction. This could be an additional function of the per unit vertical pillars such as those used for the vertical bus. These pillars, for example, such as vertical pillars 1414 of FIG. 14B, could be designed to provide good conductivity of power to the specific level and also to remove the heat out of levels that could need heat removal. These heat removal pillars could be considered as ‘thermal vias’. These pillars could be designed to have a good thermal path to the cooling substrate 1401 of FIG. 14A herein, while being electrically isolative. Methods of forming and utilizing a thermally conductive contact while being electrically non-conductive, for example, such as presented in reference to at least FIG. 6 of U.S. Pat. No. 8,674,470. And in a similar way these pillars could be thermally connected and electrically isolated up to and including the top level which could include the heat sink structure for heat removal by air or fluid conduction. In one embodiment, those via may be designed in a way to mitigate or even shield electromagnetic interference.

Moreover, thermal isolation techniques, methods, materials and structures such as disclosed in the entirety of U.S. Pat. No. 9,023,688 could be utilized in the 3D systems and devices disclosed herein. The forgoing U.S. patent and its entire contents are incorporated herein by reference.

FIG. 16A illustrates a side X-Z 1602 cut view of a 3D system similar to the one disclosed in FIG. 14E herein including an upper level 1604 of computing logic. A thermal isolation layer 1605 could be used to keep the heat of the computing logic 1604 from substantially reaching memory stack 1603 disposed underneath, and a heat-sink 1606 could be used to remove the heat out of and off the device/system. The normally conductive power lines (not shown) could be, in part, thermally connected and electrically isolated with respect to heat sink 1606 to help remove the formation and operational heat produced by internal stack 1603 from the top, in addition to heat removal thru to the bottom substrate 1601 with its liquid micro channel cooling 1610.

FIG. 16B illustrates a similar 3D system in which the upper level of compute logic has its own liquid cooling substrate 1614, which could include power delivery lines and trench capacitors in a similar manner as to the bottom substrate 1601. The liquid cooling substrate 1614 could be a part of silicon interposer, or separately fabricated and bonded into the 3D system, or even monolithically integrated with the base die of the silicon substrate of 3D system.

The motivation for hyper-scale integration could suggest adding more compute levels to a 3D system. Yet such compute levels could generate too much heat to be removed just by the power line network. It might be desired to embed levels with liquid micro-channel cooling inside the 3D stack and not just at the bottom and top as is illustrated in FIG. 16B. The micro-channel cooling can be fluidic channels of a coolant or a heat pipe. These micro-channels could further be coupled with conventional passive cooling such as finned heat sink and ventilation slots. In one embodiment of this invention, a micro-channel can include forced convection device such as fans and nozzles. The coolant can be pumped in loops with heat exchangers and cold plates outside of the 3D system.

The challenge is to manage the system vertical (Z direction) connectivity through a thick substrate which could support micro-channel cooling, such as presented by Colgan, Evan G., et al. “A practical implementation of silicon microchannel coolers for high power chips.” IEEE Transactions on Components and Packaging Technologies 30.2 (2007): 218-225, incorporated herein by reference. Such a substrate could be at least 50 μm thick and could require TSVs through it having diameters of about 5 μm. The pillars used for the vertical bus could use a through layer via, also called nano-TSV, with diameters of less than 1 μm. One approach to manage such a vertical connectivity challenge could be to modulate the signal through the TSV such as by using RF interconnects or optical interconnects similar to what have been presented for the X-Y connectivity herein.

FIG. 16C illustrates a side X-Z 1602 cut view of a 3D system with embedded micro-channel cooling substrate 1624. The substrate could include TSVs 1622 which could be used for power line connectivity through the substrate and electromagnetic wave carrying modulated data. The layer below 1623 and the level above 1626 could include the circuits to control, generate, and detect the electromagnetic modulated data travelling through the TSVs 1622. The top level could include additional X-Y electromagnetic connectivity 1628 or connectivity to an external device which could support wireless connectivity.

Transferring data in and out (I/O) of the 3D System could utilize many technologies such wiring and bonding technologies. Use of wireless technology could be an attractive option leveraging the layer transfer concept as presented herein. Thus the upper level 1626, 1628 could have an M-Level designated for system level IO. Mobile technology progress such as G5 promoted the fast development of on chip RF circuits. Multiple papers suggested the use of wireless technology for Network on Chip (“NOC”) application such as presented by Deb, Sujay, et al. “Wireless NoC as interconnection backbone for multicore chips: Promises and challenges.” IEEE Journal on Emerging and Selected Topics in Circuits and Systems 2.2 (2012): 228-239; by Yu, Xinmin, et al. “Architecture and design of multichannel millimeter-wave wireless NoC.” IEEE Design & Test 31.6 (2014): 19-28; by Mineo, Andrea, et al. “Exploiting antenna directivity in wireless NoC architectures.” Microprocessors and Microsystems 43 (2016): 59-66; and by Kim, Ryan Gary, et al. “Wireless NoC for VFI-enabled multicore chip design: Performance evaluation and design trade-offs.” IEEE Transactions on Computers 65.4 (2015): 1323-1336, the entirety of all of the forgoing patents and papers are incorporated herein by reference. Some suggested hybrid system connectivity using both TLs and or waveguide and wireless such as in a paper by Agyeman, Michael Opoku, et al. “A resilient 2-D waveguide communication fabric for hybrid wired-wireless NoC design.” IEEE Transactions on Parallel and Distributed systems 28.2 (2016): 359-373, incorporated herein by reference. These wireless connectivity techniques could just as well be used also to connect the 3D system to external devices providing system level I/O. Such could include also technologies such plasmonic technology as presented in a paper by Zhang, Hao Chi, et al. “A plasmonic route for the integrated wireless communication of sub diffraction-limited signals.” Light: Science & Applications 9.1 (2020): 1-9, all of the forgoing incorporated herein by reference in their entirety. Extending the use of wireless, such as been presented for NOC, for connecting the 3D system to external devices, could be attractive as it could share resources for both NOC and connectivity to external devices. FIG. 16F illustrates such a concept. The 3D system 1662 could be placed in proper (determined by engineering considerations and tradeoffs) proximity to connectivity structure 1664. There may be tens or hundreds of wireless channels connecting the 3D system to the external connectivity device(s). Such parallel connectivity could enhance the overall system by providing wide and parallel distributed connectivity for the 3D system. The connectivity structure 1664 could be connected with fiber optic 1666 to an upstream data source. The connectivity structure 1664 could be constructed with a similar technology to the 3D system or utilize conventional PCB type integration technology, depending on engineering and commercial tradeoffs. The 3D System I/O structure of FIG. 16F could be applied to other type of wireless connection such as optical such as by use of diode laser and could include advanced signaling such as orbital angular momenta (OAM). Such could be used for RF type or optical type wireless connectivity. In a recent paper by Bahari, Babak, et al. “Photonic quantum Hall effect and multiplexed light sources of large orbital angular momenta.” Nature Physics (2021): 1-4, incorporated herein by reference, an ‘Unlimited’ Data Capacity using OAM is presented. Other techniques could also be used to increase the channel capacity leveraging the proximity between the structures 1662, 1664 forming such wireless connectivity.

For optical types of electromagnetic modulation, the via could be made optically transparent either by proper oxide filling or left unfilled. Similar optical via connectivity has been presented in U.S. Pat. Nos. 7,203,387 and 8,916,910, incorporated herein by reference.

For RF type of electromagnetic modulation the via could be copper filled or a Coax-like TSV transmission line using conformal side wall filling outer shell of metal, then an inner oxide, and then metal again. This structure could be accomplished by using ALD or other types of conformal deposition. RF-type TSVs are known in the art, for example, such as presented in U.S. Pat. Nos. 8,618,629, 8,759,950, 8,916,471, and in a paper by Bleiker, Simon J., et al., “High-aspect-ratio through silicon vias for high-frequency application fabricated by magnetic assembly of gold-coated nickel wires.” IEEE Transactions on Components, Packaging and Manufacturing technology 5.1 (2014): 21-27; by Vitale, Wolfgang A., et al., “Fine pitch 3D-TSV based high frequency components for RF MEMS applications.” 2015 IEEE 65th Electronic Components and Technology Conference (ECTC). IEEE, 2015; by Ebefors, Thorbjörn, et al., “The development and evaluation of RF TSV for 3D IPD applications.” 2013 IEEE International 3D Systems Integration Conference (3DIC). IEEE, 2013; the entirety of all of the forgoing patents and papers are incorporated herein by reference.

Another option is to build special M-Levels designed for a cooling substrate to be inserted inside the 3D stack. Such a SubstrateM-Level could utilize conventional TSVs with a redistribution layer connecting these large TSVs to relatively smaller TSVs used in-between units for the per unit vertical bus. For a unit sized about 200 μm×200 μm, the area for 100 large TSVs 5 μm×5 μm could be about 100×5/200×5/200=1/16 of the unit area leaving room for the micro channels and the trench capacitor.

FIG. 16D illustrates a side X-Z 1602 cut view of a cooling substrate 1644 with TSVs 1646, and logic level 1634 with redistribution layers and pads 1636 for the TSVs and in-between units pins for the vertical bus 1632 (two are shown).

FIG. 16E illustrates a side X-Z 1698 cut view of a SubstrateM-Level 1650 formed by adding top redistribution layer 1654 to the hybrid bonded structure of FIG. 16D. The per unit vertical bus pin/pads 1632, 1652 are connecting the vertical bus using the TSV 1646 through the cooling substrate. The cut layer 1656 could be used to separate the SubstrateM-Level from the carrying substrate 1658.

Using such a SubstrateM-Level a 3D system could include multiple compute levels and memory levels with X-Y connectivity levels in-between, while the system heat could be managed by liquid cooling.

FIG. 16G illustrates a side X-Z 1698 cut view and FIG. 16H illustrate a X-Y 1699 cut view of a 3D system with additional cooling liquid distribution structure. The arrows in the FIG. 16G and FIG. 16H illustrate the direction of coolant or cooling liquid flow. Using similar techniques such as oxide to oxide bond to bond a thicker substrate 1674 which could be made from a glass type material or a silicon wafer. The thicker substrate 1674 could be formed with Y direction wide tunnels 1672, 1676 having width and depth such as sub mm, few mm or even a few tens of mm. The XY size of thicker substrate 1674 could be greater than the rest of 3D system so that the thicker substrate can accommodate the 3D system with a sufficient thermal area margin/overlap of its edge region. The Y direction wide tunnels 1672 could be an odd numbered group and another Y direction wide tunnel 1676 could be an even numbered group. Each Y direction wide tunnel groups 1672 and 1676 could be joined into one tunnel near the edge of 3D systems as illustrated in FIG. 16H. Each Y direction tunnel groups share their respective inlet or outlet of external coolant circulation system. These tunnels 1676, 1672 serve as the main pipes to circulate cooling fluids to the in silicon X direction tunnels such as 1670, 1610, and 1624 and are designed to have multiple times the fluid transferring capacity. So while the silicon tunnels are embedded close to the active devices of the 3D system and are designed to have low thermal resistance from the active transistors, the thicker substrate 1674 is designed to support an overall higher cooling circulation to remove the heat out from the in silicon tunnels such as 1670, 1610, 1624. Some of the tunnels 1676 will be utilized to bring in 1678 cool liquid, such as water, through dedicated pipes 1680 to the X direction tunnels 1670 of the base of the 3D system. And some of the tunnels 1672 will be utilized to bring out the heat carrying liquid. Such a multilevel liquid distribution network could be used for large area 3D systems to achieve effective cooling and heat removal. Such a multilevel liquid distribution network could include the larger pipes 1676, 1672 as the first level supporting the finer pipes 1610, 1624 which are in close proximity to the device levels in which the heat is been generated. The fabrication process could use techniques know in the art such as etching deposition and level bonding. The specific design could consider the specific heat removal needs and fluid dynamic considerations as could be designed by an artisan in the art. The detailed design could include layout optimization to further equalize the overall fluid flow in the 3D system. This may include narrowing the in silicon tunnels 1670 closer to the device edge (near the Cold coolant in) in which the main pipes 1676, 1672 could have higher fluid pressure. This could also include narrowing the main pipes inlets 1676 and widening the main pipes outlets 1672 as it is gets further from the “Cold coolant in” and closer to the “Heated coolant out” side. Parallelizing the Y direction wide tunnel and the X direction narrow tunnel would result in minimizing the temperature gradient within the area compared to a spiral single channel solution or single direction solution. Cooling semiconductor circuit with cooling fluid and using it in substrate etched pipes was presented in a paper by Wang, Shaoxi, et al. “3D integrated circuit cooling with microfluidics.” Micromachines 9.6 (2018): 287 and by C. J. Wu, S. T. Hsiao, et al. “Ultra High Power Cooling Solution for 3D-ICs” VLSIT JFS1-4 (2021), all are incorporated herein by reference.

For multiple level 3D systems, it could be desired to add a logic level that could be optimized for data movement rather than data processing, for example, such as we have seen in the past with an Intel 8237, a direct memory access (DMA) controller, as part of the MCS 85 microprocessor system. Such a 3D system, as is illustrated in FIG. 16C, could include a base of water cooled processors level(s), overlaid by a high speed memory M Level, overlaid by high density memory M Level, overlaid by a dedicated data movement M Level, overlaid by an X-Y connectivity M Level, overlaid by a high density memory M Level, overlaid by a high speed memory M Level, overlaid by an additional water cooled processor M Level, overlaid by a device to external system connectivity M Level. A heat spreader layer could be used to average the heat between the various units to reduce the local heat spots. A phase change material layer could be used to average the heat over time to reduce the momentarily heat peaks. And active heat management could be used by integrating per zone, for example, such as per unit temperature sensors integrated with temperature control circuits. Such temperature control circuits could also control the unit processor operations to prevent overheating. Such could be done by slowing down the processor clock(s) or reducing the processor power voltage or changing the periodic quiet time, or activate a shut down. These active techniques manage the operating speed to avoid overheating. The outlined 3D system integration reduces the overall interconnects of the system and accordingly allows a far more power efficient and speed efficient computing system. Yet, power budgets and heat budgets provide limits to the 3D system operation. These heat management techniques allow optimized operation within such an overall heat budget.

Another alternative is to include use of multiple steps of simple bonding and thinning, and then using TSV processing to form the vertical bus pillars through the levels-stack and then form the pin/pads for the full M-Level for the following steps of hybrid bonding integration. Such a flow is presented with the use of FIGS. 17A-17D. The advantage for such a flow is the saving of pin/pads formation for the inner levels of such a levels-stack.

FIG. 17A illustrates a side X-Z 1702 cut view of a base level 1706 and an inner level 1704. Each of these levels is structured with spaced units 1724 and in-between connections 1722 which could be used for later connection to the vertical bus pillar 1726. FIG. 17A also shows the two levels being F2F bonded to each other creating structure 1708, in which the inner level 1704 has been flipped and bonded to the base level 1706.

FIG. 17B illustrates the structure after removal, ‘cut’ of the inner level 1704 carrying substrate 1705.

FIG. 17C illustrates the structure after repeating the process five more times forming a level-stack of base level and six inner levels bonded on-top.

FIG. 17D illustrates the structure after forming a through stack via (TSV) 1726 and bonding pin/pad 1724. The inner level thickness could be about 100 nm or larger such as about 0.5 μm, about 1 μm, about 2 μm, about 4 μm or even more than about 6 μm. The through stack via (TSV) 1726 (through the level-stack) could go through few tens of microns which is common for TSVs in the industry. The metal filling of the via could form simultaneously the connection to the horizontal between the units in-between connection lines 1722. Such is not common and would need proper tuning of the process by an artisan in semiconductor processing. It reasonable to expect that such a through stack via would require a larger space between units 1730 than what would have been required if the via would be formed for each level independently, thus increasing the structure size, and yet the simplicity of the process could make it attractive in some applications. The industry is improving the etch technology for such vias and an aspect ratio of 1:20 has been demonstrated. Thus, for a level-stack of 20 μm thickness a via of about 1 μm diameter could be manufacturable.

An important aspect of such a 3D system is the memory technology used for the memory level(s). A specific memory technology named 3D NOR-P has been presented in at least U.S. Pat. No. 10,892,016 and U.S. application Ser. No. 16/483,431 (now US 2020/0013791), incorporated herein by reference. In the following some enhancements for such a 3D NOR-P technology are presented.

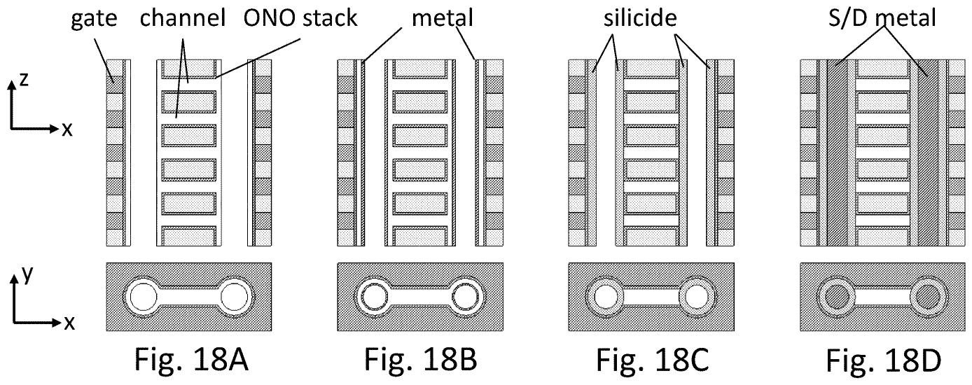

Another embodiment of this invention is related to the process steps which may be used to form Schottky Barrier S/D junctions. More specifically, a method to precisely form a silicide layer. FIGS. 18A-18F are cross-sectional cut views of XY and XZ sectioning of an illustrative 3D NOR-P structure, showing exemplary process steps. FIG. 18A illustrates the process after polysilicon channel deposition and before S/D formation similar to FIG. 1P or FIG. 1G of U.S. Pat. No. 10,892,016, incorporated herein by reference.

FIG. 18B shows the metal, such as, for example, Ni, Co, Ti, Ta, W, Cu, Pt, Al, or their alloy metal deposition for a silicidation process. In this step, a very thin metal liner is deposited by a capable method/machine, for example, atomic layer deposition (ALD) or molecular beam epitaxy (MBE). The atomically thickness controlled metal liner would be ranging from 3 nm 20 nm in thickness. For the nominal process, the volume of the metal would be deposited so to be fully consumed and form a silicide without leaving substantially any un-reacted metal behind.

FIG. 18C shows the structure after silicidation by annealing. The annealing may be conducted by a process which promotes the silicidation reaction, for example, such as rapid thermal annealing, laser spike annealing, microwave annealing or their various combinations. By constraining the metal supply and fully consuming the metal, the silicide depth and interface would be uniform. The use of thin metal would lead a self-limiting reaction property. After the self-limiting silicidation, the remaining holes can be filled by other metal(s) to form a large portion of the S/D as shown in FIG. 18D. An artisan in the art could adapt such a Schottky Barrier S/D junction formation to the other memory structures utilizing Schottky Barrier S/D junctions presented herein or in the incorporated by reference art herein.

An advantage of 3D NOR-P when compared to many other 3D memory structures is found in the variability tolerance due to its architecture. In general, the high aspect ratio etch inevitably involves bowing and twisting variation at top and bottom, as is illustrated in FIG. 18G. In the 3D NAND architecture, those variations directly reflect into the program and reading operations because the NAND architecture uses one very long shared channel called a ‘string’. Sometimes, the variability would be too high and the device would be considered defected. In many cases, each cell's variability would require a different operation voltage for different WLs. Furthermore, 3D NAND programming requires incremental step pulse programming (ISSP), which uses multiple repetitions of a gentle programming operation followed by verification. Such a method inevitably slows the programming operation. In contrast, the 3D NOR-P architectures use one channel per corresponding bit cell. Therefore, the variability issue would be much less than that of 3D NAND. In one embodiment of this invention, the programming and erasing voltage could be constant across the different WL levels. Furthermore, whereas 3D NAND uses ISSP and ISSE, the programming and erasing voltage pulses of the 3D NOR-P could use only a single pulse, thus providing a faster than 3D NAND program and erase operations.

Another advantage of 3D NOR-P technology with Schottky Barrier S/D is related to the immunity to source-and-drain separation variation. Typically, a current-voltage characteristic of a standard transistor with degenerately doped (n+) S/D suffers from the source-and-drain separation or gate length. The program efficiency could also largely be affected by the gate length because the electron would need to travel the different channel length to be available as a hot electron for programming. In other words, the drain-side injection for programming is naturally suffering from any channel length variability. Consequently, a standard transistor based NOR flash memory tends to suffer from the variability issue. However, the current that flows into the channel in a Schottky Barrier S/D is restricted by the source barrier. As a result, the Schottky Barrier S/D is inherently insensitive to the gate length. Such gate length insensitivity was demonstrated by Sporea, Radu A., et al. “Effects of process variations on the current in Schottky Barrier Source-Gated Transistors.” 2009 International Semiconductor Conference. Vol. 2. IEEE, 2009; incorporated herein by reference. This advantage is even more significant for high speed applications for which the use of techniques such as incremental step pulse programming (ISSP) would slow the write cycle and thus defeat the high speed objective.

A thermo-mechanical stress may be induced during processing of a NOR-P structure. The thermo-mechanical stress can cause reliability issues such as bowing of a wafer. This is mainly due to the Coefficient of Thermal Expansion (CTE) mismatch between materials used in the structure. The major CTE mismatch may occur between metal such as metal S/D and non-metal such as oxide, nitride, and polysilicon. In an embodiment of this invention, an empty space or void is introduced on purpose in order to mitigate the thermo-mechanical stress. An example is shown in FIG. 18E. The void is made inside the S/D metal pillar. The void may be formed during metal deposition. When the thermal expansion mismatch occurs, the void may play as stress damper as the stress would be absorbed.

A modified flow for the one above is to follow the step associated with FIG. 18B with additional metal 1854 deposition as shown in FIG. 18F. So, the first thin metal 1852 may be selected to possess a high silicidation capability such as, but not limited to, Nickel (Ni), Titanium (Ti), or Cobalt (Co), while the second and thicker metal 1854 could be selected to possess a slower silicidation capability, such as, for example, Tungsten (W). Alternatively, the first thin metal 1852 is chosen from metals which react with silicon at a relatively lower temperature, such as, for example, less than 400° C., while the second thicker metal 1854 could be chosen from metals which react with the silicon only at relatively higher temperatures, such as, for example, greater than 600° C. Thus, performing the post metal deposition anneal step at a relatively lower temperature so to engineer the silicidation to be primarily with the first thin metal 1852 and very little with the second thicker metal 1854, resulting with a structure similar to the one illustrated in FIG. 18E. With this flow the presence of the second metal 1854 during the anneal could help with the anneal heat transfer, of the second metal 1854, to reduce heat exposure time at temperature variation between the various Schottky Barrier S/D junction locations. Thereby resulting in a more uniform Schottky Barrier S/D junction depth and shape, resulting in more uniform device characteristics across and up & down the arrayed memory cells.

Another modified flow (not drawn) is to add thin amorphous silicon layer in-between the channel polysilicon and the metal(s) for silicidation to form the Schottky barrier S/Ds. As the metal silicidation annealing progresses, metal diffusion is faster along the grain boundary of the polysilicon channel. Such fast diffusion through the grain boundary can cause a silicidation spike, which can cause failure of the device. In order to avoid the metal directly interfacing with the grain boundary, a thin amorphous phase silicon film is inserted between the polysilicon channel and the metal for the silicidation. This interface of amorphous silicon may have a thickness ranging, for example, from 5 nm to 10 nm. The interface amorphous silicon may optionally include an n-type dopant, for example such as Phosphorous or Arsenic, to help form a dopant segregated Schottky Barrier S/D.

Another alternative is to utilize a concept known as MIS—Metal-Insulator-Semiconductor contact. As the device scales down, the discreetness of dopant could be a source of increasing variability in contact resistance. A very thin interlayer dielectric semiconductor and metal could reduce atomistic variation. In traditional approaches of MIS contact, the interlayer oxide needs to be not only thin enough but also have conduction band edge Fermi level pinning in order to not degrade the contact resistance itself as presented in at least U.S. Pat. Nos. 9,240,480B2, 9,735,111B2, and 9,613,855B1 the entire contents of the forgoing are incorporated herein by reference. However, this invention is differentiated by the fact that the Fermi level of the interlayer dielectric may be formed at 0.1~1.0 eV lower than the conduction band edge, in order to maintain a hot-carrier generation capability near the Schottky junction. So in reference to FIG. 1W a thin oxide layer 152 could serve as a barrier between the metalized S/D pillar 154 and the channel. The oxide layer 152 could be about 0.1 nm to about 0.3 nm, about 0.3 to about 0.6 nm, about 0.6 nm to about 1 nm or even thicker depending on product, engineering, circuit and design considerations and tradeoffs. The thin barrier could help achieve a consistent S/D to channel barrier and a stable Schottky Barrier for all cells in the memory array. Such an approach may not only reduce the variability due to the discreetness of the dopant; it may also reduce the variability due to the grain boundary of the metal and the polysilicon channel.

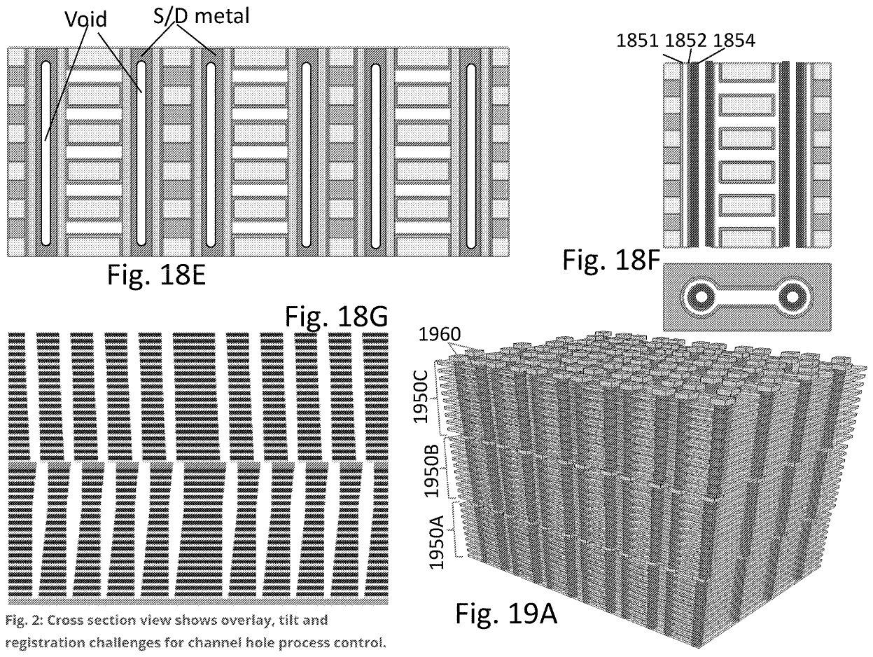

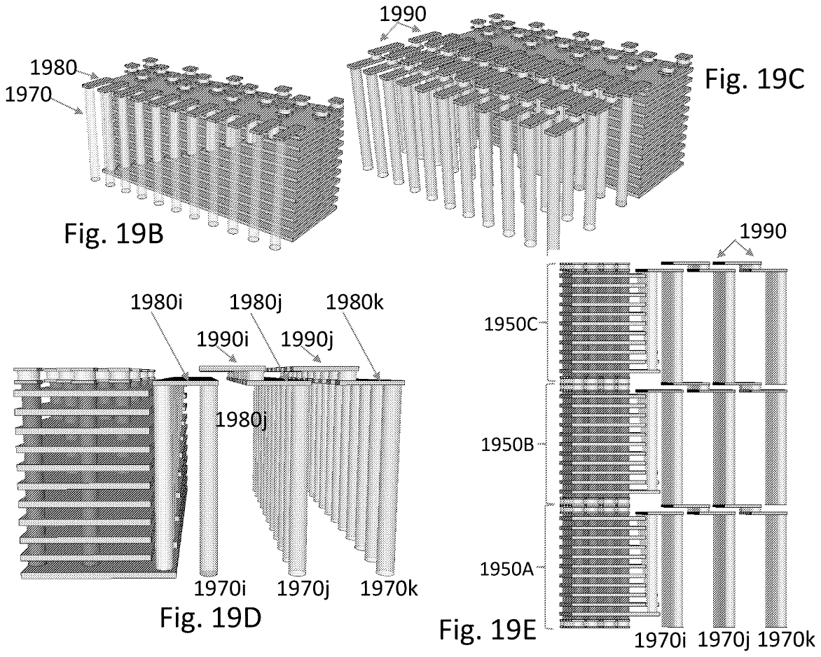

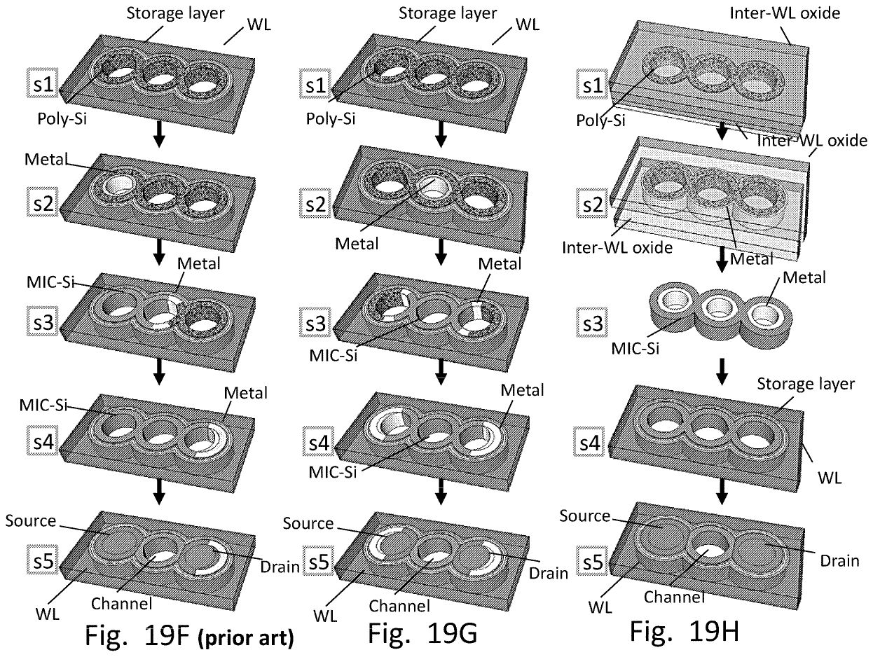

A memory capacity demand per chip may exceed the memory capacity of the wafer fabrication technology. In order to increase the memory capacity per chip, multiple memory wafers can be stacked over each other. In one embodiment, illustrated in FIGS. 19A to 19E, a 3D NOR-P wafer can include multiple stacks of 3D NOR-P blocks, where each of 3D NOR-P block, 1950A, 1950B, and 1950C are fabricated on different wafers. The memory wafers can be stacked, for example, by using wafer bonding technology. For this, each 3D NOR-P block would include a bonding pad 1960. FIG. 19A shows one example of a stacked 3D NOR-P block. The S/D lines are vertically aligned so that each vertically stacked S/D line shares the same BL and SL address. In this case, however, the WL in one wafer block should not share the corresponding WL in another wafer block. Thus, staircases of WL contacts are necessary for all individual WL layers. In order to achieve an individual/unique WL addresses of all the individual WL layers, an example of forming wafer block staircase WL, is presented in the following, wherein a staircase WL is also formed within a wafer block as shown in FIG. 19B-FIG. 19E. Hereinafter, the staircase WL within a wafer is called a local WL staircase. The staircase WL that connects staircase WL of one wafer and that of another wafer is called a global WL staircase.

In one embodiment of this invention, each of local staircase WL contacts is connected with its own vertical jumping metal plug 1970 through a local staircase jumper 1980 as illustrated in FIG. 19B. The jumping metal plug 1970 penetrates substantially the entire height of a NOR-P level. For multiple stacked NOR-P blocks, a global WL staircase is needed. Depending on how many NOR-P wafers are to be stacked, the same number of jumping metal plug groups are added as illustrated in the FIG. 19C example. The additional jumping metal plug is connected via global staircase jumper 1990. For better view of local staircase jumper 1980, global staircase jumper 1990, jumping metal plug, FIG. 19D is a side view of FIG. 19C. The left side of global staircase 1990, and right side of local staircase 1990, is in open (electrically not connected, non-conductive) while the right side of global staircase 1990, and the left side of local staircase 1990ₙ₊₁ is in short (electrically connected, conductive).

FIG. 19E shows global WL staircase connections for the case of three NOR-P blocks being stacked. The first jumping plug 1970i connects the local WL staircase of the first NOR-P block 1950A, the second jumping plug 1970j connects the local WL staircase of second NOR-P block 1950B, and the third jumping plug 1970j connects the local WL staircase of third NOR-P block 1950C. By doing so, every individual WL of stacked WLs can have a dedicated WL control signal from the peripheral logic circuit. Such a method which connects between local staircases and global staircases can be applied to other control lines, for example, such as BL and SL. Furthermore, the same method can be used in other 3D memories such as 3D stacked NAND, RRAM, and PCRAM. The above stacking concept is similar to the concept presented in respect to FIG. 22A-22B and FIG. 27A-27D of U.S. patent application Ser. No. 16/558,304 (now U.S. Patent Publication 2020/0176420), incorporated herein by reference in its entirety.

Aa One embodiment of 3D NOR-P memory device is a process step for metal induced crystallized silicon channel. 3D NOR-P. The process step could be used to form a substantially large grain sized metal induced crystallized (MIC) silicon channel from small grain sized polysilicon or amorphous silicon channel. The small grain sized polysilicon or amorphous silicon refers to a semiconductor phase of as-deposited by chemical vapor deposition process. For simplicity, “poly-Si” in this invention refers to as-deposited silicon before the crystallization process while “MIC-Si” refers to the recrystallized poly-Si after metal induced crystallization process. The seed metal and temperature requirement for the crystallization could be found in Yoon, Soo Young, et al. “Metal-induced crystallization of amorphous silicon.” Thin Solid Films 383.1-2 (2001): 34-38, incorporated herein by a reference. Furthermore, the channel material of 3D NOR-P presented in this invention could be, but not limited to, polycrystalline germanium, amorphous germanium, polycrystalline silicon germanium, amorphous silicon germanium, or their metal induced crystallized semiconductors. The seed metal and temperature requirement for the crystallization could be found in Kang, Dong-Ho, and Jin-Hong Park. “Indium (In)- and tin (Sn)-based metal induced crystallization (MIC) on amorphous germanium (α-Ge).” Materials Research Bulletin 60 (2014): 814-818 and Peng, Shanglong, et al. “Low-temperature AI-induced crystallization of hydrogenated amorphous Si₁₋ₓGeₓ (0.2≤x≤1) thin films.” Thin solid films 516.8 (2008): 2276-2279, incorporated herein by a reference. The device structure of 3D NOR-P is presented in U.S. Pat. No. 10,892,016, incorporated herein as a reference. FIG. 19F shows a method to form MIC silicon in 3D NOR-P in the prior art. FIG. 19G and FIG. 19H show another method to form MIC silicon in 3D NOR-P presented in this invention. For simplicity, only single layer unit memory cell is drawn. The prior art drawn in FIG. 19F depicts a metal induced crystallization process occurs lateral direction. Step s1 shows multi stacked horizontal layers of material alternating silicon oxide as inter-WL oxide and degenerately doped polysilicon as wordline (WL) are formed. For better view, only a single layer of WL is shown here but inter-WL oxide is not drawn. A unit memory cell consists of three holes of hollow cylindrically shaped poly-Si that extends vertically with respective to wafer substrate, where a portion of poly-Si near the center hole could become a channel region and portion of poly-Si near the left and right hole could become source and drain region. The storage layer is formed in between outer surface of hollow cylindrically shaped poly-Si and WL. The storage layer could be stack of tunneling oxide, charge trapping layer such as silicon nitride or floating gate, and blocking oxide. Step s2 shows a thin layer of metal such as Ni, Al, or Cu deposited on the inner surface of poly-Si hole to be either source or drain. Step s3 shows an intermediate stage of MIC process, demonstrating that the metal is migrating laterally toward opposite direction and leaving MIC-Si behind. Step s4 shows final stage of MIC process, demonstrating that the metal arrived the drain or source region and the poly-Si of channel region becomes MIC-Si. Step s5 shows the device structure after subsequent source and drain process. Compared to the process depicted in FIG. 19F, the processes presented in this invention could provide shorter process time. FIG. 19G depicts a MIC process presented in this invention. Step s1 shows multi stacked horizontal layers of material alternating silicon oxide as inter-WL oxide and degenerately doped polysilicon as wordline (WL) are formed similar to that shown in FIG. 19F. The storage layer is formed in between outer surface of hollow cylindrically shaped poly-Si and WL. The storage layer could be stack of tunneling oxide, charge trapping layer such as silicon nitride or floating gate, and blocking oxide. Step s2 shows a thin layer of metal such as Ni, Al, or Cu deposited on the inner surface of poly-Si hole to be the channel region. Step s3 shows an intermediate stage of MIC process, demonstrating that the metal is migrating radial direction first from inner to outer surface of hollow poly-Si in the channel followed by lateral direction toward source and drain region, leaving MIC-Si behind. Step s4 shows final stage of MIC process, demonstrating that the metal arrived the drain or source region and the poly-Si of channel region becomes MIC-Si. Step s5 shows the device structure after subsequent source and drain process. FIG. 19H depicts another embodiment of MIC process presented in this invention. Step s1 shows multi stacked horizontal layers of material alternation silicon oxide as inter-WL oxide and silicon nitride as sacrificial layer to be replaced with metal or other conductive WL material. Step s2 shows a device structure after selectively removing a sacrificial silicon nitride followed by a thin layer of metal such as Ni, Al, or Cu deposited on the outer surface of poly-Si. Step s3 shows final stage of MIC process, demonstrating that the metal is migrated radial direction from outer to inner surface hollow poly-Si, leaving MIC-Si behind. Step s4 shows a device structure after removing the metal arrived in the inner surface of MIC-Si, followed by forming storage layer and WL. The storage layer could be stack of tunneling oxide, charge trapping layer such as silicon nitride or floating gate, and blocking oxide. Step s5 shows the device structure after subsequent source and drain process.

An important advantage of the 3D NOR architecture, and more so for 3D NOR-P with metalized S/D pillars, is the ability to stack hundreds of levels yet have a low impact on device performance, particularly the value of the sensing current. The common 3D NAND architecture is very sensitive to the number of levels because the channel is connected in series with adjacent transistors, which is called a string, as previously mentioned. Therefore, when a random cell is accessed, the current has to flow through each of the transistors in the string. As the current through the channel get reduced as the number of levels increase and accordingly limits the number of levels that could be stacked. In the 3D NOR-P, when a random cell is accessed, the current flows thru only one selected transistor. The punch hole through the stack of levels is designated for S/D and with metalized S/D the conductivity is a few orders of magnitude better than that of the 3D NAND channel, thus allowing for relatively orders of magnitude more 3D levels. Therefore, the size of manufacturable memories can grow rapidly, easily, to 100×/1000× or more in density with little or no loss in performance.

FIG. 20A and FIG. 20B provide tables of the main attributes of high-speed memory such as SRAM, DRAM; and medium speed memory such as NOR, Storage Class (SCM); and high-density memory such as NAND. As we can see, these memory technologies provide trade-offs between densities, access time, and power. The power trade-off could include write power and standby power; the access time trade-off could include read access and write access. The density trade-off could include cell size, number of levels, and how many bits per cell are programmable. These trade-offs could be made to better support the desired application. For example, in an Artificial Intelligence (AI) application there could be built-in a physical and electrical difference between the memory portions used for data versus the memory portions used for the weights, the weights generally require many more reads than writes. Thus, for this example, the data could be stored in cells with no or minimal tunneling oxide, while the weights could be stored in cells with a greater than about 1 nm tunneling oxide to reduce the need and power of refresh at the trade-off of a longer write time.

The 3D NOR-P could be structured to support memory cells designed and processed to better match these trade-offs by changing the cell structure such as thin or thicker tunneling oxide. Such could be done along the X-Y direction with proper masks or along the Z direction such as with stacking—for example FIG. 19A. Adapting to better match the application could also be done by the memory control such as by the use of mirror bits or multilevel cell storage techniques.

The term ‘electron charging’ herein means the increase in net density of electrons by trapping electrons or de-trapping holes in the charge trapping layer. Similarly, the term ‘electron discharging’ describes the decrease in net density of electrons by de-trapping electrons or trapping holes in the charge trapping layer. In the binary bit or one bit per cell operation, term ‘programming’ and ‘erasing’ could be interchangeably used as “write 0’ and ‘write 1’, respectively.

A method of operation for 3D NOR-P is presented to compensate for the cell-to-cell variation. In the conventional memory operation, a memory state such as threshold voltage is compared with a reference level, where the reference level could be a fixed value made by external voltage generator or a control line such as bit-line of unselected neighboring block. However, process induced variability and variability in programming and erasing operations may result in a wide spread of the threshold voltage distribution. With a large threshold voltage distribution, a fixed reference voltage level for the reading operation could result in a failure or may require additional reading time to resolve the reading operation. A self-referenced or differential operating mode and control circuits could overcome such cell to cell variations.

The differential operating mode and control circuits scheme utilize the memory cell itself for generating the reference signal for that cell reading operation. The concept is a modified technique originally applied to mirror-bit cells for differential operating mode. It leverages the aspect of the charge trap and the non-conductivity of the trap layer to form an asymmetry of channel resistance distribution along the source to the drain side.

FIG. 20C illustrates a 2×2 array structure of 3D NOR-P. FIG. 20D illustrates an example of write voltages to such memory cells and is illustrated on a single cell for four situations. The arrow indicates the direction of electron charging. A filled circle in the charge trap layer illustrates the filled localized electron charged zone and an only outlined (empty) circle in the charge trap layer illustrates the emptied localized electron charged zone (holes). It should be noted that the absolute voltage values exemplified as these values are to be set for the specific memory structure.

Such charge-trap memory cells could be used for a self-referenced (differential) reading operation. For the state ‘1’, the local threshold voltage of the drain side is lower than the local threshold voltage of the source side. For the state ‘0’, the local threshold voltage of the drain side is higher than that of the source side. Thus, the reading operation conducts a sensing of the imbalance or skew of the local threshold voltage. As a result, the self-referenced reading could tolerate a large cell-to-cell variability.

FIG. 20E illustrates a 2×2 array connected to the sense amplifier (S/A). In conventional memory, the differential inputs of a S/A are connected to one BL and another BL from a different column of a memory array. For a self-reference reading, the differential inputs are connected to the BL and the SL from the same column.

FIG. 20F illustrates the voltage development of a BL of S/A according to the reading time. FIG. 20G shows an exemplified voltage conditions and associated energy band diagrams for the reading operation. First, the same voltages such as 0.5V are pre-charged to the SL/BL to the selected column, the operation could be called ‘SL/BL pre-charge’. Next, a WL voltage greater than the local threshold voltage for reading, for example, such as 1V is applied to the selected row. Then, despite that the SL/BL is pre-charged to the equal potential, a small amount of electrons may flow from source side to channel for state ‘1’ or from drain side to channel for state ‘0’ due to the asymmetric distribution of the cell local threshold voltage. When a small current flow from one of source line or bit line to the channel happens, the pre-charged potential level of the source line or the bit line slightly drops. Next, a S/A is enabled to amplify the slight change in BL and SL of the given column. As a result, the memory state could be sensed by self-reference.

FIG. 20G also shows the voltage conditions and associated energy band diagrams for inhibits to the reading for unselected cells. A WL voltage smaller than the local threshold voltage for reading such as 0V is applied to the unselected row sharing SL/BL. As the read inhibit WL voltage is smaller than the local threshold voltage, no channel current will flow. The BL/SL could be floated for the unselected columns sharing WL. When BL/SL are floating, no channel current will flow. For a 3D NOR-P memory structure which has a body in contact with the channel such as illustrated in FIGS. 27A-27C of U.S. application Ser. No. 16/483,431 the body could be biased to 0 volt to highly accelerate the reading of such a differential cell structure and method.

Another example of a reading method is to accelerate the sensing timing. In reference to the reading voltage condition presented in FIG. 5E of U.S. Pat. Nos. 11,018,156 and 10,892,016, incorporated herein by reference, the WL voltage of 1V for reading is exemplified. In this embodiment, the gate overdrive voltage for the reading could be greater than 1V such as 1.5V or 2V in order to accelerate the channel current or reduces the minimum required time for the sensing. However, the gate overdrive voltage could be limited to the value that rarely causes soft-writing or read disturb to the unselected cells sharing the same BL or disturbance of the memory state of the selected cells during a read operation. For example, at a given write voltage difference across WL and SL/BL, ΔV_{WL_SL/BL}, the read gate voltage could be ranging between 50%~75% of ΔV_{WL_SL/BL}.

Additional alternative of a self-reference type read scheme could utilize over drive to read the saturation current of the memory cell to be used as a read reference signal. The technique could use two read cycles, first for the reference signal and second for the cell memory state signal. FIG. 20H illustrates the bitline current versus wordline voltage characteristics for different memory states and read conditions. A first set of read bias condition {V_{read1}} is applied to the selected cell and a drain current of bitline current, I_{BL1}, is obtained according to {V_{read1}}— the cell memory state signal. A second set of read bias condition {V_{read2}} greater than a first set of read bias condition {V_{read1}} is applied to the same selected cell {V_{read2}} and a drain current of bitline current, I_{BL2} (the saturation current), is obtained according to {V_{read2}}—the reference signal. The difference in the bitline current (I_{BL2}−I_{BL1}) due to the change in the applied bias condition {V_{read2}}−{V_{read1}} depends on the state of the selected memory cell. For example, the wordline voltage of {V_{read2}} could be far greater than the threshold voltage of the state ‘0’ and the wordline voltage of {V_{read1}} could be far greater than the threshold voltage of the state ‘1’ but falling into the subthreshold region of the state ‘0’. The current differential (I_{BL2}−I_{BL1}) for the state ‘1’, could be far greater than the current differential (I_{BL2}−I_{BL1}) for the state ‘0’. As an example, a very small bitline current differential such as less than 100 nA could be observed for the state ‘0’ but a large bitline current differential such as greater than 5 μA cell could be observed for the state ‘1’. The sense amplifier circuit could use ratios rather than a differential technique.

Such sense amplifier technologies are known in the memory art and such techniques and circuits has been presented in at least U.S. Pat. No. 7,590,003 and in papers such as by Jeong, Gitae, et al., “A 0.24-μm 2.0-V 1T1MTJ 16-kb nonvolatile magnetoresistance RAM with self-reference sensing scheme,” IEEE Journal of solid-state circuits 38.11 (2003): 1906-1910; by Tanizaki, Hiroaki, et al., “A high-density and high-speed 1T-4MTJ MRAM with voltage offset self-reference sensing scheme.” 2006 IEEE Asian Solid-State Circuits Conference. IEEE, 2006; by Choi, Jun-Tae, et al., “Novel self-reference sense amplifier for spin-transfer-torque magneto-resistive random access memory.” JSTS: Journal of Semiconductor Technology and Science 16.1 (2016): 31-38; and by Na, Taehui, et al. “Data-cell-variation-tolerant dual-mode sensing scheme for deep submicrometer STT-RAM.” IEEE Transactions on Circuits and Systems I: Regular Papers 65.1 (2017): 163-174, all of which are incorporated here by reference in their entirety.

A further alternative for self-reference reading is to use the 3D NOR memory without leveraging the mirrorbit concept for two bits per cell but rather leaving the drain side zone not as a bit storage site but rather as a reference location to form the self reference signal. Thus, in such a case only the source side of the cell is used to program and erase while the drain side is used only for reading the reference signal. In such an approach two read cycles could be used in a similar way to that presented in reference to FIG. 20H. One read cycle is to read the un-programmed drain side and use it as reference to be compared to the read of the memory site of the source side. The sense amplifier could use a similar circuit to that presented in reference to the self-reference method and structure presented in reference to FIG. 20H herein.

A system with such a multilevel 3D NOR-P structure could include one or few levels of memory control circuits which could support an effective in-system transfer of memory data from one device region to another device region, for example, such as from a high density region to a high speed region. Such has been presented in respect to FIG. 15A-FIG. 17 and FIG. 34A-FIG. 35D of U.S. Pat. No. 10,515,981, incorporated herein by reference in its entirety. Such a transfer could in some cases be controlled by direct connection of one memory zone to another memory zone by connecting their data lines, or by first transferring the data from one zone to a buffer memory and then from the buffer memory to the other zone.

An additional advantage of a 3D memory with memory control logic circuitry placed on at least one or both on top and/or under the memory array is an option to structure the memory with an extremely wide data bus. The common memory in the industry with a relatively narrow bus constrains by the limitation of the number of I/Os and pins available with a low cost device package and the limitation of routing the bus with a common printed circuit board. A 3D architecture in which device control and connectivity to the processor could be done vertically could support extremely wide data bases, for example, such as 32, 64, 128, 256, 512 or even more than 1024 lines. Such an extremely wide bus increases the data rate as well as the bandwidth of memory to processors and especially for multi-core architectures. At least one 3D memory die can be integrated on a processor die by 3D stacking, which may require a close collaboration between processor and memory designer. Alternatively, at least one 3D memory die can be integrated with a processor die through a 2.5D interposer, thus the design of processor and memory could be decoupled. Furthermore, plurality of 3D memory dies and a plurality of processors could be routed through a network-on-chip topology. The network-on-chip could be a conventional metal line based network. Or it could be an optical or RF interposer based network. The processor could be not only be multi-core but also heterogeneous. The heterogeneous integration could include any other exotic devices. Different types of memories such as MRAM, PCRAM, and RRAM could be integrated into a 3D system. A sensor such as LIDAR, 3D camera, and microphone could be directly integrated on the 3D system. In addition to the wide data bus, an advantage of such a 3D integration includes wire length reduction and the consequent power reduction compared to the traditional PCB integration.

An additional advantage of a 3D memory with memory control logic circuits placed on at least one or both of the top and/or under the memory array is that some simple arithmetic/logic units could be included in the memory control logic. Thus, a simple arithmetic and logic operation could be completed in the memory die, significantly increasing system performance and reducing power consumption. The ALU function could also be performed in the memory itself and optimized.

With an extremely wide bus slow memory could sometimes be used for high speed computing applications. An example of high-speed computing could include an AI accelerator for cloud and edge. In such cases relatively slow memory architectures such as 3D NAND could be used for forming a moderate speed system. Accordingly it might be desired in some systems to utilize the 3D NAND architecture with thin tunneling oxide to support a moderately good memory speed with good memory density and low off currents.

In AI computing, a few different AI tasks with different AL algorithms could be necessary. Because of different requirements in performance, efficiency, and size of parameters, their configuration may need to be versatile. In order to accommodate the configurability, a 3D system with 3D memory could include FPGA elements. Alternatively, an array of many process cores and many 3D memory blocks are constituted by configuration of a network on chip. The software could re-configure the memory bandwidth and memory bit width. In some 3D systems, for example, such as mobile systems, alternative (not liquid cooling unless recycled) heat management techniques could be used.

The 3D system as presented herein could be of a full wafer or diced to a sub-wafer size. Such dicing could be done in regular patterns which may be designed to match the yield to maximize the good yield structures out of the multi-level wafer structure. Such dicing could be done by many of the dicing techniques used in the industry. A more advanced dicing technique such as use of plasma etching could be effective and allow flexible dicing patterns as well as reducing the width of the dicing lanes (often called streets) and the associated waste of active device wafer utilization. The dicing or singulation pattern could use a mask pattern or mask-less patterns for even greater flexibility, especially when employing directional etching/matter removal techniques, for example, such as plasma based etching. Laser dicing technology is another alternative for dicing or singulation.

In general the construction of a 3D system as presented herein includes multiple steps of layer transfer. Such layer transfer could include flipping over a donor wafer on top of a target wafer and performing hybrid bonding. Then grind and etch back the donor wafer substrate leveraging a built-in cut layer, for example, such as SiGe. And if needed forming pins/pads for the next step. These steps could include an exchange of role for the donor wafer or target wafer, and substantially removing the substrate from either or both as presented in reference to at least FIG. 13A herein and within many incorporated references. These steps of layer transfer could include use of a carrier wafer as presented multiple times in the incorporated by reference art or as presented in a paper by Jourdain, Anne, et al., “Extreme wafer thinning and nano-TSV processing for 3D heterogeneous integration.” 2020 IEEE 70th Electronic Components and Technology Conference (ECTC). IEEE, 2020, incorporated herein by reference in its entirety. The use of a carrier wafer helps performing the back side adds of pin/pads on a side wafer rather than on the target 3D structure. Additionally it effectively flips back the transferred layer to be aligned to the target wafer in a non-flipped form. So, for example, in reference to FIG. 13A herein, the structure 1318 would have been a carrier wafer then the flow formation to the structure 1330 could be representative of a carrier wafer use prior to the final step of removal of the carrier wafer. The carrier wafer removal process/method could be similar to the removal of a substrate by using grind and etch back to a build-in etch stop layer.

Accordingly the 3D System presented here could provide a flexible framework for end-system formation. It could support a mix and match of device level processing at various fabs using multiple processes. A 3D System could be constructed like a Lego in which the engineering could include use of ‘off the shelf’ generic level(s). An industry standard for the vertical busses and unit size could help support availability of such generic levels for the Lego like system construction. Levels could also include at least one array of programmable cores. Other forms of flexibility could make use of technologies such as (embedded) field programmable logic and semicustom logic as presented herein or in the incorporated by reference art. The flexible framework could include the system construction by the choice of the various levels being stacked in the Z direction, and the choice of a full wafer level or dicing including dicing choices in the X/Y directions. An engineer in the art could engineer specific systems and devices based on the flexible 3D System framework presented herein.

FIG. 21A shows the wafer scale engine of Cerebras Systems Inc as a prior art. The wafer scale engine is square shaped after cutting out the four pieces of silicon from a circle-shaped wafer. Then, the input/output connection pins or pads are located on two edges of the square wafer scale engine.

As an alternative for wafer scale 3D system it could includes IO pads along the circumference of the wafer edge. The IO pins could be at least one rows as seen in the magnified view of FIG. 21B. While the IO pads are usually aligned straight in conventional semiconductor system, the IO pads are could be axially arrayed. The I/O pads could be placed within about 110 um of the wafer edge, within about 220 um from the wafer edge, within about 300 um from the wafer edge, or within about 500 um from the wafer edge. The orientation of the IO pads may be all aligned in one direction, with the preferred direction directly ‘up’ or North’ with respect to the wafer stepper layout, or may be oriented all pointed towards the circular wafer's center, as if on a radial ray from the circle center, or in a changing orientation with location that allows the best attack angle for the pad bonding/connection process. By using a full wafer size to configure a wafer scale 3D system, the real estate utilization of the wafer is unmatched.

Another embodiment is related to the fixture of 3D wafer scale system. Traditionally, the semiconductor chips are encapsulated for the purpose of protecting from the external environment, for example, such as, shock, light, humidity, and dust. The components of the encapsulation materials usually include inorganic fillers such as silica and epoxy resin. Chips for consumer electronics, especially mobile applications, need to be protected from these environmental threats. However, enterprise applications, for example, such as, supercomputer, data center, and server may not require encapsulation because such applications are usually operated in a well-controlled light/humidity/dust environment and the chips are rarely relocated once it is installed. A major disadvantage of encapsulation packaging is its thermal resistance which inhibits thermal dissipation.

Accordingly, to provide better thermal dissipation of the wafer scale 3D system, fixtures that could allow the system to be ‘naked’ could be used as is illustrated in FIG. 21C to FIG. 21E. The fixture could be made to hold and grip the edge regions of the wafer scale 3D system while the central area could be left exposed. The fixture could be configured to connect IO pads of the wafer scale 3D system through the grip region. The fixture may include an indentation according to the shape of the wafer scale 3D system in order for it to sit and firmly hold the wafer/3D system. As illustrated in FIG. 21C to FIG. 21E the wafer scale 3D system is drawn as circular; however, the system shape could be square, rectangular, edge truncated square, or edge truncated rectangular if the wafer scale 3D system is to be sawed. The wafer scale 3D system could include IO pads along the edge region of the wafer as exemplified in FIG. 21B. The material of the bottom part of the chassis could include aluminum, stainless steel, silicon, silicon carbide, glasses, or their metal (such as nickel or gold) plated. The fixture may grip the wafer by various methods.

FIG. 21C illustrates a screw-type fixture. The top and bottom parts of the fixture are separated. The two parts hold the wafer by using a screw and spring mechanism. The number of and placement of the screws and spring is subject to engineering considerations and may be different than the illustrated 4 screws/springs in the illustrated fixture locations. FIG. 21D illustrates a clamp-type fixture. The upper and lower parts of fixture are connected by a vertical hinge. FIG. 21E illustrates a clamshell-type fixture. The top and bottom parts of fixture are connected by a horizontal hinge. When the wafer is mounted, the hinge mechanism grips and holds the wafer. FIG. 21F illustrates an inner view of the bottom part of such fixture. The bottom part of the fixture may include a elastic material such as rubber o-ring or polyimide which can gently applies a pressure to hold the wafer when the fixture is closed. FIG. 21G illustrates an inner view of the top part of the fixture. The top part of the fixture may include a printed circuit board system for signal integrity, power integrity, and other control functions. A PCB could also include a pin that probes the IO pads of the wafer scale 3D system.

Another embodiment could utilize a liquid immersion cooling bath which could contain multiple wafer scale 3D systems mounted through a naked fixture as shown in FIG. 21C to FIG. 21E. The multiple fixtures with naked wafer scale 3D systems could be submerged into a bath of dielectric heat transfer liquid. The bath may optionally contain inlet and outlet holes if a fluid requires the circulation such as single-phase cooling.

Alternatively, the bath could include two-phase cooling fluids. In two-phase cooling, the fluid evaporates on the surface of hot part of the wafer scale 3D system, which removes heat of the hot region from the wafer. The circulation of fluid occurs passively by evaporation and condensation of the coolant. FIG. 21H illustrates a two-phase cooling bath from Gigabyte Technology (https://www.gigabyte.com/Solutions/Cooling/immersion-cooling). PCB boards mounting multiple encapsulated chips are submerged in the bath. As an alternative embodiment, a liquid cooling bath could contain multiple naked wafer scale 3D systems as is illustrated in FIG. 21I.

Another alternative is to use a fixture for the naked wafer scale 3D system which may further include an Ethernet port and power port as is illustrated in FIG. 21J. The Ethernet and power ports are connected to the wafer scale 3D systems through a PCB similar to what was presented in reference to FIG. 21G.

In another alternative, the wafer scale 3D system could be designed to be cut in half as is illustrated in FIG. 21K. The half wafer scale 3D systems could be arrayed through printed circuit board as is illustrated in FIG. 21L. The input/output (I/O) pads could be formed across the center line of the wafer as is illustrated in FIG. 21K. A data channel and address could be shared when multiple wafers are arrayed as is illustrated in FIG. 21L. A half wafer scale 3D system could be mounted directly to a socket. A half-wafer scale 3D system may be naked or encapsulated by an epoxy mold compound or polyimide. In order to address for what wafer the information should communicate to and there from, the I/O pads could include the appropriate wafer identification numbers (ID). In such alternative the arrayed wafer scale 3D system could be interleaving 3D systems. By spreading addresses evenly across the wafer but differencing by wafer ID, memory access, instruction, and other programming could be interleaved by a main controller.

A 3D system presented herein could be considered as a semiconductor device and be integrated into a larger system using other integration technologies used in the industry such as Printed Circuit Board (PCB), interposers, substrates and integration techniques also known as 2.5D, as well as others.

It will also be appreciated by persons of ordinary skill in the art that the invention is not limited to what has been particularly shown and described hereinabove. For example, the use of SiGe as the designated sacrificial layer or etch stop layer could be replaced by compatible material or combination of other material including additive materials to SiGe such as carbon or various doping materials such as boron or other variations. And for example, drawings or illustrations may not show n or p wells for clarity in illustration. Further, any transferred layer or donor substrate or wafer preparation illustrated or discussed herein may include one or more undoped regions or layers of semiconductor material. Further, transferred layer or layers may have regions of STI or other transistor elements within it or on it when transferred. And for example the order of the levels and their function could be different from what have been illustrated here, the use of hybrid bonding or other type of bonding and the relevant alignment techniques and their vertical connectivity could be mix and matched using techniques presented herein or in the incorporated by reference art or elsewhere. Additionally the modular approach of a typical unit based architecture could support a desired flexible system construction such as dicing the 3D heterogeneous integrated wafer to a size of 40×40 mm2 system or too far larger sizes such as 100×100 mm2 system or even using the 3D wafer as a final system. Also the system could be designed with a mix of units having different sizes and/or different functionality including units to support AI calculation and units to support data management and system management. Furthermore, the 3D system could be extended beyond wafer sizes by utilizing panels with built-in wave guides or transmission lines as presented in respect to FIG. 43A to FIG. 43E of U.S. patent application Ser. No. 16/558,304, publication 2020/0176420, incorporated herein by reference.

There many options and engineering considerations to construct specific systems utilizing the techniques presented herein as those in the art could apply. Rather, the scope of the invention includes combinations and sub-combinations of the various features described hereinabove as well as modifications and variations which would occur to such skilled persons upon reading the foregoing description. Thus, the invention is to be limited only by appended claims.

1-23. (canceled)

24. A 3D device, said device comprising:
a first level comprising first transistors, said first level comprising a first interconnect;
a second level comprising second transistors, said second level overlaying said first level;
at least four functional units; and
a redundancy circuit,
wherein each of said at least four functional units comprises a first circuit, said first circuit comprising a portion of said first transistors,
wherein each of said at least four functional units comprises a second circuit, said second circuit comprising a portion of said second transistors,
wherein each of said at least four functional units comprises a vertical connectivity structure, said vertical connectivity structure comprising a plurality of pillars,
wherein said plurality of pillars provides electrical control connection between said first circuit and said second circuit,
wherein each of said at least four functional units comprises at least one memory control circuit and at least one memory array,
wherein said second level is bonded to said first level, and
wherein said bonded comprises metal to metal bonding regions.

25. The device according to claim 24, further comprising:
at least one SRAM (Static Random Access Memory) array.

26. The device according to claim 24, further comprising:
at least one temperature sensor.

27. The device according to claim 24, further comprising:
a plurality of electrically programmable fuses.

28. The device according to claim 24, further comprising:
at least one processor circuit.

29. The device according to claim 24, further comprising:
a plurality of capacitors.

30. The device according to claim 24,
wherein said plurality of pillars is disposed in-between said memory arrays.

31. A 3D device, said device comprising:
a first level comprising first transistors, said first level comprising a first interconnect;
a second level comprising second transistors, said second level overlaying said first level;
at least four functional units; and
at least one SRAM (Static Random Access Memory) array,
wherein each of said at least four functional units comprises a first circuit, said first circuit comprising a portion of said first transistors,
wherein each of said at least four functional units comprises a second circuit, said second circuit comprising a portion of said second transistors,
wherein each of said at least four functional units comprises a vertical connectivity structure, said vertical connectivity structure comprising a plurality of pillars,
wherein said plurality of pillars provides electrical control connections between said first circuit and said second circuit,
wherein each of said at least four functional units comprises at least one memory control circuit and at least one memory array,
wherein said second level is bonded to said first level, and
wherein said bonded comprises metal to metal bonding regions.

32. The device according to claim 31, further comprising:
a redundancy circuit.

33. The device according to claim 31, further comprising:
at least one temperature sensor.

34. The device according to claim 31, further comprising:
a plurality of electrically programmable fuses.

35. The device according to claim 31, further comprising:
at least one processor circuit.

36. The device according to claim 31, further comprising:
a plurality of capacitors.

37. The device according to claim 31,
wherein said plurality of pillars is disposed in-between said memory arrays.

38. A 3D device, said device comprising:
a first level comprising first transistors, said first level comprising a first interconnect;
a second level comprising second transistors, said second level overlaying said first level;
at least four functional units; and
at least one temperature sensor,
wherein each of said at least four functional units comprises a first circuit, said first circuit comprising a portion of said first transistors,
wherein each of said at least four functional units comprises a second circuit, said second circuit comprising a portion of said second transistors,
wherein each of said at least four functional units comprises a vertical connectivity structure, said vertical connectivity structure comprising a plurality of pillars,
wherein said plurality of pillars provides electrical control connections between said first circuit and said second circuit,
wherein each of said at least four functional units comprises at least one memory control circuit and at least one memory array,
wherein said second level is bonded to said first level, and
wherein said bonded comprises metal to metal bonding regions.

39. The device according to claim 38, further comprising:
a redundancy circuit.

40. The device according to claim 38, further comprising:
a plurality of electrically programmable fuses.

41. The device according to claim 38, further comprising:
at least one processor circuit.

42. The device according to claim 38, further comprising:
a plurality of capacitors.

43. The device according to claim 38,
wherein said plurality of pillars is disposed in-between said memory arrays.
